(19) United States
(12) Patent Application Publication
(10) Pub. No.: US 2023/0231012 A1
(43) Pub. Date: Jul. 20, 2023

(54) SEMICONDUCTOR DEVICE

(71) Applicant: ROHM CO., LTD., Kyoto-shi, Kyoto (JP)

(72) Inventor: Taro KORESAWA, Kyoto-shi, Kyoto (JP)

(73) Assignee: ROHM CO., LTD., Kyoto-shi, Kyoto (JP)

(21) Appl. No.: 17/928,621

(22) PCT Filed: May 31, 2021
(86) PCT No.: PCT/JP2021/020650

§ 371 Date: Nov. 30, 2022

(30) Foreign Application Priority Data
Jun. 5, 2020 (JP) 2020-098806
Aug. 14, 2020 (JP) 2020-137036

(51) Int. Cl. H01L 29/06; H01L 29/872; H01L 29/66

(52) U.S. Cl. CPC H01L 29/0649; H01L 29/0619; H01L 29/8725; H01L 29/66143

(57) ABSTRACT

A semiconductor has a layer of a first conductivity type with a main surface, a trench separation structure which includes a separation trench formed in the main surface, a separation insulating film that covers a wall surface of the separation trench and a separation electrode that is embedded in the separation trench across the separation insulating film, the trench separation structure demarcating an outer region and an active region in the main surface, a floating region of a second conductivity type which is formed in an electrically floating state at a surface layer portion of the main surface along the trench separation structure in the outer region, and a Schottky electrode which is electrically connected to the separation electrode such as to retain the floating region in the electrically floating state in the outer region and which forms a Schottky junction with the main surface in the active region.

### TECHNICAL FIELD

This application corresponds to Japanese Patent Application No. 2020-098806 filed in the Japan Patent Office on Jun. 5, 2020, and Japanese Patent Application No. 2020-137036 filed in the Japan Patent Office on Aug. 14, 2020, an entire disclosure of which is incorporated herein by reference. The present invention relates to a semiconductor device.

### BACKGROUND ART

FIG. 10 of Patent Literature 1 discloses a semiconductor device which includes an n-type epitaxial layer, an annular trench portion, a plurality of band-shape trench portions, a plurality of silicon oxide films, plural types of polysilicon, a p-type semiconductor layer and a Schottky metal layer. The annular trench portion surrounds an inner portion of the epitaxial layer in plan view. The plurality of band-shape trench portions are formed in a region which is surrounded by the annular trench portion in the epitaxial layer to extend in a stripe shape in one direction in plan view.

Each of the silicon oxide films is formed as a film on a wall surface of each trench portion. Each polysilicon is embedded in each trench portion across each silicon oxide film. The p-type semiconductor layer is formed in a surface layer portion of the epitaxial layer along an inner peripheral wall of the annular trench portion inside the region surrounded by the annular trench portion. Inside the region surrounded by the annular trench portion, the Schottky metal layer is electrically connected to the epitaxial layer, the polysilicon inside each trench portion and the p-type semiconductor layer. The Schottky metal layer forms a Schottky junction with the epitaxial layer. In this semiconductor device, the annular trench portion demarcates an outer region which does not have an SBD (Schottky Barrier Diode) and an active region which has the SBD.

FIG. 11 of Patent Literature 1 discloses a semiconductor device which includes an n-type epitaxial layer, a p-type guard ring, an insulating film and a Schottky metal layer. The guard ring surrounds an inner portion of the epitaxial layer in plan view. The insulating film is formed on the epitaxial layer. The insulating film has an opening which exposes an inner portion of the epitaxial layer and a part of the guard ring.

A wall portion of the opening is positioned on the guard ring. The Schottky metal layer is electrically connected to the epitaxial layer and the guard ring inside the opening of the insulating film. The Schottky metal layer forms a Schottky junction with the epitaxial layer. In this semiconductor device, the guard ring demarcates an outer region which does not have an SBD and an active region which has the SBD.

### CITATION LIST

### Patent Literature

Patent Literature 1: Japanese Patent Publication Application No. 2002-050773

### SUMMARY OF INVENTION

### Technical Problem

One embodiment of the present invention provides a semiconductor device capable of improving electrical characteristics.

### Solution to Problem

One embodiment of the present invention is a semiconductor device including a semiconductor layer of a first conductivity type which has a main surface, a trench separation structure which includes a separation trench that is formed in the main surface, a separation insulating film that covers a wall surface of the separation trench and a separation electrode that is embedded in the separation trench across the separation insulating film, the trench separation structure demarcating an outer region and an active region in the main surface, a floating region of a second conductivity type which is formed in an electrically floating state at a surface layer portion of the main surface along the trench separation structure in the outer region, and a Schottky electrode which is electrically connected to the separation electrode such as to retain the floating region in the electrically floating state in the outer region and which forms a Schottky junction with the main surface in the active region.

One embodiment of the present invention is a semiconductor device including a semiconductor layer of a first conductivity type which has a main surface, a plurality of trench structures which include a first trench structure and a second trench structure that are formed in the main surface at an interval in a first direction and that each extends in a band shape in a second direction which intersects the first direction, a first trench separation structure which is formed in the main surface at an interval in the first direction from the first trench structure such as to face the second trench structure across the first trench structure and which extends in a band shape in the second direction, a second trench separation structure which has an outer connecting portion that connects an end portion of the first trench separation structure and an end portion of the second trench structure at an interval from the end portion of the first trench structure and extends in a band shape in the first direction, and a Schottky electrode which is connected to a portion that is exposed from the plurality of trench structures in the main surface.

One embodiment of the present invention is a semiconductor device including a semiconductor layer of a first conductivity type which has a main surface, a plurality of trench structures which include a plurality of first trench structures and a plurality of second trench structures that are formed alternately in the main surface at an interval in a first direction and that each extends in a band shape in a second direction that intersects the first direction, a trench separation structure which has a connecting portion that connects end portions of the two adjacent second trench structures at an interval from the end portion of the first trench structure, and a Schottky electrode which is connected to a portion that is exposed from the plurality of trench structures in the main surface.

One embodiment of the present invention is a semiconductor device including a semiconductor layer which has a main surface, a trench structure which includes a trench that is formed in the main surface, an insulating film that covers a wall surface of the trench and an electrode that is embedded in the trench across the insulating film, a protrusion portion which is constituted of an upper end portion of the insulating film and protrudes as a wall from the main surface such as to separate the electrode and the main surface, and a Schottky electrode which covers the main surface and the trench structure and which forms a Schottky junction with the main surface.

One embodiment of the present invention is a semiconductor device including a semiconductor layer which has a main surface, a trench separation structure which includes a separation trench that is formed in the main surface, a separation insulating film which covers a wall surface of the separation trench and a separation electrode which is embedded in the separation trench across the separation insulating film, the trench separation structure demarcating an outer region and an active region in the main surface, a separation protrusion portion which is constituted of an upper end portion of the separation insulating film and protrudes as a wall from the main surface such as to separate the separation electrode and the main surface on the active region side, and a Schottky electrode which forms a Schottky junction with the main surface on the active region side.

The aforementioned as well as yet other objects, features, and effects of the present invention will be made clear by the following description of embodiments, with reference to the accompanying drawings.

### BRIEF DESCRIPTION OF DRAWINGS

FIG. 1 is a plan view which shows a semiconductor device according to a first embodiment of the present invention.

FIG. 2 is a plan view which shows a structure of a first main surface of a semiconductor chip shown in FIG. 1.

FIG. 3 is an enlarged view of a region III shown in FIG. 2.

FIG. 4 is a cross-sectional view along line IV-IV shown in FIG. 1.

FIG. 5 is an enlarged cross-sectional view of an outer region shown in FIG. 4.

FIG. 6A is a cross-sectional view which shows a semiconductor device according to a first reference embodiment.

FIG. 6B is a cross-sectional view which shows a semiconductor device according to a second reference embodiment.

FIG. 6C is a cross-sectional view which shows a semiconductor device according to a third reference embodiment.

FIG. 6D is a cross-sectional view which shows a semiconductor device according to a fourth reference embodiment.

FIG. 7 is a graph which examines a relationship between a reverse current and a reverse voltage by simulation.

FIG. 8 corresponds to FIG. 5 and is a drawing for describing a depletion layer which is formed inside a drift layer.

FIG. 9 is a graph which examines an electric field distribution of a broken-line portion IX shown in FIG. 8 by simulation.

FIG. 10A is a cross-sectional view for describing a method for manufacturing the semiconductor device shown in FIG. 1.

FIG. 10B is a cross-sectional view which shows a step subsequent to that of FIG. 10A.

FIG. 10C is a cross-sectional view which shows a step subsequent to that of FIG. 10B.

FIG. 10D is a cross-sectional view which shows a step subsequent to that of FIG. 10C.

FIG. 10E is a cross-sectional view which shows a step subsequent to that of FIG. 10D.

FIG. 10F is a cross-sectional view which shows a step subsequent to that of FIG. 10E.

FIG. 10G is a cross-sectional view which shows a step subsequent to that of FIG. 10F.

FIG. 10H is a cross-sectional view which shows a step subsequent to that of FIG. 10G.

FIG. 10I is a cross-sectional view which shows a step subsequent to that of FIG. 10H.

FIG. 10J is a cross-sectional view which shows a step subsequent to that of FIG. 10I.

FIG. 10K is a cross-sectional view which shows a step subsequent to that of FIG. 10J.

FIG. 10L is a cross-sectional view which shows a step subsequent to that of FIG. 10K.

FIG. 10M is a cross-sectional view which shows a step subsequent to that of FIG. 10L.

FIG. 10N is a cross-sectional view which shows a step subsequent to that of FIG. 10M.

FIG. 10O is a cross-sectional view which shows a step subsequent to that of FIG. 10N.

FIG. 10P is a cross-sectional view which shows a step subsequent to that of FIG. 10O.

FIG. 10Q is a cross-sectional view which shows a step subsequent to that of FIG. 10P.

FIG. 11 is a drawing which corresponds to FIG. 4 and a cross-sectional view for showing a semiconductor device according to a second embodiment of the present invention.

FIG. 12 is a drawing which corresponds to FIG. 11 and a cross-sectional view for showing a semiconductor device according to a third embodiment of the present invention.

FIG. 13 is a drawing which corresponds to FIG. 2 and a plan view for showing a semiconductor device according to a fourth embodiment of the present invention.

FIG. 14 is a drawing which corresponds to FIG. 2 and a plan view for showing a semiconductor device according to a fifth embodiment of the present invention.

FIG. 15 is a drawing which corresponds to FIG. 2 and a plan view for showing a semiconductor device according to a sixth embodiment of the present invention.

FIG. 16 is a drawing which corresponds to FIG. 2 and a plan view for showing a semiconductor device according to a seventh embodiment of the present invention.

FIG. 17 is a drawing which corresponds to FIG. 2 and a plan view for showing a semiconductor device according to an eighth embodiment of the present invention.

FIG. 18 is an enlarged view of a region XVIII shown in FIG. 17.

FIG. 19 is a drawing which corresponds to FIG. 4 and a cross-sectional view for showing a semiconductor device according to a ninth embodiment of the present invention.

FIG. 20 is a plan view which shows a semiconductor device according to a tenth embodiment of the present invention.

FIG. 21 is a plan view which shows a structure of a first main surface of a semiconductor chip shown in FIG. 20.

FIG. 22 is a cross-sectional view along line XXII-XXII shown in FIG. 20.

FIG. 23 is a cross-sectional view along line XXIII-XXIII shown in FIG. 20.

FIG. 24 is an enlarged view of a region XXIV shown in FIG. 21.

FIG. 25 is an enlarged view of a region XXV shown in FIG. 21.

FIG. 26 is a cross-sectional view along line XXVI-XXVI shown in FIG. 25.

FIG. 27 is an enlarged view of a main portion in FIG. 26.

FIG. 28 corresponds to FIG. 26 and is a drawing for describing a depletion layer inside a drift layer.

### DESCRIPTION OF EMBODIMENTS

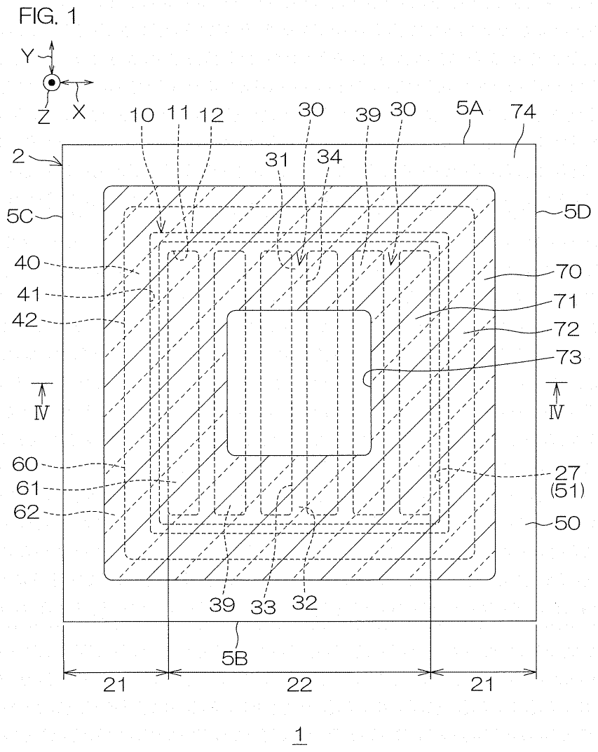

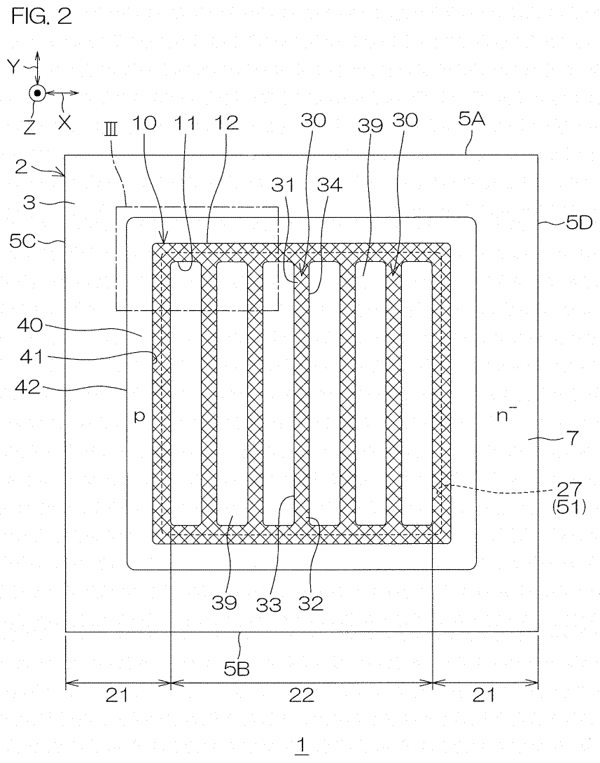

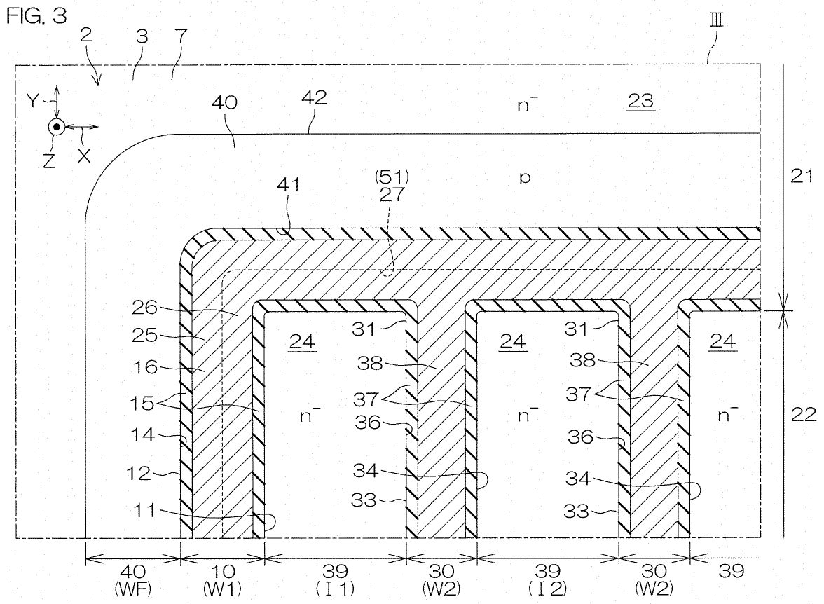

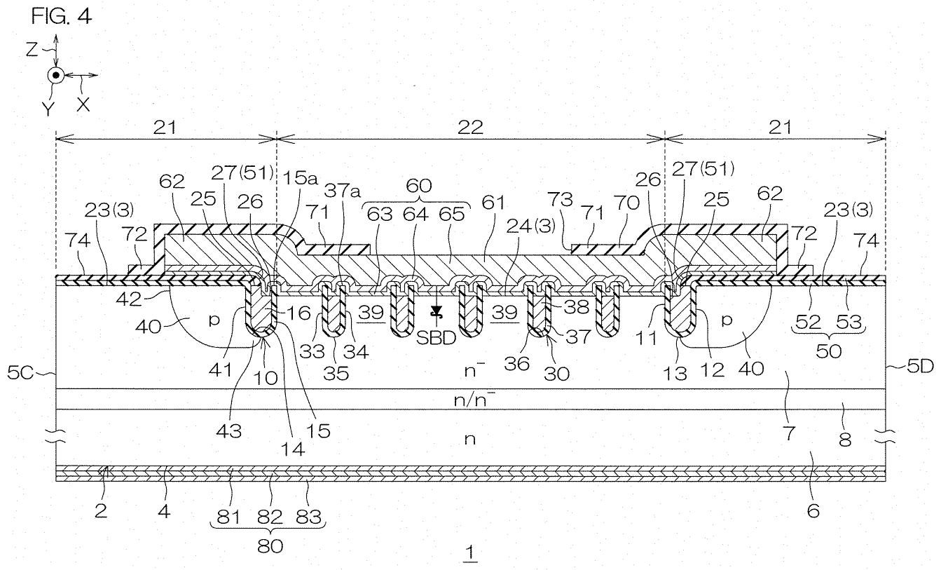

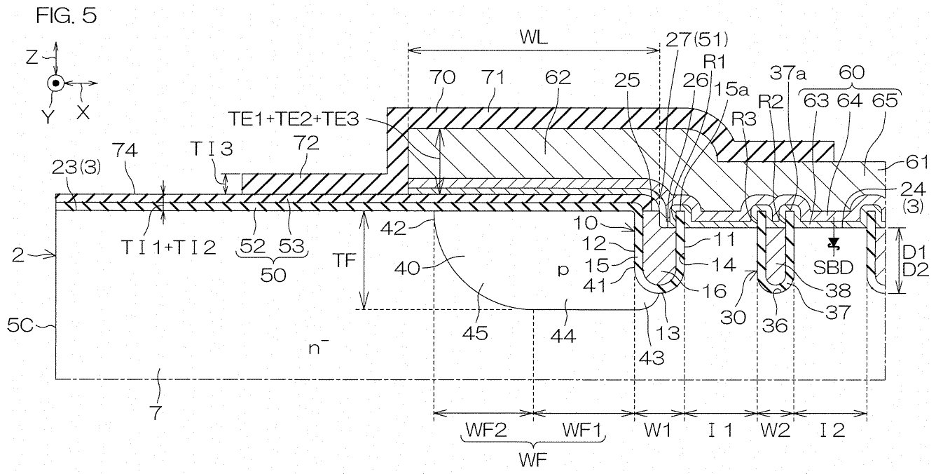

FIG. 1 is a plan view which shows a semiconductor device 1 according to the first embodiment of the present invention. FIG. 2 is a plan view for showing a structure of a first main surface 3 of a semiconductor chip 2 shown in FIG. 1. FIG. 3 is an enlarged view of the region III shown in FIG. 2. FIG. 4 is a cross-sectional view along line IV-IV shown in FIG. 1. FIG. 5 is an enlarged cross-sectional view of an outer region 21 shown in FIG. 4.

With reference to FIG. 1 to FIG. 5, the semiconductor device 1 is a semiconductor rectifying device having an SBD (Schottky Barrier Diode). The semiconductor device 1 includes the semiconductor chip 2 formed in a rectangular parallelepiped shape. In this embodiment, the semiconductor chip 2 is constituted of an Si (silicon) chip. The semiconductor chip 2 has the first main surface 3 on one side, a second main surface 4 on the other side and first to fourth side surfaces 5A to 5D which connect the first main surface 3 and the second main surface 4.

The first main surface 3 and the second main surface 4 are each formed in a quadrilateral shape in plan view as viewed in a normal direction Z thereof (hereinafter, simply referred to as “in plan view”). The first main surface 3 is a device surface in which the SBD is formed. The second main surface 4 is a non-device surface. The second main surface 4 may be a ground surface having grinding marks. The first side surface 5A and the second side surface 5B extend in a first direction X along the first main surface 3 and face in a second direction Y which intersects (specifically, orthogonal to) the first direction X. The third side surface 5C and the fourth side surface 5D extend in the second direction Y and face each other in the first direction X.

The first to fourth side surfaces 5A to 5D may each be constituted of a ground surface having grinding marks which are formed by cutting with a dicing blade or may each be constituted of a cleavage surface which has a modified layer that is formed by laser light irradiation. Specifically, the modified layer is constituted of a region in which a crystalline structure of the semiconductor chip 2 is partially modified into another property. That is, the modified layer is constituted of a region in which a density, a refractive index or a mechanical intensity (crystal strength) or other physical characteristics are modified into a property different from that of the crystalline structure of the semiconductor chip 2.

The modified layer may include at least one layer among an amorphous layer, a melt re-hardened layer, a defect layer, a dielectric breakdown layer and a refractive index change layer. The amorphous layer is a layer in which a part of the semiconductor chip 2 is made amorphous. The melt re-hardened layer is a layer in which a part of the semiconductor chip 2 is re-hardened after being melted. The defect layer is a layer which includes a hole, a crack, etc., formed in the semiconductor chip 2. The dielectric breakdown layer is a layer in which a part of the semiconductor chip 2 has undergone dielectric breakdown. The refractive index change layer is a layer in which a part of the semiconductor chip 2 is changed to a refractive index different from that of the semiconductor chip 2.

The semiconductor device 1 includes an n-type (first conductivity type) cathode layer 6 (high concentration semiconductor layer) which is formed at a surface layer portion of the second main surface 4 of the semiconductor chip 2. The cathode layer 6 forms a cathode of the SBD. The cathode layer 6 is formed in an entire area of the surface layer portion of the second main surface 4 and exposed from the second main surface 4 and the first to fourth side surfaces 5A to 5D. That is, the cathode layer 6 has the second main surface 4 and a part of the first to fourth side surfaces 5A to 5D. The cathode layer 6 has a first electric resistivity. The first electric resistivity may be not less than 0.5 mΩ·cm and not more than 3 mΩ·cm.

The cathode layer 6 has an n-type impurity concentration which is substantially constant in a thickness direction. The n-type impurity concentration of the cathode layer 6 may be not less than 1×10¹⁸ cm⁻³ and not more than 1×10²¹ cm⁻³. A thickness of the cathode layer 6 may be not less than 5 μm and not more than 300 μm. The thickness of the cathode layer 6 is typically not less than 50 μm and not more than 300 μm. The thickness of the cathode layer 6 is adjusted by grinding the second main surface 4. In this embodiment, the cathode layer 6 is formed of an n-type semiconductor substrate (Si substrate).

The semiconductor device 1 includes an n-type drift layer 7 (semiconductor layer) which is formed at a surface layer portion of the first main surface 3 of the semiconductor chip 2. The drift layer 7 is formed in an entire area of the surface layer portion of the first main surface 3 and exposed from the first main surface 3 and the first to fourth side surfaces 5A to 5D. That is, the drift layer 7 has the first main surface 3 and a part of the first to fourth side surfaces 5A to 5D. The drift layer 7 is electrically connected to the cathode layer 6 and forms the cathode of the SBD together with the cathode layer 6. The drift layer 7 has a second electric resistivity in excess of the first electric resistivity of the cathode layer 6. The second electric resistivity may be not less than 0.1 Ω·cm and not more than 3 Ω·cm.

The drift layer 7 has an n-type impurity concentration which is less than the n-type impurity concentration of the cathode layer 6. The n-type impurity concentration of the drift layer 7 may be not less than 1×10¹⁵ cm⁻³ and not more than 1×10¹⁶ cm⁻³. A thickness of the drift layer 7 may be not less than 5 μm and not more than 20 μm. In this embodiment, the drift layer 7 is formed by an n-type epitaxial layer (Si epitaxial layer).

The semiconductor device 1 includes an n-type buffer layer 8 which is interposed between the cathode layer 6 and the drift layer 7 in the semiconductor chip 2. The buffer layer 8 is interposed in an entire area of a region between the cathode layer 6 and the drift layer 7 and exposed from the first to fourth side surfaces 5A to 5D. That is, the buffer layer 8 has a part of the first to fourth side surfaces 5A to 5D. The buffer layer 8 is electrically connected to the cathode layer 6 and the drift layer 7 and forms the cathode of the SBD together with the cathode layer 6 and the drift layer 7. The buffer layer 8 has a concentration gradient in which the n-type impurity concentration decreases (specifically, decreases gradually) from the n-type impurity concentration of the cathode layer 6 to the n-type impurity concentration of the drift layer 7. A thickness of the buffer layer 8 may be not less than 1 μm and not more than 10 μm. In this embodiment, the buffer layer 8 is formed by the n-type epitaxial layer (Si epitaxial layer).

The semiconductor device 1 includes a trench separation structure 10 which is formed in the first main surface 3. The trench separation structure 10 is formed at an interval from a bottom portion of the drift layer 7 (that is, buffer layer 8) to the first main surface 3 side. Specifically, the trench separation structure 10 is formed internally at an interval from the first to fourth side surfaces 5A to 5D and formed in an annular shape which surrounds an inner portion (central portion) of the first main surface 3 in plan view.

The trench separation structure 10 has an inner peripheral wall 11, an outer peripheral wall 12 and a bottom wall 13. In this embodiment, the inner peripheral wall 11 is formed in a quadrilateral shape having four sides which are parallel to the first to fourth side surfaces 5A to 5D in plan view. The outer peripheral wall 12 is positioned on the first to fourth side surfaces 5A to 5D sides with respect to the inner peripheral wall 11 and surrounds the inner peripheral wall 11 in plan view. The outer peripheral wall 12 is formed in a quadrilateral shape having four sides parallel to the first to fourth side surfaces 5A to 5D and extend substantially in parallel with the inner peripheral wall 11 in plan view.

The bottom wall 13 connects the inner peripheral wall 11 and the outer peripheral wall 12. The bottom wall 13 is preferably formed in a curved shape toward the second main surface 4. The bottom wall 13 may have a flat surface which is parallel to the first main surface 3. In this case, it is preferable that a corner portion which connects the inner peripheral wall 11 and the bottom wall 13 and a corner portion which connects the outer peripheral wall 12 and the bottom wall 13 are each formed in a curved shape.

The trench separation structure 10 may be formed in a vertical shape in which a width (that is, opening width) between the inner peripheral wall 11 and the outer peripheral wall 12 is substantially constant toward the bottom wall 13. The trench separation structure 10 may be formed in a tapered shape in which the width (that is, opening width) between the inner peripheral wall 11 and the outer peripheral wall 12 is narrowed toward the bottom wall 13. The trench separation structure 10 is preferably formed in a quadrilateral shape in which four corners are chamfered in plan view. That is, a corner portion of the inner peripheral wall 11 is preferably formed in a curved shape outward in plan view. Further, a corner portion of the outer peripheral wall 12 is preferably formed in a curved shape outward such as to extend substantially in parallel with the corner portion of the inner peripheral wall 11 in plan view.

The trench separation structure 10 has a first width W1 and a first depth D1. The first width W1 is a width in a direction orthogonal to a direction in which the trench separation structure 10 extends. The first width W1 may be not less than 0.5 μm and not more than 3 μm. The first width W1 is preferably not less than 0.8 μm and not more than 1.5 μm. The first depth D1 may be not less than 1 μm and not more than 5 μm. The first depth D1 is preferably not less than 1.5 μm and not more than 3 μm. The trench separation structure 10 is preferably formed at an interval of not less than 1 μm (preferably not less than 3 μm) from the bottom portion of the drift layer 7.

The trench separation structure 10 includes a separation trench 14, a separation insulating film 15 and a separation electrode 16. The separation trench 14 is dug down from the first main surface 3 to the second main surface 4. The separation trench 14 is formed at an interval from the bottom portion of the drift layer 7 (that is, buffer layer 8) to the first main surface 3 side to face the cathode layer 6 (buffer layer 8) across a part of the drift layer 7.

The separation trench 14 forms the inner peripheral wall 11, the outer peripheral wall 12 and the bottom wall 13 of the trench separation structure 10. The inner peripheral wall 11, the outer peripheral wall 12 and the bottom wall 13 form a wall surface (inner wall and outer wall) of the separation trench 14. The separation trench 14 exposes the drift layer 7 from the inner peripheral wall 11, the outer peripheral wall 12 and the bottom wall 13.

The separation insulating film 15 is formed as a film along the wall surface of the separation trench 14 and demarcates a recess space inside the separation trench 14. In this embodiment, the separation insulating film 15 includes a silicon oxide film. A thickness of the separation insulating film 15 may be not less than 0.05 μm and not more than 0.5 μm. The thickness of the separation insulating film 15 is preferably not less than 0.1 μm and not more than 0.4 μm. The separation electrode 16 is embedded in the separation trench 14 across the separation insulating film 15. In this embodiment, the separation electrode 16 contains conductive polysilicon. The conductive polysilicon may be n-type polysilicon or p-type polysilicon.

The trench separation structure 10 demarcates an outer region 21 having a predetermined shape and an active region 22 having a predetermined shape in the first main surface 3 in plan view. The outer region 21 is a region in which the SBD is not formed. The active region 22 is a region in which the SBD is formed. The outer region 21 is demarcated in a region between the peripheral edge (that is, the first to fourth side surfaces 5A to 5D) of the first main surface 3 and the inner peripheral wall 11 of the trench separation structure 10 in the first main surface 3. The active region 22 is demarcated in a region surrounded by the inner peripheral wall 11 of the trench separation structure 10 in the first main surface 3. In this embodiment, the trench separation structure 10 is formed in a quadrilateral annular shape in plan view. Therefore, the outer region 21 is demarcated in a quadrilateral annular shape in plan view, and the active region 22 is demarcated in a quadrilateral shape in plan view.

With reference to FIG. 4 and FIG. 5, the first main surface 3 has an outer main surface 23 positioned in the outer region 21 and an active main surface 24 positioned in the active region 22. In this embodiment, the active main surface 24 is positioned on the bottom portion side of the drift layer 7 (second main surface 4 side) with respect to the outer main surface 23. Specifically, the active main surface 24 is further depressed to the bottom portion side of the drift layer 7 with respect to the outer main surface 23. The n-type impurity concentration of the drift layer 7 at a surface layer portion of the active main surface 24 is higher than the n-type impurity concentration of the drift layer 7 at a surface layer portion of the outer region 21. With regard to the normal direction Z, the active main surface 24 is preferably depressed in a range in excess of 0 μm and not more than 0.5 μm (preferably, not more than 0.1 μm) with respect to the outer main surface 23.

The trench separation structure 10 includes a first portion 25 on the outer region 21 side and a second portion 26 on the active region 22 side. The first portion 25 includes the outer peripheral wall 12 of the separation trench 14, a portion of the separation insulating film 15 which covers the outer peripheral wall 12 and a portion of the separation electrode 16 which is positioned on the outer peripheral wall 12 side. The second portion 26 includes the inner peripheral wall 11 of the separation trench 14, a portion of the separation insulating film 15 which covers the inner peripheral wall 11 and a portion of the separation electrode 16 which is positioned on the inner peripheral wall 11 side.

The separation electrode 16 on the second portion 26 side is depressed to the bottom portion side of the drift layer 7 with respect to the separation electrode 16 on the first portion 25 side. Specifically, the separation electrode 16 on the second portion 26 side is further depressed to the bottom portion side of the drift layer 7 with respect to the separation electrode 16 on the first portion 25 side. That is, an upper end portion of the separation electrode 16 on the active region 22 side is depressed to the bottom portion side of the drift layer 7 with respect to an upper end portion thereof on the outer region 21 side. The separation electrode 16 on the second portion 26 side is preferably positioned on the bottom wall side of the separation trench 14 with respect to the active main surface 24.

With regard to the normal direction Z, the separation electrode 16 on the second portion 26 side is preferably depressed in a range in excess of 0 μm and not more than 0.5 μm (preferably not more than 0.1 μm) with respect to the separation electrode 16 on the first portion 25 side. The first portion 25 and the second portion 26 of the trench separation structure 10 demarcate a contact opening 27 which is dug down from the outer main surface 23 toward the bottom portion side of the drift layer 7 with the active main surface 24.

With reference to FIG. 5, the separation insulating film 15 on the second portion 26 side has a separation protrusion portion 15a which protrudes as a wall from the active main surface 24. The separation protrusion portion 15a is constituted of an upper end portion of the separation insulating film 15. The separation protrusion portion 15a is also one constituent of the trench separation structure 10. In this embodiment, the separation protrusion portion 15a protrudes upper than the separation electrode 16 on the second portion 26 side and is formed in a depth range between the outer main surface 23 and the active main surface 24. The separation protrusion portion 15a may be formed at an interval on the active main surface 24 side with respect to the outer main surface 23. A leading end portion of the separation protrusion portion 15a may be inclined downward in an oblique direction toward the inner portion side of the trench separation structure 10.

The separation protrusion portion 15a demarcates a first recess R1 with the separation electrode 16 at an inner portion of the separation trench 14. The separation protrusion portion 15a linearly extends along the inner peripheral wall 11 of the separation trench 14 such as to separate the separation electrode 16 and the active main surface 24. In this embodiment, the separation protrusion portion 15a is formed in an annular shape (specifically, quadrilateral annular shape) which extends along the separation trench 14 in plan view.

That is, the separation protrusion portion 15a separates the active main surface 24 from the separation electrode 16 in an entire area (entire periphery) of the separation trench 14. The separation protrusion portion 15a increases an insulation distance between the separation electrode 16 and the active main surface 24 and suppresses a boundary leakage which occurs between the separation electrode 16 and the active main surface 24. The separation protrusion portion 15a preferably protrudes in a range in excess of 0 μm and not more than 0.5 μm (preferably, not more than 0.1 μm) with respect to the active main surface 24.

The semiconductor device 1 includes a plurality of trench structures 30 which are formed in the first main surface 3 in the active region 22. That is, in this embodiment, the plurality of trench structures 30 are formed in the active main surface 24 which is depressed to the bottom portion side of the drift layer 7 with respect to the outer main surface 23. Therefore, the plurality of trench structures 30 are formed on the bottom portion side of the drift layer 7 with respect to the outer main surface 23. The plurality of trench structures 30 are formed on the first main surface 3 side at an interval from the bottom portion (that is, buffer layer 8) of the drift layer 7.

The plurality of trench structures 30 are formed at an interval in the first direction X in plan view and each formed in a band shape extending in the second direction Y. That is, the plurality of trench structures 30 are arrayed in a stripe shape extending in one direction (second direction Y). The plurality of trench structures 30 have a first end portion 31 on one side (first side surface 5A side) and a second end portion 32 on the other side (second side surface 5B side) with regard to the second direction Y. The first end portion 31 of each of the trench structures 30 is communicatively connected to the trench separation structure 10 (a portion along the first side surface 5A). The second end portion 32 of each of the trench structures 30 is communicatively connected to the trench separation structure 10 (a portion along the second side surface 5B).

Specifically, each of the trench structures 30 has a first side wall 33 on one side (third side surface 5C side), a second side wall 34 on the other side (fourth side surface 5D side) and a bottom wall 35. The first side wall 33 and the second side wall 34 extend substantially in parallel with the second direction Y and are communicatively connected to the inner peripheral wall 11 of the trench separation structure 10. The bottom wall 35 connects the first side wall 33 and the second side wall 34 and is communicatively connected to the bottom wall 13 of the trench separation structure 10.

The bottom wall 35 is preferably formed in a curved shape toward the second main surface 4. The bottom wall 35 may have a flat surface which is parallel to the first main surface 3. In this case, it is preferable that a corner portion which connects the first side wall 33 and the bottom wall 35 and a corner portion which connects the second side wall 34 and the bottom wall 35 are each formed in a curved shape. Each of the trench structures 30 may be formed in a vertical shape which is substantially constant in width (that is, opening width) between the first side wall 33 and the second side wall 34 toward the bottom wall 35. Each of the trench structures 30 may be formed in a tapered shape in which the width (that is, opening width) between the first side wall 33 and the second side wall 34 is narrowed toward the bottom wall 35.

Each of the trench structures 30 has a second width W2 and a second depth D2. The second width W2 is a width in a direction orthogonal to a direction in which each of the trench structures 30 extends (that is, first direction X). The second width W2 is preferably less than the first width W1 of the trench separation structure 10. That is, the trench separation structure 10 is preferably formed wider than each of the trench structures 30. The second width W2 may be not less than 0.1 μm and not more than 2 μm. The second width W2 is preferably not less than 0.4 μm and not more than 1.2 μm.

The second depth D2 may be not less than 1 μm and not more than 5 μm. The second depth D2 is preferably not less than 1.5 μm and not more than 3 μm. Each of the trench structures 30 is preferably formed at an interval of not less than 1 μm (preferably, not less than 3 μm) from the bottom portion of the drift layer 7. The second depth D2 may be less than the first depth D1 of the trench separation structure 10.

That is, each of the trench structures 30 may be formed shallower than the trench separation structure 10. In this case, the bottom wall 35 of each of the trench structures 30 is positioned on the first main surface 3 (active main surface 24) side with respect to the bottom wall 13 of the trench separation structure 10. Further, in this case, a difference between the first depth D1 and the second depth D2 (D1−D2) is preferably in excess of 0 μm and not more than 0.5 μm. The difference (D1−D2) is particularly preferably not more than 0.2 μm.

The plurality of trench structures 30 are formed at a first interval I1 from the trench separation structure 10 with regard to the first direction X. The first interval I1 may be not less than 1 μm and not more than 5 μm. The first interval I1 is preferably not less than 2 μm and not more than 4 μm. The plurality of trench structures 30 are formed each other at a second interval I2 with regard to the first direction X. The second interval I2 may be not less than 1 μm and not more than 5 μm. The second interval I2 is preferably not less than 2 μm and not more than 4 μm. It is particularly preferable that the second interval I2 is substantially equal to the first interval I1.

The plurality of trench structures 30 each include a trench 36, an insulating film 37 and an electrode 38. The trench 36 is dug down from the first main surface 3 toward the second main surface 4. The trench 36 is formed at an interval from the bottom portion (that is, buffer layer 8) of the drift layer 7 to the first main surface 3 side and faces the cathode layer 6 (buffer layer 8) across a part of the drift layer 7.

The trench 36 forms the first side wall 33, the second side wall 34 and the bottom wall 35 of the trench structure 30. The first side wall 33, the second side wall 34 and the bottom wall 35 form a wall surface (inner wall and outer wall) of the trench 36. The trench 36 exposes the drift layer 7 from the first side wall 33, the second side wall 34 and the bottom wall 35. The first side wall 33, the second side wall 34 and the bottom wall 35 of the trench 36 are communicatively connected to the inner peripheral wall 11 and the bottom wall 13 of the separation trench 14.

The insulating film 37 is formed as a film along a wall surface of the trench 36 and demarcates a recess space inside the trench 36. The insulating film 37 is connected to the separation insulating film 15 at a communicatively connecting portion of the separation trench 14 and the trench 36. In this embodiment, the insulating film 37 includes a silicon oxide film. A thickness of the insulating film 37 may be not less than 0.05 μm and not more than 0.5 μm. The thickness of the insulating film 37 is preferably not less than 0.1 μm and not more than 0.4 μm.

As compared with the thickness of the insulating film 37, a thickness of the separation insulating film 15 is preferably in excess of the thickness of the insulating film 37. As a matter of course, in consideration of the convenience of the manufacturing method, the separation insulating film 15 having the thickness substantially equal to the thickness of the insulating film 37 may be formed.

The electrode 38 is embedded in the trench 36 across the insulating film 37. The electrode 38 is connected to the separation electrode 16 at the communicatively connecting portion of the separation trench 14 and the trench 36. An upper end portion of the electrode 38 is preferably positioned on the bottom wall side of the trench 36 with respect to the active main surface 24. The electrode 38 includes the same electrode material as the separation electrode 16. That is, in this embodiment, the electrode 38 contains conductive polysilicon. The conductive polysilicon may be n-type polysilicon or p-type polysilicon.

The plurality of trench structures 30 demarcate a plurality of mesa portions 39 which are each constituted of a part of the drift layer 7 in the first main surface 3 (that is, active main surface 24) inside the active region 22. The plurality of mesa portions 39 are formed at an interval in the first direction X in plan view and each formed in a band shape extending in the second direction Y. That is, the plurality of trench structures 30 are formed alternately together with the plurality of mesa portions 39 in a mode that one mesa portion 39 is held between them. The plurality of mesa portions 39 are each demarcated in a rectangular shape extending in the second direction Y by the trench separation structure 10 and the plurality of trench structures 30 in plan view. Corner portions (four corners) of each of the mesa portions 39 are demarcated in a curved shape toward the outside of the semiconductor chip 2 in plan view.

With reference to FIG. 5, the insulating film 37 has a protrusion portion 37a which protrudes as a wall from the active main surface 24. The protrusion portion 37a is constituted of an upper end portion of the insulating film 37. The protrusion portion 37a is also one constituent of the trench structure 30. In this embodiment, the protrusion portion 37a protrudes upper than the electrode 38 and is formed in a depth range between the outer main surface 23 and the active main surface 24. The protrusion portion 37a may be formed at an interval on the active main surface 24 side with respect to the outer main surface 23. A leading end portion of the protrusion portion 37a may be inclined downward in an oblique direction toward the inner portion side of the trench structure 30.

The protrusion portion 37a demarcates a second recess R2 with the electrode 38 in an inner portion of the trench 36. The protrusion portion 37a linearly extends along a wall surface of the trench 36 in plan view and separates the electrode 38 and the active main surface 24. The protrusion portion 37a increases an insulation distance between the electrode 38 and the active main surface 24 and suppresses a boundary leakage which occurs between the electrode 38 and the active main surface 24.

The protrusion portion 37a is connected to a separation protrusion portion 15a of the separation insulating film 15 at the communicatively connecting portion of the separation trench 14 and the trench 36. That is, the protrusion portion 37a is formed in an entire area of the trench structure 30. Further, the protrusion portion 37a separates each of the mesa portions 39 from the separation electrode 16 and the electrode 38 in an entire area (entire periphery) of each of the mesa portions 39 together with the separation protrusion portion 15a of the separation insulating film 15.

Further, the protrusion portion 37a demarcates a third recess R3 (mesa recess) which exposes each of the mesa portions 39 together with the separation protrusion portion 15a. Still further, the second recess R2 of the trench structure 30 is communicatively connected to the first recess R1 of the trench separation structure 10 at the communicatively connecting portion of the separation trench 14 and the trench 36. It is preferable that the protrusion portion 37a protrudes in a range in excess of 0 μm and not more than 0.5 μm (preferably, not more than 0.1 μm) with respect to the active main surface 24.

The semiconductor device 1 includes a p-type floating region 40 which is formed at the surface layer portion of the first main surface 3 along the trench separation structure 10 in the outer region 21. That is, the floating region 40 is formed in the outer main surface 23. In this embodiment, with regard to the normal direction Z, the floating region 40 includes a portion which is positioned on the outer main surface 23 side with respect to the active main surface 24 and a portion which is positioned on the bottom portion side of the drift layer 7 with respect to the active main surface 24.

The floating region 40 is formed in an electrically floating state. That is, the floating region 40 is formed electrically in separation from the active region 22, the trench separation structure 10 and the plurality of trench structures 30. The floating region 40 has a p-type impurity concentration which is not less than 1×10¹⁷ cm⁻³ and not more than 1×10¹⁹ cm⁻³. The p-type impurity concentration of the floating region 40 has a concentration gradient which decreases gradually from the first main surface 3 (outer main surface 23) in a width direction and a thickness direction of the drift layer 7.

The floating region 40 is adjacent to the trench separation structure 10 in the outer region 21. The floating region 40 is formed in a band shape along the outer peripheral wall 12 of the trench separation structure 10 in plan view. Specifically, the floating region 40 is formed in an annular shape which surrounds the trench separation structure 10 in plan view. The floating region 40 has an inner peripheral edge 41 on the active region 22 (trench separation structure 10) side and an outer peripheral edge 42 on the outer region 21 (first to fourth side surfaces 5A to 5D) side.

The inner peripheral edge 41 of the floating region 40 is connected to the outer peripheral wall 12 of the trench separation structure 10. The outer peripheral edge 42 of the floating region 40 extends along the outer peripheral wall 12 of the trench separation structure 10 in plan view. In this embodiment, the outer peripheral edge 42 of the floating region 40 extends substantially in parallel with the outer peripheral wall 12 of the trench separation structure 10 in plan view. A portion along the four corners of the trench separation structure 10 at the outer peripheral edge 42 of the floating region 40 is preferably formed in a curved shape outward.

The floating region 40 is formed at the surface layer portion of the first main surface 3 at an interval from the bottom portion of the drift layer 7 to the first main surface 3 side. The floating region 40 is formed in a depth range between the first main surface 3 and the bottom wall 13 of the trench separation structure 10. The floating region 40 is formed deeper than the trench separation structure 10. The floating region 40 is also formed deeper than each of the trench structures 30.

The floating region 40 (specifically, inner peripheral edge 41) has a covering portion 43 which covers the bottom wall 13 of the trench separation structure 10. Specifically, the covering portion 43 covers the bottom wall 13 of the trench separation structure 10 at an interval from the active region 22 to the outer region 21 side in plan view. That is, in the bottom wall 13 of the trench separation structure 10, the covering portion 43 covers a portion on the outer region 21 side such as to expose a portion on the active region 22 side.

The floating region 40 has a region thickness TF and a region width WF. The region thickness TF is a distance between the first main surface 3 (outer main surface 23) and a bottom portion of the floating region 40. The region width WF is a width (maximum width) in a direction orthogonal to a direction in which the floating region 40 extends, with the outer peripheral wall 12 of the trench separation structure 10 given as a reference. The region width WF is preferably equal to or larger than the second width W2 of the trench structure 30 (W2≤WF). The region width WF is preferably equal to or larger than the first width W1 of the trench separation structure 10 (W1≤WF).

In this embodiment, the region width WF is in excess of the first width W1 of the trench separation structure 10 (W1<WF). That is, with regard to the first direction X, the width becomes larger from the active region 22 side to the outer region 21 side in an ascending order of the second width W2 of the trench structure 30, the first width W1 of the trench separation structure 10 and the region width WF of the floating region 40 (W2<W1<WF). The region width WF may be not less than 2 μm and not more than 20 μm. The region width WF is preferably not less than 5 μm and not more than 15 μm.

The region thickness TF may be not less than 1 μm and not more than 5 μm. The region thickness TF is preferably not less than 1.5 μm and not more than 3.5 μm. The floating region 40 is preferably formed at an interval of not less than 1 μm (preferably, not less than 3 μm) from the bottom portion of the drift layer 7 (that is, buffer layer 8). The floating region 40 is formed such that the region thickness TF decreases gradually to the first main surface 3 side from the inner peripheral edge 41 side to the outer peripheral edge 42 side. In this embodiment, the floating region 40 includes a first region 44 having the region thickness TF which is substantially constant on the inner peripheral edge 41 (trench separation structure 10) side and a second region 45 having the region thickness TF which decreases gradually to the first main surface 3 side on the outer edge side.

The first region 44 has a first region width WF1, and the second region 45 has a second region width WF2. The region width WF is a sum (WF=WF1+WF2) of the first region width WF1 and the second region width WF2. The second region width WF2 is preferably equal to or less than the first region width WF1 (WF2≤WF1). It is particularly preferable that the second region width WF2 is less than the first region width WF1 (WF2<WF1).

An aspect ratio of the floating region 40, WF/TF, is preferably in excess of 1. The aspect ratio of WF/TF is a ratio of the region width WF with respect to the region thickness TF. That is, the floating region 40 preferably has a horizontally long structure along the first main surface 3 (outer main surface 23) in a cross sectional view. The aspect ratio of WF/TF is preferably in excess of 1 and not more than 5.

The semiconductor device 1 includes a main surface insulating film 50 which covers the first main surface 3 in the outer region 21. That is, the main surface insulating film 50 covers the outer main surface 23. In this embodiment, the main surface insulating film 50 includes a silicon oxide film. The main surface insulating film 50 covers an entire area of the floating region 40 in the outer region 21 and electrically insulates the floating region 40 from the outside. Specifically, the main surface insulating film 50 covers an entire area of the outer region 21 (outer main surface 23) and continues to the first to fourth side surfaces 5A to 5D.

The main surface insulating film 50 covers the first portion 25 of the trench separation structure 10 at an edge portion on the active region 22 side and exposes the second portion 26 of the trench separation structure 10. Specifically, the main surface insulating film 50 crosses the outer peripheral wall 12 of the trench separation structure 10 such as to expose the upper end portion of the separation electrode 16 on the active region 22 side and covers the upper end portion of the separation electrode 16 on the outer region 21 side.

The main surface insulating film 50 has a through hole 51 exposing the second portion 26 of the trench separation structure 10 and the active region 22 (active main surface 24) at a portion which covers the first portion 25 of the trench separation structure 10. A wall portion which demarcates the through hole 51 is positioned on the separation electrode 16 and exposes the contact opening 27. That is, the through hole 51 is communicatively connected to the contact opening 27. In this embodiment, the wall portion of the through hole 51 is connected to a wall portion of the contact opening 27.

In this embodiment, the main surface insulating film 50 has a laminated structure which includes a first main surface insulating film 52 and a second main surface insulating film 53 that are laminated in this order from the first main surface 3 side. In this embodiment, the first main surface insulating film 52 includes a silicon oxide film. Specifically, the first main surface insulating film 52 is constituted of a field oxide film that contains an oxide of the semiconductor chip 2 (drift layer 7). On the other hand, the second main surface insulating film 53 includes a silicon oxide film that is different in property from the first main surface insulating film 52.

The second main surface insulating film 53 may include at least one among a BPSG (Boron and Phosphorus Silicate Glass) film, a PSG (Phosphorus Silicate Glass) film and a USG (Undoped Silicate Glass) film. The BPSG film is a silicon oxide film that contains boron and phosphorus, the PSG film is a silicon oxide film that contains phosphorus, and the USG film is a silicon oxide film that is not doped with an impurity.

The second main surface insulating film 53 may have a laminated structure in which at least one among the BPSG film, the PSG film and the USG film is laminated. The second main surface insulating film 53 may have a laminated structure which includes the PSG film and the BPSG film that are laminated in this order from the first main surface 3 side. The second main surface insulating film 53 may have a single layer structure which is constituted of the BPSG film, the PSG film or the USG film. In this embodiment, the second main surface insulating film 53 has a single layer structure that is constituted of the BPSG film.

The first main surface insulating film 52 covers an entire area of the outer region 21 (outer main surface 23) and continues to the first to fourth side surfaces 5A to 5D. The first main surface insulating film 52 continues to the separation insulating film 15 which is exposed from the outer peripheral wall 12 of the trench separation structure 10 in the outer region 21 and exposes the separation electrode 16. The first main surface insulating film 52 covers an entire area of the floating region 40 in the outer region 21 and electrically insulates the floating region 40 from outside.

The second main surface insulating film 53 covers an entire area of the first main surface insulating film 52 and continues to the first to fourth side surfaces 5A to 5D. Therefore, the second main surface insulating film 53 faces the drift layer 7 and the floating region 40 across the first main surface insulating film 52. The second main surface insulating film 53 crosses the outer peripheral wall 12 of the trench separation structure 10 and covers the upper end portion of the separation electrode 16 on the outer region 21 side such as to expose the upper end portion of the separation electrode 16 on the active region 22 side. The second main surface insulating film 53 demarcates the through hole 51 which exposes the second portion 26 of the trench separation structure 10 and the active region 22 (active main surface 24) at the portion which covers the first portion 25 of the trench separation structure 10.

The first main surface insulating film 52 has a first insulation thickness TI1. The first insulation thickness TI1 may be not less than 1000 Å and not more than 5000 Å. The first insulation thickness TI1 is preferably not less than 1500 Å and not more than 3500 Å. The second main surface insulating film 53 has a second insulation thickness TI2. The second insulation thickness TI2 may be not less than 1000 Å and not more than 6000 Å. The second insulation thickness TI2 is preferably not less than 2500 Å and not more than 4500 Å.

The semiconductor device 1 includes a Schottky electrode 60 which is formed on the first main surface 3. The Schottky electrode 60 is an anode electrode of the SBD. The Schottky electrode 60 is electrically connected to the separation electrode 16 of the trench separation structure 10 such as to retain the floating region 40 in the electrically floating state in the outer region 21. Specifically, the Schottky electrode 60 enters into the first recess R1 of the trench separation structure 10 from above the separation protrusion portion 15a of the separation insulating film 15 and is electrically connected to the separation electrode 16 inside the first recess R1.

The Schottky electrode 60 is electrically connected to the first main surface 3 and the electrode 38 of each of the trench structures 30 in the active region 22. Specifically, the Schottky electrode 60 enters into the second recess R2 of the trench structure 30 from above the protrusion portion 37a of the insulating film 37 and is electrically connected to the electrode 38 inside the second recess R2.

The Schottky electrode 60 forms a Schottky junction with the first main surface 3 in the active region 22. That is, the Schottky electrode 60 forms a Schottky junction with the active main surface 24 which is depressed to the bottom portion side of the drift layer 7 with respect to the outer main surface 23. Specifically, the Schottky electrode 60 enters into the third recess R3 from above the separation protrusion portion 15a of the separation insulating film 15 and the protrusion portion 37a of the insulating film 37 and forms the Schottky junction with each of the mesa portions 39 inside the third recess R3.

The Schottky electrode 60 refills the contact opening 27 and the through hole 51 and protrudes upper than a main surface of the main surface insulating film 50. The Schottky electrode 60 is formed at an interval on the active region 22 side from the first to fourth side surfaces 5A to 5D in plan view. In this embodiment, the Schottky electrode 60 is formed in a quadrilateral shape that has four sides which are parallel to the first to fourth side surfaces 5A to 5D.

The Schottky electrode 60 includes a main body portion 61 which covers the active region 22 and a lead-out portion 62 which covers the outer region 21. The main body portion 61 is positioned inside the contact opening 27 (through hole 51) and electrically connected to the active main surface 24, the electrode 38 of each of the trench structures 30 and the separation electrode 16 of the trench separation structure 10. The lead-out portion 62 is led out on the main surface insulating film 50 from the main body portion 61 and faces a part of the separation electrode 16 and the floating region 40 across the main surface insulating film 50.

Specifically, the lead-out portion 62 faces an entire area of the floating region 40 across the main surface insulating film 50. A peripheral edge of the lead-out portion 62 is formed at an interval on the active region 22 side from the first to fourth side surfaces 5A to 5D. The lead-out portion 62 has a lead-out width WL. The lead-out width WL is a width of the lead-out portion 62, with the wall portion of the contact opening 27 (through hole 51) given as a reference. The lead-out width WL, the region width WF may be not less than 2 μm and not more than 25 μm. The region width WF is preferably not less than 5 μm and not more than 20 μm. The lead-out width WL is preferably in excess of the region width WF of the floating region 40 (WL<WF).

The Schottky electrode 60 has a laminated structure which includes a first electrode film 63, a second electrode film 64 and a third electrode film 65 which are laminated in this order from the semiconductor chip 2 side. The first electrode film 63 is formed as a film along the active main surface 24, the separation protrusion portion 15a of the separation insulating film 15, the protrusion portion 37a of the insulating film 37, the wall portion of the contact opening 27 (through hole 51) and the main surface of the main surface insulating film 50. The first electrode film 63 includes a portion which is positioned inside the first recess R1 demarcated by the separation protrusion portion 15a on the trench separation structure 10. The first electrode film 63 is electrically connected to the separation electrode 16 inside the first recess R1.

The first electrode film 63 includes a portion which is positioned inside the second recess R2 demarcated by the protrusion portion 37a on the trench structure 30. The first electrode film 63 is electrically connected to the electrode 38 inside the second recess R2. The first electrode film 63 includes a portion which is positioned inside the third recess R3 that is demarcated by the separation protrusion portion 15a and the protrusion portion 37a on the active main surface 24. The first electrode film 63 is electrically connected to the mesa portion 39 inside the third recess R3.

The first electrode film 63 is constituted of a Schottky barrier electrode film and forms the Schottky junction with the first main surface 3. An electrode material of the first electrode film 63 is arbitrary as long as the Schottky junction can be formed with the first main surface 3. The first electrode film 63 may contain as least one among magnesium (Mg), aluminum (Al), titanium (Ti), vanadium (V), chromium (Cr), manganese (Mn), cobalt (Co), nickel (Ni), copper (Cu), zirconium (Zr), niobium (Nb), molybdenum (Mo), palladium (Pd), silver (Ag), indium (In), tin (Sn), tantalum (Ta), tungsten (W), platinum (Pt) and

The first electrode film 63 may be constituted of an alloy film which contains at least one among the above-described metals. In this embodiment, the first electrode film 63 has a single layer structure that is constituted of a molybdenum film. The first electrode film 63 has a first electrode thickness TE1. The first electrode thickness TE1 may be not less than 50 Å and not more than 1000 Å. The first electrode thickness TE1 is preferably not less than 250 Å and not more than 500 Å. The first electrode thickness TE1 is preferably less than the thickness of the separation insulating film 15. The first electrode thickness TE1 is preferably less than the thickness of the insulating film 37. The first electrode thickness TE1 is preferably less than a protrusion extent of the separation protrusion portion 15a and a protrusion extent of the protrusion portion 37a of the insulating film 37.

The second electrode film 64 is formed as a film along the active main surface 24, the separation protrusion portion 15a of the separation insulating film 15, the protrusion portion 37a of the insulating film 37, the wall portion of the contact opening 27 (through hole 51) and the main surface of the main surface insulating film 50 on the first electrode film 63. The second electrode film 64 includes a portion which is positioned inside the first recess R1 demarcated by the separation protrusion portion 15a on the trench separation structure 10. The second electrode film 64 is electrically connected to the separation electrode 16 across the first electrode film 63 inside the first recess R1. The second electrode film 64 refills the first recess R1 and faces the separation protrusion portion 15a across the first electrode film 63.

The second electrode film 64 includes a portion which is positioned inside the second recess R2 demarcated by the protrusion portion 37a on the trench structure 30. The second electrode film 64 is electrically connected to the electrode 38 across the first electrode film 63 inside the second recess R2. The second electrode film 64 refills the second recess R2 and faces the protrusion portion 37a across the first electrode film 63.

The second electrode film 64 includes a portion which is positioned inside the third recess R3 demarcated by the separation protrusion portion 15a and the protrusion portion 37a on the active main surface 24. The second electrode film 64 is electrically connected to the mesa portion 39 across the first electrode film 63 inside the third recess R3. The second electrode film 64 refills the third recess R3 and faces the separation protrusion portion 15a and the protrusion portion 37a across the first electrode film 63.

The second electrode film 64 is constituted of a metal barrier film. In this embodiment, the second electrode film 64 is constituted of a Ti-based metal film. The second electrode film 64 includes at least one of a titanium (Ti) film and a titanium nitride (TiN) film. The second electrode film 64 may have a single layer structure which is constituted of a titanium film or a titanium nitride film or a laminated structure which includes a titanium film and a titanium nitride film in any given order.

In this embodiment, the second electrode film 64 has a single layer structure which is constituted of a titanium nitride film. The second electrode film 64 has a second electrode thickness TE2. The second electrode thickness TE2 may be not less than 500 Å and not more than 5000 Å. The second electrode thickness TE2 is preferably not less than 1500 Å and not more than 4500 Å. The second electrode thickness TE2 is preferably in excess of the first electrode thickness TE1 (TE1<TE2). The second electrode thickness TE2 is preferably in excess of the protrusion extent of the separation protrusion portion 15a and the protrusion extent of the protrusion portion 37a of the insulating film 37.

The third electrode film 65 is formed as a film along the main surface of the second electrode film 64. The third electrode film 65 faces the active main surface 24, the separation protrusion portion 15a of the separation insulating film 15, the protrusion portion 37a of the insulating film 37, the wall portion of the contact opening 27 (through hole 51) and the main surface of the main surface insulating film 50 across the first electrode film 63 and the second electrode film 64. The third electrode film 65 is in its entirety positioned upper than the separation protrusion portion 15a and the protrusion portion 37a. That is, the third electrode film 65 is positioned in its entirety outside the first recess R1 demarcated by the separation protrusion portion 15a, the second recess R2 demarcated by the protrusion portion 37a and the third recess R3 demarcated by the protrusion portion 37a.

The third electrode film 65 may be a terminal electrode (pad electrode) which is to be externally connected by a conductive wire (for example, bonding wire). The third electrode film 65 is constituted of a Cu-based metal film or an Al-based metal film. The third electrode film 65 may include at least one among a pure Cu film (Cu film with purity of not less than 99%), a pure Al film (Al film with purity of not less than 99%) an AlCu alloy film, an AlSi alloy film and an AlSiCu alloy film. In this embodiment, the third electrode film 65 has a single layer structure which is constituted of an AlCu alloy film.

The third electrode film 65 has a third electrode thickness TE3. The third electrode thickness TE3 may be not less than 0.5 μm (=5000 Å) and not more than 10 μm (=100000 Å). The third electrode thickness TE3 is preferably not less than 2.5 μm and not more than 7.5 μm. The third electrode thickness TE3 is preferably in excess of the first electrode thickness TE1 and the second electrode thickness TE2 (TE1<TE3, TE2<TE3). It is particularly preferable that the third electrode thickness TE3 is in excess of a sum (TE1+TE2) of the first electrode thickness TE1 and the second electrode thickness TE2 (TE1+TE2<TE3).

The semiconductor device 1 includes an upper insulating film 70 which is formed on the main surface insulating film 50 such as to cover the Schottky electrode 60. In this embodiment, the upper insulating film 70 has a single layer structure which is constituted of an inorganic insulating film. The upper insulating film 70 is preferably constituted of an insulator different from that of the main surface insulating film 50. The upper insulating film 70 preferably includes at least one of a silicon nitride (SiN) film and a silicon oxynitride (SiON) film. In this embodiment, the upper insulating film 70 has a single layer structure which is constituted of a silicon oxynitride film.

The upper insulating film 70 is formed as a film along the main surface of the main surface insulating film 50, a side wall of the Schottky electrode 60 and the main surface of the Schottky electrode 60. Thereby, the upper insulating film 70 has a first covering portion 71 which covers the Schottky electrode 60 and a second covering portion 72 which covers the main surface insulating film 50. The first covering portion 71 covers a part of the main body portion 61 of the Schottky electrode 60 and an entire area of the lead-out portion 62 of the Schottky electrode 60.

The first covering portion 71 has a pad opening 73 which exposes a central portion of the main body portion 61 of the Schottky electrode 60. The first covering portion 71 faces the trench separation structure 10 and the floating region 40 across the Schottky electrode 60 with regard to the normal direction Z. The first covering portion 71 preferably faces at least one of the trench structures 30 across the Schottky electrode 60. That is, the upper insulating film 70 (first covering portion 71) preferably overlaps the trench separation structure 10, the floating region 40 and the trench structure 30 in plan view. In this embodiment, the upper insulating film 70 faces an entire area of the trench separation structure 10 and an entire area of the floating region 40 in plan view.

The second covering portion 72 covers the main surface insulating film 50 at an interval on the active region 22 side from the first to fourth side surfaces 5A to 5D in plan view. In this embodiment, the second covering portion 72 covers the main surface insulating film 50 at an interval from the floating region 40 to the outside (first to fourth side surfaces 5A to 5D side) in plan view. In this embodiment, the second covering portion 72 is formed in a quadrilateral shape having four sides which are parallel to the first to fourth side surfaces 5A to 5D.

The second covering portion 72 demarcates a dicing street 74 which exposes a peripheral edge portion of the main surface insulating film 50 with the first to fourth side surfaces 5A to 5D. The drift layer 7 is positioned directly under the dicing street 74 and the floating region 40 is not arranged. A width of the dicing street 74 may be not less than 10 μm and not more than 50 μm. The width of the dicing street 74 is a width in a direction orthogonal to a direction in which the dicing street 74 extends.

The upper insulating film 70 has a third insulation thickness TI3. The third insulation thickness TI3 is preferably in excess of the first insulation thickness TI1 of the first main surface insulating film 52 (TI1<TI3). The third insulation thickness TI3 is preferably in excess of the second insulation thickness TI2 of the second main surface insulating film 53 (TI2<TI3). The third insulation thickness TI3 is preferably in excess of a sum of the first insulation thickness TI1 and the second insulation thickness TI2 (TI1+TI2<TI3).

Further, the third insulation thickness TI3 is preferably in excess of the first electrode thickness TE1 of the first electrode film 63 (TE1<TI3). The third insulation thickness TI3 is preferably in excess of the second electrode thickness TE2 of the second electrode film 64 (TE2<TI3). The third insulation thickness TI3 is preferably in excess of a sum of the first electrode thickness TE1 and the second electrode thickness TE2 (TE1+TE2<TI3). The third insulation thickness TI3 is preferably less than the third electrode thickness TE3 of the third electrode film 65 (TE3>TI3). The third insulation thickness TI3 may be not less than 0.2 μm (=2000 Å) and not more than 1.5 μm (=15000 Å). The third insulation thickness TI3 is preferably not less than 0.6 μm and not more than 1.2 μm.

The semiconductor device 1 includes a cathode electrode 80 which covers the second main surface 4. The cathode electrode 80 covers an entire area of the second main surface 4 and continues to the first to fourth side surfaces 5A to 5D. The cathode electrode 80 is electrically connected to the cathode layer 6. Specifically, the cathode electrode 80 forms an ohmic contact with the cathode layer 6 (second main surface 4). The cathode electrode 80 has a laminated structure which includes a titanium film 81, a nickel film 82 and a gold film 83 laminated in this order from the second main surface 4 side.

The titanium film 81 may have a thickness which is not less than 500 Å and not more than 2000 Å. The nickel film 82 preferably has a thickness in excess of the thickness of the titanium film 81. The nickel film 82 may have a thickness which is not less than 2000 Å and not more than 6000 Å. The gold film 83 preferably has a thickness which is less than the thickness of the nickel film 82. It is particularly preferable that the gold film 83 has a thickness which is less than the thickness of the titanium film 81. The gold film 83 may have a thickness which is not less than 100 Å and not more than 1000 Å. The cathode electrode 80 may also include a palladium film interposed between the nickel film 82 and the gold film 83.

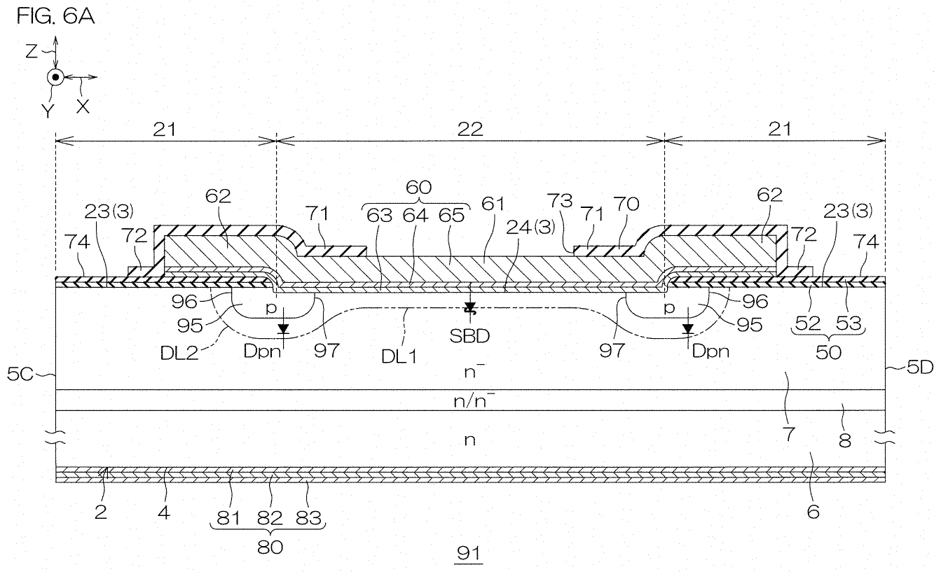

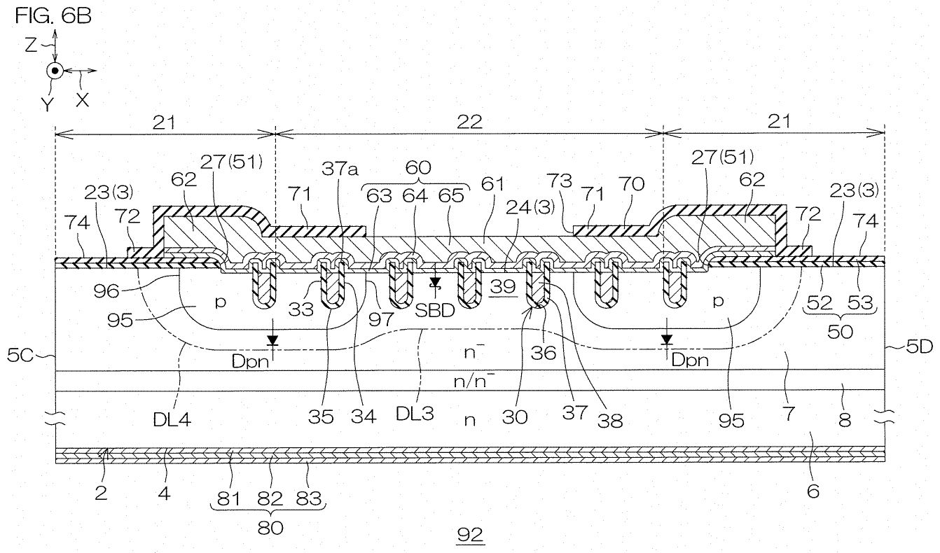

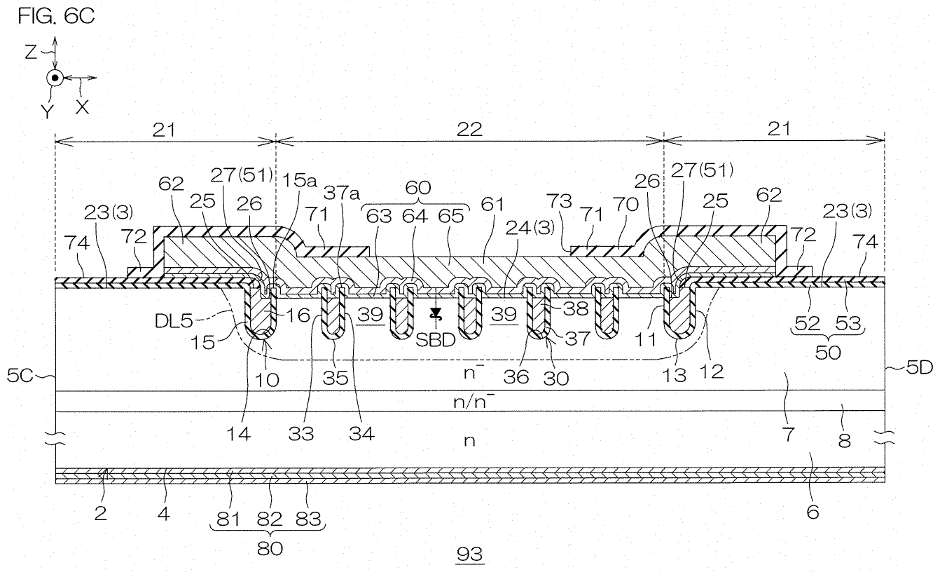

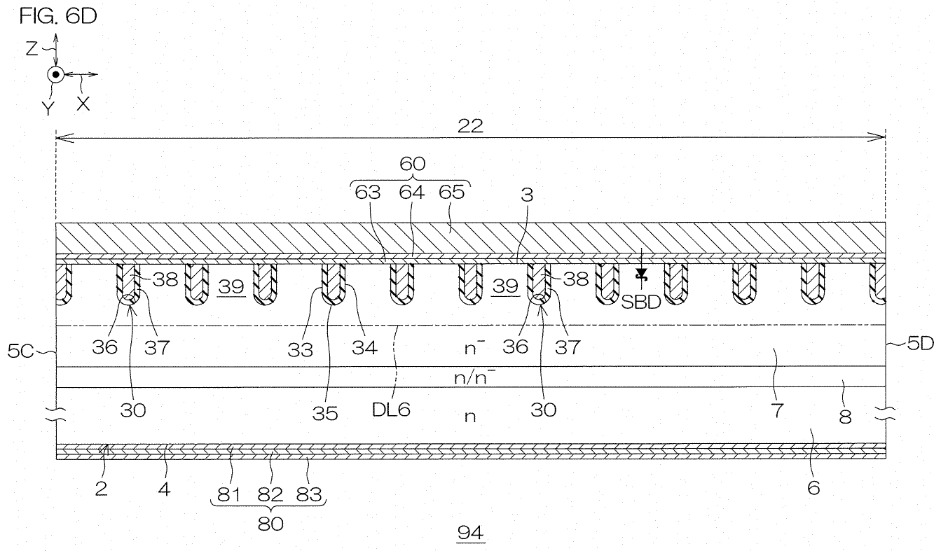

Next, a description regarding the electrical characteristics of the semiconductor device 1 according to the first embodiment will be given. In order to examine the characteristics of the semiconductor device 1 according to the first embodiment, semiconductor devices 91 to 94 according to first to the fourth reference embodiments shown in FIG. 6A to FIG. 6D have been manufactured. Hereinafter, after a sequential description of structures of the semiconductor devices 91 to 94 according to the first to the fourth reference embodiments, there will be shown the electrical characteristics of the semiconductor device 1 according to the first embodiment and those of the semiconductor devices 91 to 94 according to the first to the fourth reference embodiments.

FIG. 6A is a cross-sectional view which shows the semiconductor device 91 according to the first reference embodiment. Hereinafter, a structure corresponding to the structure described in the semiconductor device 1 will be given the same reference number, with a description thereof omitted. With reference to FIG. 6A, the semiconductor device 91 according to the first reference embodiment does not have a trench separation structure 10, a plurality of trench structures 30 and a floating region 40.

The semiconductor device 91 according to the first reference embodiment includes a p-type guard region 95 which is formed at a surface layer portion of a first main surface 3. Specifically, the guard region 95 is formed internally at an interval from first to fourth side surfaces 5A to 5D and formed in an annular shape which surrounds a central portion of the first main surface 3 (in this embodiment, in a quadrilateral annular shape). Thereby, the guard region 95 is formed as a guard ring region.

The guard region 95 demarcates an outer region 21 (outer main surface 23) and an active region 22 (active main surface 24) by an inner peripheral edge in the first main surface 3. In this embodiment, the active main surface 24 of the active region 22 is further depressed to the bottom portion side of a drift layer 7 with respect to the outer main surface 23. The guard region 95 includes an outer portion 96 on the outer region 21 side and an inner portion 97 on the active region 22 side.

In the guard region 95, the inner portion 97 is positioned on the bottom portion side of the drift layer 7 with respect to the outer portion 96. In this embodiment, the inner portion 97 is further depressed to the bottom portion side of the drift layer 7 with respect to the outer portion 96 and continues to the active main surface 24. The outer portion 96 and the inner portion 97 of the guard region 95 demarcate a contact opening 27 which is dug down to the bottom portion side of the drift layer 7 from the outer main surface 23 with the active main surface 24.

The main surface insulating film 50 cover the outer portion 96 of the guard region 95 and covers the outer region 21 (outer main surface 23) such as to expose the inner portion 97 of the guard region 95. The through hole 51 of the main surface insulating film 50 is communicatively connected to the contact opening 27 to expose the inner portion 97 of the guard region 95 and the active region 22 (active main surface 24).

The Schottky electrode 60 enters into the contact opening 27 (through hole 51) from above the main surface insulating film 50. The Schottky electrode 60 is electrically connected to the first main surface 3 and the inner portion 97 of the guard region 95 inside the contact opening 27 (through hole 51). The Schottky electrode 60 forms the Schottky junction with the first main surface 3. Thereby, a pn-junction diode Dpn is formed in the outer region 21 and the active region 22, and the SBD is formed in the active region 22.

FIG. 6B is a cross-sectional view which shows the semiconductor device 92 according to the second reference embodiment. Hereinafter, a structure corresponding to the structure described in the semiconductor device 1 will be given the same reference number, with a description thereof omitted. With reference to FIG. 6B, the semiconductor device 92 according to the second reference embodiment does not have the trench separation structure 10 and the floating region 40.

The semiconductor device 92 according to the second reference embodiment has a combination structure which includes the plurality of trench structures 30 according to the first embodiment and the guard region 95 according to the first reference embodiment. As with the first embodiment, the plurality of trench structures 30 may be arrayed in a stripe shape extending in the second direction Y. In each of the trench structures 30, the protrusion portion 37a of the insulating film 37 may be formed in an annular shape (specifically, quadrilateral annular shape) extending along the wall surface of the trench 36 such as to separate the electrode 38 and the active main surface 24 in plan view.

The guard region 95 is formed in an annular shape (in this embodiment, a quadrilateral annular shape) which surrounds the central portion of the first main surface 3 in plan view. The guard region 95 (inner portion) covers both end portions of the plurality of trench structures 30 and at least one (in this embodiment, two positioned at an outermost area) of the trench structures 30.

The Schottky electrode 60 enters into the contact opening 27 (through hole 51) from above the main surface insulating film 50. In this embodiment, the Schottky electrode 60 is electrically connected to the first main surface 3, the electrode 38 of each of the trench structures 30 and the inner portion 97 of the guard region 95 inside the contact opening 27 (through hole 51). The Schottky electrode 60 forms the Schottky junction with the first main surface 3. Thereby, the pn-junction diode Dpn is formed in the outer region 21 and the active region 22, and the SBD is formed in the active region 22.

FIG. 6C is a cross-sectional view which shows the semiconductor device 93 according to the third reference embodiment. Hereinafter, a structure corresponding to the structure described in the semiconductor device 1 will be given the same reference number, with a description thereof omitted. With reference to FIG. 6C, the semiconductor device 93 according to the third reference embodiment has a structure in which the floating region 40 is removed from the semiconductor device 1 according to the first embodiment.

FIG. 6D is a cross-sectional view which shows the semiconductor device 94 according to the fourth reference embodiment. Hereinafter, a structure corresponding to the structure described in the semiconductor device 1 will be given the same reference number, with a description thereof omitted. With reference to FIG. 6D, the semiconductor device 94 according to the fourth reference embodiment does not have the trench separation structure 10, the floating region 40, the main surface insulating film 50 and the upper insulating film 70.

In the semiconductor device 94 according to the fourth reference embodiment, the trench structures 30 are formed at an equal interval in an entire area of the first main surface 3. The plurality of trench structures 30 are arrayed in a stripe shape extending in the second direction Y. The trench structures 30 are exposed from first to fourth side surfaces 5A to 5D. Specifically, electrodes 38 of the two trench structures 30 positioned at both ends in the first direction X are each exposed from the third side surface 5C and the fourth side surface 5D. Further, although not specifically illustrated, the electrodes 38 of the trench structures 30 are each exposed from the first side surface 5A and the second side surface 5B.

The Schottky electrode 60 covers an entire area of the first main surface 3 and continues to the first to fourth side surfaces 5A to 5D. The Schottky electrode 60 is electrically connected to the electrode 38 of each of the trench structures 30 and the first main surface 3. The Schottky electrode 60 forms the Schottky junction with the first main surface 3. That is, the semiconductor device 94 according to the fourth reference embodiment does not have the outer region 21 but has the active region 22 which is formed in an entire area of the first main surface 3.

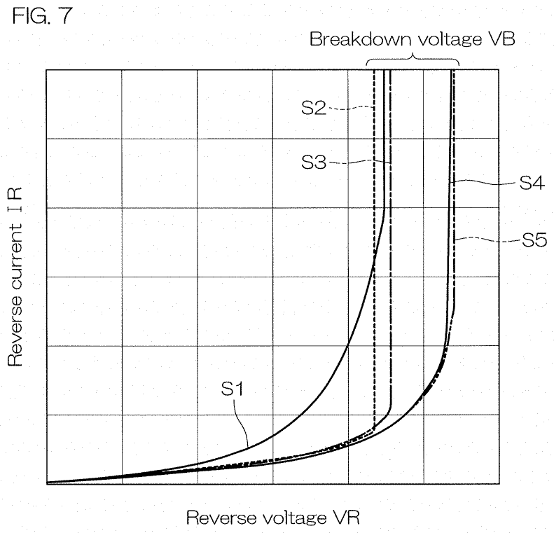

FIG. 7 is a graph which examines a relationship between a reverse current IR and a reverse voltage VR by simulation. In FIG. 7, a vertical axis indicates the reverse current IR, and a horizontal axis indicates the reverse voltage VR. The reverse current IR is also referred to as a leakage current. The reverse voltage VR in which the reverse current IR increases abruptly is referred to as a breakdown voltage VB. The breakdown voltage VB is a device withstand voltage. The lower the reverse current IR is and the higher the breakdown voltage VB is, the better the device characteristics.

FIG. 7 shows first to fifth characteristics of S1 to S5. The first characteristics S1 indicate the characteristics of the semiconductor device 91 according to the first reference embodiment. The second characteristics S2 indicate the characteristics of the semiconductor device 92 according to the second reference embodiment. The third characteristics S3 indicate the characteristics of the semiconductor device 93 according to the third reference embodiment. The fourth characteristics S4 indicate the characteristics of the semiconductor device 94 according to the fourth reference embodiment. The fifth characteristics S5 indicate the characteristics of the semiconductor device 1 according to the first embodiment.

The characteristics of the reverse currents IR are improved in an ascending order of the first characteristics S1 (first reference embodiment), the second characteristics S2 (second reference embodiment), the third characteristics S3 (third reference embodiment) and the fourth characteristics S4 (fourth reference embodiment). The characteristics of the breakdown voltages VB are also improved in an ascending order of the first characteristics S1, the second characteristics S2, the third characteristics S3 and the fourth characteristics S4.

The characteristics of the reverse current IR of the fifth characteristics S5 (first embodiment) are improved to a greater extent than the characteristics of the reverse currents IR of the first to third characteristics S1 to S3 (first to third reference embodiments) and substantially coincided with the characteristics of the reverse current IR of the fourth characteristics S4 (fourth reference embodiment). The characteristics of the breakdown voltage VB of the fifth characteristics S5 are improved to a greater extent than the characteristics of the breakdown voltages VB of the first to third characteristics S1 to S3 and substantially coincided with the characteristics of the breakdown voltage VB of the fourth characteristics S4.

Again with reference to FIG. 6A, in the semiconductor device 91 according to the first reference embodiment, where the reverse voltage VR is applied between the Schottky electrode 60 and the cathode electrode 80, a depletion layer DL1 expands from the active region 22. Specifically, the depletion layer DL1 which expands from the active region 22 expands in a depth direction and a width direction of the drift layer 7, with a boundary between the Schottky electrode 60 and the first main surface 3 given as a starting point. Further, in the drift layer 7, a depletion layer DL2 expands from the guard region 95.

The depletion layer DL2 which expands from the guard region 95 is made integral with the depletion layer DL1 in a mode that the depletion layer DL1 expanding from the active region 22 is enlarged toward the outer region 21 (refer to the double chain line in FIG. 6A). A terminal portion of the depletion layer DL2 is positioned in the outer region 21 (outer main surface 23) at an interval from the first to fourth side surfaces 5A to 5D to the guard region 95 side. In the semiconductor device 91 according to the first reference embodiment, an electric field concentration at a peripheral edge portion of the active region 22 (trench separation structure 10) is relaxed by the depletion layer DL1 and the depletion layer DL2.

However, in the semiconductor device 91 according to the first reference embodiment, in view of the structure in which the depletion layer DL1 expands, with the interface between the Schottky electrode 60 and the first main surface 3 given as a starting point, an electric field intensity (current density) is easily increased at the surface layer portion of the first main surface 3. Further, in the semiconductor device 91 according to the first reference embodiment, the pn-junction diode Dpn is formed in the drift layer 7 by the guard region 95 which is electrically connected to the Schottky electrode 60. As a result, as shown in the first characteristics Si, the reverse current IR is increased and the breakdown voltage VB of the SBD is also limited by the breakdown voltage VB of the pn-junction diode Dpn.

Again, with reference to FIG. 6B, in the semiconductor device 92 according to the second reference embodiment, where the reverse voltage VR is applied between the Schottky electrode 60 and the cathode electrode 80, a depletion layer DL3 expands from the active region 22. Specifically, the depletion layer DL3 which expands from the active region 22 expands in a depth direction and a width direction of the drift layer 7, with the plurality of trench structures 30 given as a starting point. Further, in the drift layer 7, a depletion layer DL4 expands from the guard region 95.

The depletion layer DL4 which expands from the guard region 95 is made integral with the depletion layer DL3 in a mode that the depletion layer DL3 which expands from the active region 22 is enlarged to the outer region 21 (refer to the double chain line in FIG. 6B). A terminal portion of the depletion layer DL4 is positioned in the outer region 21 (outer main surface 23) at an interval from the first to fourth side surfaces 5A to 5D to the guard region 95 side. As a result, the electric field concentration at the peripheral edge portion of the active region 22 (trench separation structure 10) is relaxed.

In the semiconductor device 92 according to the second reference embodiment, since the depletion layer DL4 expands, with the plurality of trench structures 30 (particularly, bottom wall 35) given as a starting point, it is possible to relax the electric field intensity at the surface layer portion of the first main surface 3. However, in the semiconductor device 92 according to the second reference embodiment, the pn-junction diode Dpn is formed in the drift layer 7 by the guard region 95 which is electrically connected to the Schottky electrode 60. As a result, as shown in the second characteristics S2, although the reverse current IR can be suppressed, the breakdown voltage VB of the SBD is limited by the breakdown voltage VB of the pn-junction diode Dpn.

Again, with reference to FIG. 6C, in the semiconductor device 93 according to the third reference embodiment, where the reverse voltage VR is applied between the Schottky electrode 60 and the cathode electrode 80, a depletion layer DL5 expands from the active region 22. Specifically, the depletion layer DL5 which expands from the active region 22 expands in a depth direction and a width direction of the drift layer 7, with the plurality of trench structures 30 given as a starting point.

In the semiconductor device 93 according to the third reference embodiment, since the depletion layer DL5 expands, with the plurality of trench structures 30 (particularly, bottom wall 35) given as a starting point, it is possible to relax the electric field intensity at the surface layer portion of the first main surface 3. However, the depletion layer DL5 which expands from the active region 22 decreases abruptly at the peripheral edge portion of the active region 22 with the trench separation structure 10 given as a turning point (refer to the double chain line in FIG. 6C). That is, an electric field concentrates locally at the trench separation structure 10. As a result, as shown in the third characteristics S3, although the reverse current IR can be suppressed, the breakdown voltage VB is lowered.

Again, with reference to FIG. 6D, in the semiconductor device 94 according to the fourth reference embodiment, where the reverse voltage VR is applied between the Schottky electrode 60 and the cathode electrode 80, a depletion layer DL6 expands from the active region 22. Specifically, the depletion layer DL6 which expands from the active region 22 expands in a depth direction and a width direction of the drift layer 7, with the plurality of trench structures 30 given as a starting point.

In the semiconductor device 94 according to the fourth reference embodiment, the plurality of trench structures 30 are formed at an equal interval in an entire area of the first main surface 3 and, therefore, with the plurality of trench structure 30 (particularly, bottom wall 35) given as a starting point, the depletion layer DL6 which is uniform in thickness is formed inside the drift layer 7 (refer to the double chain line in FIG. 6D). As a result, as shown in the fourth characteristics S4, it is possible to suppress the reverse current IR and also improve the breakdown voltage VB.

The semiconductor device 94 according to the fourth reference embodiment has the most desirable mode in terms of characteristics of the reverse current IR and characteristics of the breakdown voltage VB. However, in the semiconductor device 94 according to the fourth reference embodiment, in view of the structure in which the plurality of trench structures 30 are exposed from the first to fourth side surfaces 5A to 5D and the Schottky electrode 60 continues to the first to fourth side surfaces 5A to 5D, it is impossible to secure an insulation distance between the first to fourth side surfaces 5A to 5D and the Schottky electrode 60. Therefore, such a problem is found that a discharge phenomenon (creeping discharge phenomenon) occurs between the first to fourth side surfaces 5A to 5D and the Schottky electrode 60.

In order to avoid the above problem, in the semiconductor devices 91 to 94 according to the first to third reference embodiments and the semiconductor device 1 according to the first embodiment, the outer region 21 and the active region 22 are provided, thereby separating the plurality of trench structures 30 and the Schottky electrode 60 each from the first to fourth side surfaces 5A to 5D to the inner portion side of the semiconductor chip 2. Further, the main surface insulating film 50 is interposed between a peripheral edge of the Schottky electrode 60 and the first to fourth side surfaces 5A to 5D.

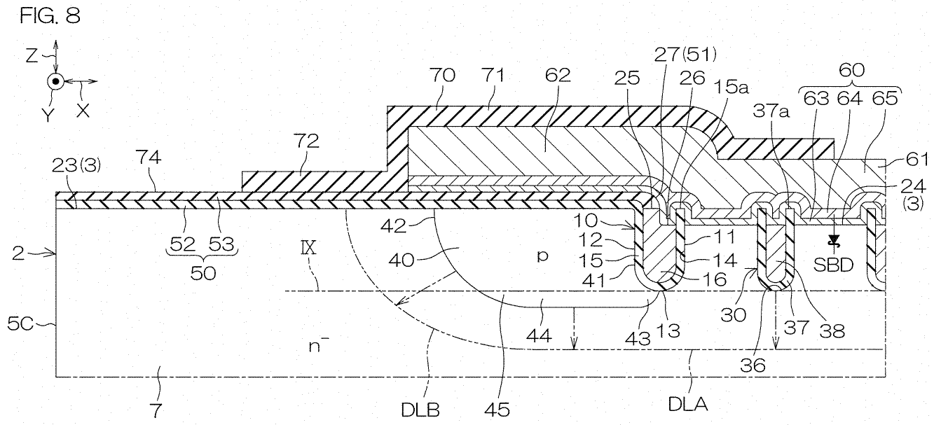

FIG. 8 corresponds to FIG. 5 and is a drawing for describing depletion layers DLA, DLB which are formed inside the drift layer 7. With reference to FIG. 8, in the semiconductor device 1, where the reverse voltage VR is applied between the Schottky electrode 60 and the cathode electrode 80, the depletion layer DLA expands from the active region 22. Specifically, the depletion layer DLA which expands from the active region 22 expands in a depth direction and a width direction of the drift layer 7, with the plurality of trench structures 30 given as a starting point.

Further, in the drift layer 7, the depletion layer DLB expands also from the floating region 40. The depletion layer DLB which expands from the floating region 40 is made integral with the depletion layer DLA in a mode that the depletion layer DLA which expands from the active region 22 is enlarged to the outer region 21 (refer to the double chain line in FIG. 8). A terminal portion of the depletion layer DLB is positioned in the outer region 21 (outer main surface 23) at an interval from the first to fourth side surfaces 5A to 5D to the floating region 40 side.

In the semiconductor device 1, since the depletion layer DLA expands, with the plurality of trench structures 30 (particularly, bottom wall 35) given as a starting point, it is possible to relax the electric field intensity at the surface layer portion of the first main surface 3. Further, in the semiconductor device 1, since the depletion layer DLA at the peripheral edge portion of the active region 22 is enlarged by the depletion layer DLB which expands from the floating region 40, the electric field intensity at the peripheral edge portion of the active region 22 is relaxed by the floating region 40.

Further, the floating region 40 is formed in the electrically floating state and, therefore, does not form a pn-junction (that is, pn-junction diode Dpn) with the drift layer 7. Therefore, the breakdown voltage VB of the SBD is not limited by the breakdown voltage VB of the pn-junction diode Dpn. Thereby, as shown in the fifth characteristics S5, it is possible to suppress the reverse current IR and improve the breakdown voltage VB.

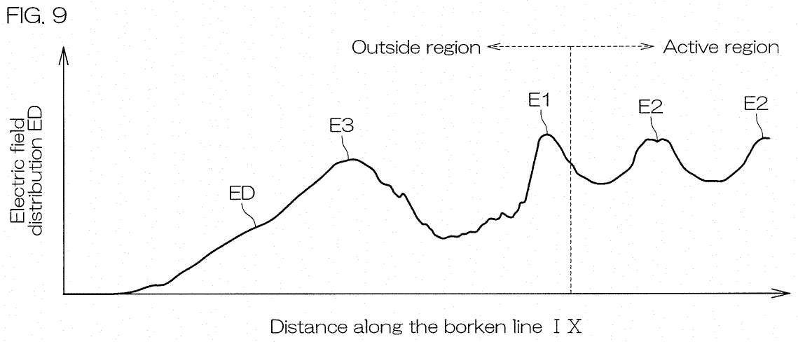

FIG. 9 is a graph in which an electric field distribution ED along a broken-line portion IX shown in FIG. 8 is examined by simulation. The broken-line portion IX crosses a depth position of the bottom wall 13 of the trench separation structure 10 in the first direction X. The electric field distribution ED is examined by applying the reverse voltage VR between the Schottky electrode 60 and the cathode electrode 80.

With reference to FIG. 9, the electric field distribution ED has a plurality of peaks (maximum values). The plurality of peaks indicate a first electric field intensity E1 which is applied to the bottom wall 13 of the trench separation structure 10, a second electric field intensity E2 which is applied to the bottom wall 35 of each of the plurality of trench structures 30 and a third electric field intensity E3 which is applied to the outer peripheral edge 42 of the floating region 40. The first to third electric field intensities E1 to E3 are substantially equal to each other (E1≈E2≈E3).

As described above, in the drift layer 7, the first to third electric field intensities E1 to E3 (that is, peaks of electric field intensity) are substantially uniformly distributed, and an abrupt increase in any one of the first to third electric field intensities E1 to E3 is suppressed. That is, in the drift layer 7, a local electric field concentration at the trench separation structure 10, the plurality of trench structures 30 and the floating region 40 is suppressed.

The first electric field intensity E1 is adjusted by changing the first width W1 and the first depth D1 of the trench separation structure 10, the thickness of the separation insulating film 15, the volume of the separation electrode 16, etc. The second electric field intensity E1 is adjusted by changing the second width W2 and the second depth D2 of the trench structure 30, the thickness of the insulating film 37, the volume of the electrode 38, etc. The third electric field intensity E3 is adjusted by changing the p-type impurity concentration, the region width WF and the region thickness TF of the floating region 40, etc.

As described above, the semiconductor device 1 includes the drift layer 7 (semiconductor layer) of n-type, the trench separation structure 10, the floating region 40 of p-type and the Schottky electrode 60. The drift layer 7 has the first main surface 3. The trench separation structure 10 includes the separation trench 14 which is formed in the first main surface 3, the separation insulating film 15 which covers the wall surface of the separation trench 14 and the separation electrode 16 which is embedded in the separation trench 14 across the separation insulating film 15.

The trench separation structure 10 demarcates the outer region 21 and the active region 22 in the first main surface 3. The floating region 40 is formed in the electrically floating state at the surface layer portion of the first main surface 3 along the trench separation structure 10 in the outer region 21. The Schottky electrode 60 is electrically connected to the separation electrode 16 such as to retain the floating region 40 in the electrically floating state in the outer region 21 and forms the Schottky junction with the first main surface 3 in the active region 22.

According to this structure, it is possible to relax the electric field intensity at the peripheral edge portion of the active region 22 by the depletion layer DLB which expands from the floating region 40. Further, the floating region 40 is formed in the electrically floating state and, thus, does not form a pn-junction (that is, pn-junction diode Dpn) with the drift layer 7. Therefore, it is possible to suppress the breakdown voltage VB of the SBD from being limited by the breakdown voltage VB of the pn-junction diode Dpn. It is thereby possible to suppress the reverse current IR, with the peripheral edge portion of the active region 22 given as a starting point, and also suppress a decrease in breakdown voltage VB (that is, device withstand voltage).

The floating region 40 is preferably adjacent to the trench separation structure 10 in the outer region 21. The floating region 40 is preferably formed in a depth range between the first main surface 3 and the bottom wall 13 of the trench separation structure 10 in the outer region 21. The floating region 40 is preferably formed deeper than the trench separation structure 10. The floating region 40 preferably covers the bottom wall 13 of the trench separation structure 10. The floating region 40 preferably covers the bottom wall 13 of the trench separation structure 10 at an interval from the active region 22 to the outer region 21 side in plan view. According to the above-described structures, it is possible to appropriately suppress the electric field concentration at the trench separation structure 10.

The trench separation structure 10 is preferably formed in an annular shape having the inner peripheral wall 11 and the outer peripheral wall 12 in plan view and demarcates the outer region 21 and the active region 22 by the inner peripheral wall 11. In this case, the floating region 40 is preferably formed along the outer peripheral wall 12 of the trench separation structure 10 in the outer region 21.

According to this structure, it is possible to suppress the electric field concentration at the trench separation structure 10 (peripheral edge portion of active region 22) along a circumferential direction of the trench separation structure 10 (active region 22). In this case, the floating region 40 preferably surrounds the trench separation structure 10 in plan view. According to this structure, it is possible to appropriately suppress the electric field concentration at the trench separation structure 10 (peripheral edge portion of active region 22) in an entire area of the active region 22 in the circumferential direction.

The Schottky electrode 60 is preferably connected to a portion of the separation electrode 16 on the active region 22 side such as to expose a portion of the separation electrode 16 on the outer region 21 side. According to this structure, it is possible to appropriately suppress the Schottky electrode 60 from being electrically connected to the floating region 40. It is thereby possible to appropriately suppress the pn-junction diode Dpn from being formed between the drift layer 7 and the floating region 40. As a result, it is possible to appropriately suppress the breakdown voltage VB from being limited by the pn-junction diode Dpn.

The first main surface 3 (that is, active main surface 24) inside the active region 22 may be depressed in a thickness direction (bottom portion side of drift layer 7) of the drift layer 7 with respect to the first main surface 3 (that is, outer main surface 23) inside the outer region 21. In this case, the trench separation structure 10 may include the first portion 25 which is positioned on the outer region 21 side and the second portion 26 which is positioned on the active region 22 side with respect to the first portion 25 and depressed in a thickness direction of the drift layer 7 with respect to the first portion 25. The trench separation structure 10 may demarcate the contact opening 27 which is dug down to the bottom portion side of the drift layer 7 from the outer main surface 23 with the first main surface 3 inside the active region 22.

It is preferable that the semiconductor device 1 further includes the main surface insulating film 50 which is formed on the outer region 21 such as to cover an entire area of the floating region 40. According to this structure, the floating region 40 can be electrically insulated from outside by the main surface insulating film 50. In this case, the main surface insulating film 50 preferably covers a portion of the separation electrode 16 on the outer region 21 side such as to expose a portion of the separation electrode 16 on the active region 22 side. According to this structure, the floating region 40 can be electrically insulated from outside appropriately, while a contact portion with the separation electrode 16 is secured.

The main surface insulating film 50 preferably has a wall portion which demarcates the through hole 51 that exposes the active region 22 on the separation electrode 16. In this case, the Schottky electrode 60 is preferably electrically connected to the first main surface 3 and the separation electrode 16 inside the through hole 51. The Schottky electrode 60 preferably has the lead-out portion 62 which is led out from the active region 22 on the main surface insulating film 50 and faces a part of the separation electrode 16 and the floating region 40 across the main surface insulating film 50. The lead-out portion 62 preferably faces an entire area of the floating region 40 across the main surface insulating film 50.

The semiconductor device 1 preferably includes the plurality of trench structures 30 which are formed at an interval on the first main surface 3 in the active region 22. The plurality of trench structures 30 each include the trench 36, the insulating film 37 and the electrode 38. The trench 36 is formed in the first main surface 3. The insulating film 37 covers the wall surface of the trench 36. The electrode 38 is embedded in the trench 36 across the insulating film 37. In this case, the Schottky electrode 60 is electrically connected to the electrode 38 of each of the trench structures 30 in the active region 22 and forms the Schottky junction with the first main surface 3.

According to this structure, the depletion layer DLA expands in the depth direction and the width direction of the drift layer 7 in the active region 22, with the plurality of trench structures 30 (particularly, bottom wall 35) given as a starting point. The depletion layer DLB which expands from the floating region 40 is made integral with the depletion layer DLA in a mode that the depletion layer DLA which expands from the active region 22 is enlarged to the outer region 21 (refer to the double chain line in FIG. 8). Therefore, it is possible to suppress an abrupt decrease in depletion layer DLA which expands from the active region 22 at the peripheral edge portion of the active region 22 by the floating region 40, with the trench separation structure 10 given as a turning point.

It is thereby possible to relax the electric field intensity at the surface layer portion of the first main surface 3 inside the active region 22. It is also possible to relax the electric field intensity at the surface layer portion of the first main surface 3 in the peripheral edge portion of the active region 22. As a result, it is possible to relax the electric field concentration at the surface layer portion of the first main surface 3 inside and outside the active region 22. Thus, it is possible to appropriately suppress the reverse current IR and appropriately improve the breakdown voltage VB (also referred to as the fifth characteristics S5 in FIG. 7).

The trench separation structure 10 is preferably formed wider than the trench structure 30. According to this structure, it is possible to reduce influences of a process error occurring in the trench separation structure 10. Thereby, the Schottky electrode 60 can be appropriately connected to the trench separation structure 10. In this case, the trench structure 30 may be formed shallower than the trench separation structure 10.

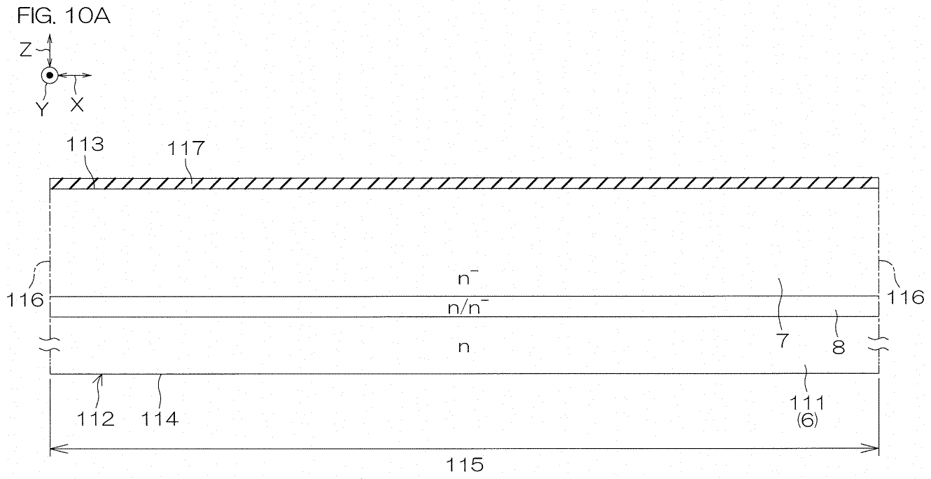

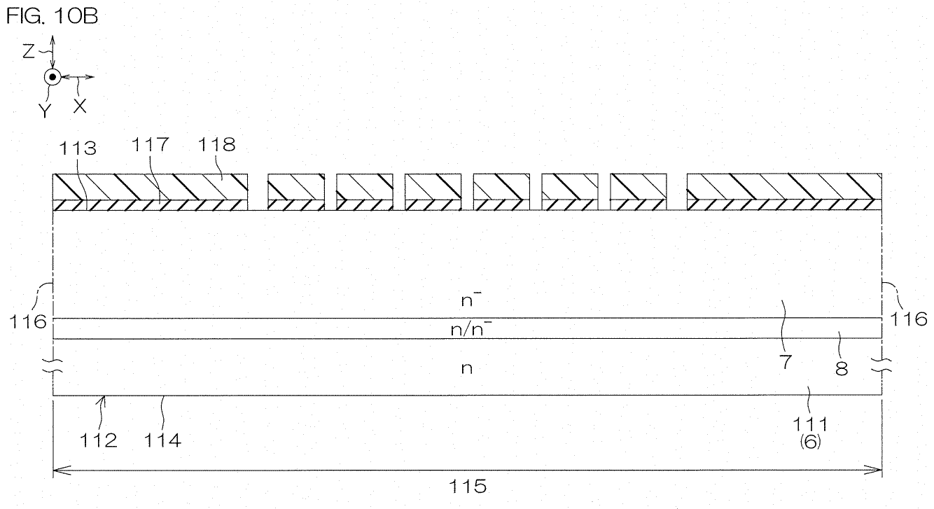

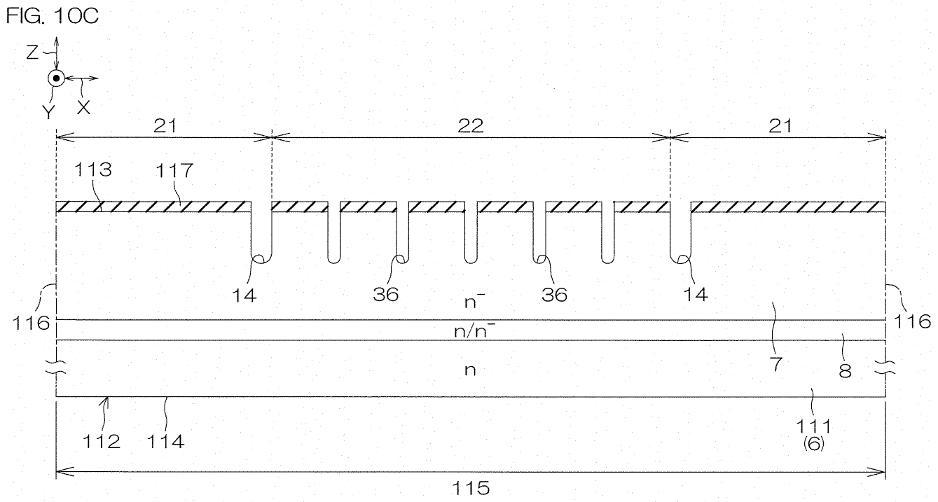

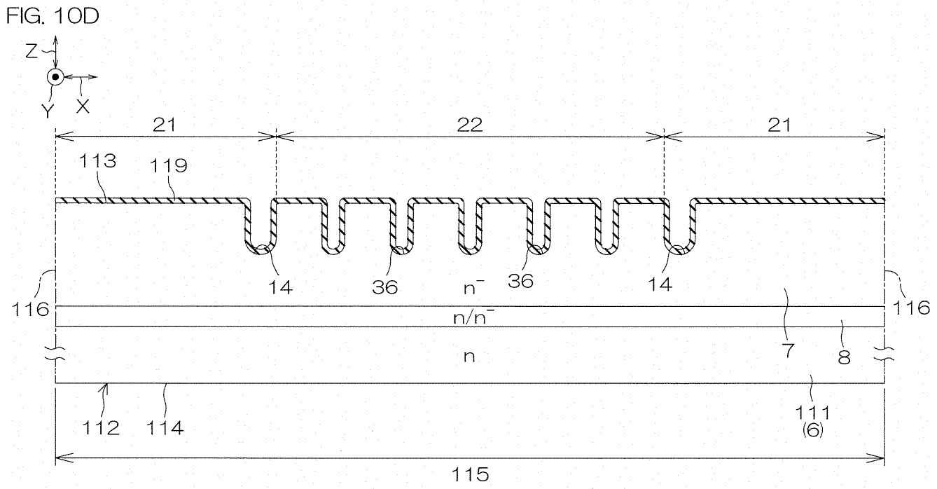

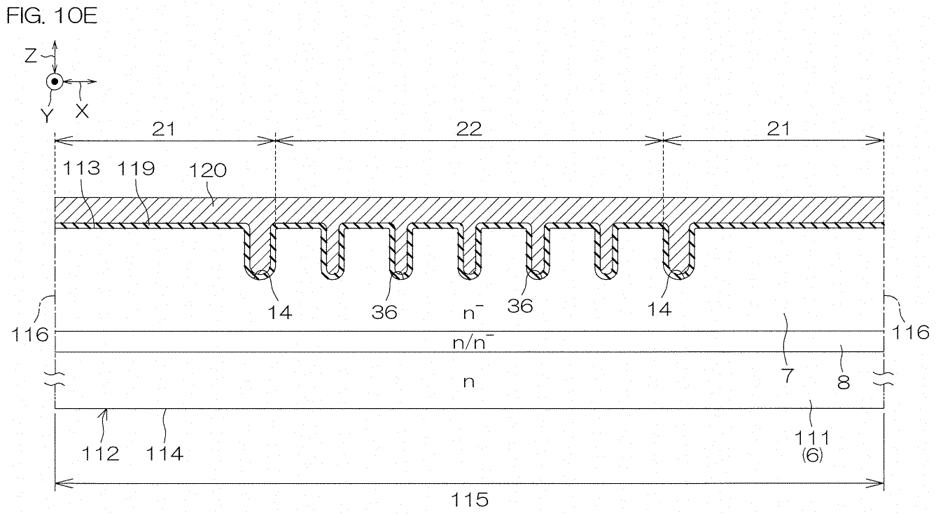

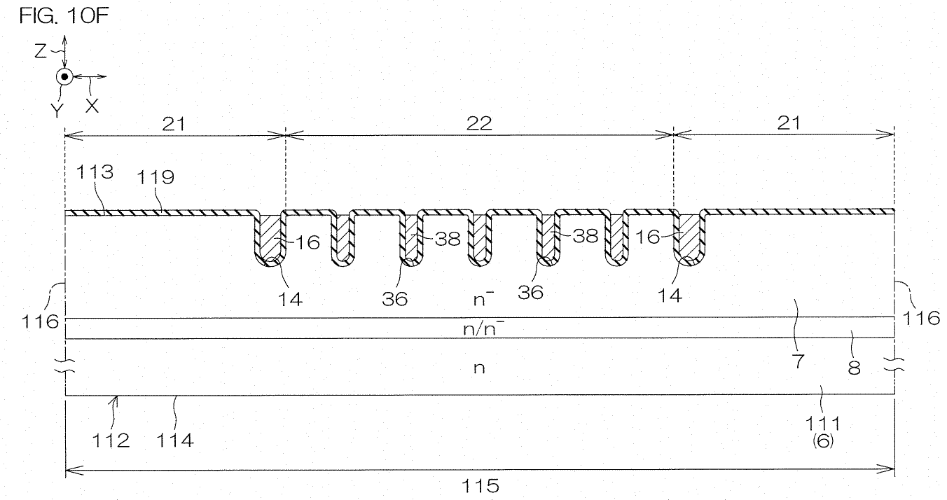

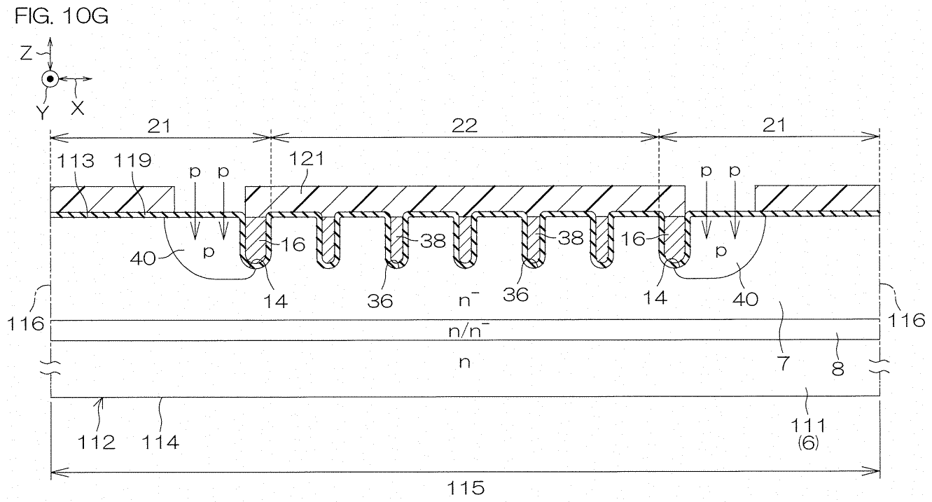

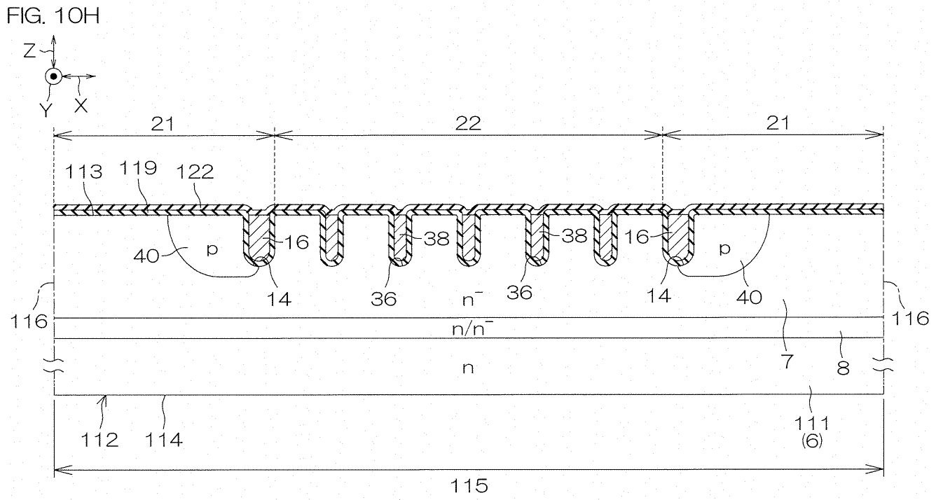

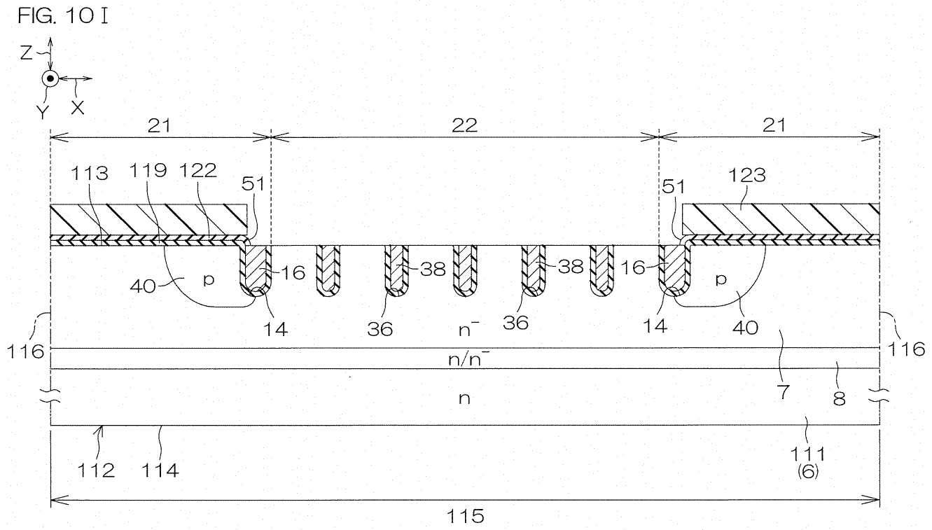

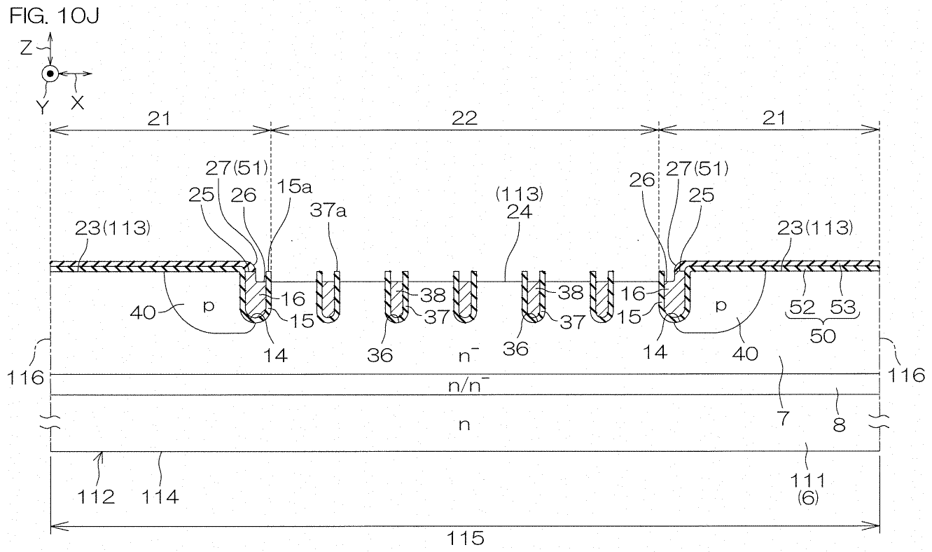

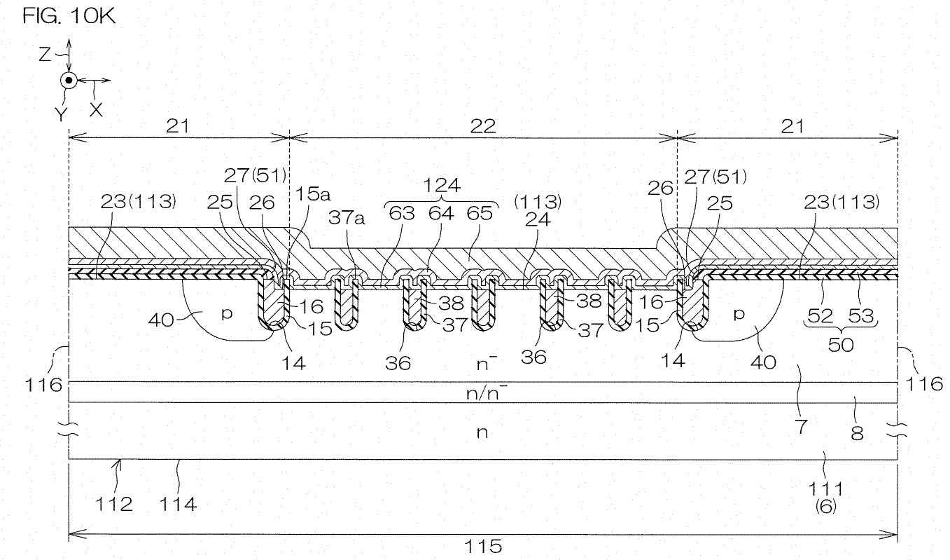

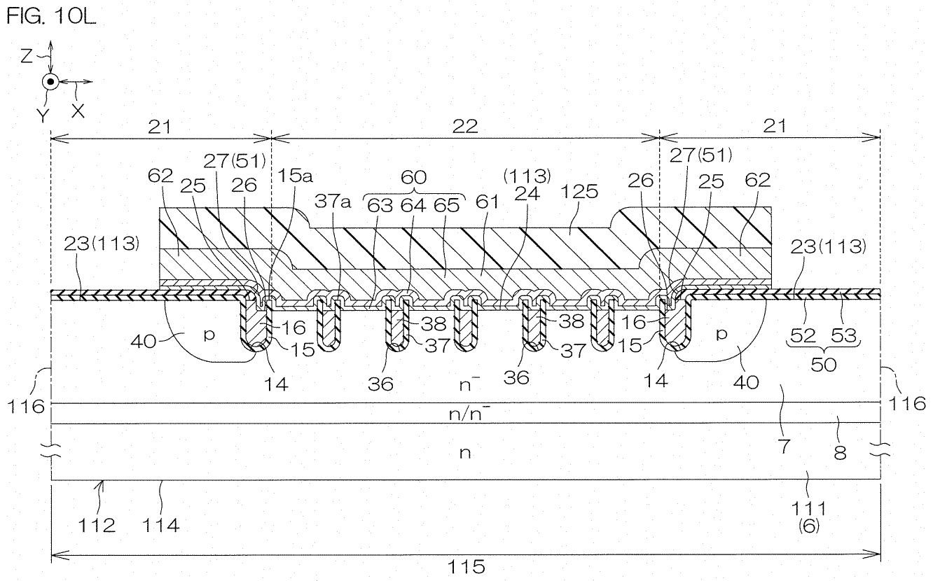

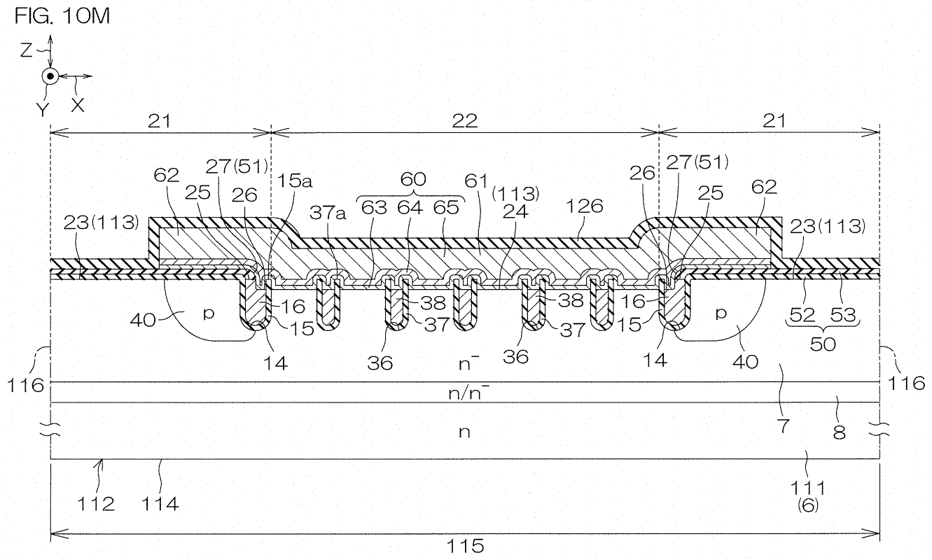

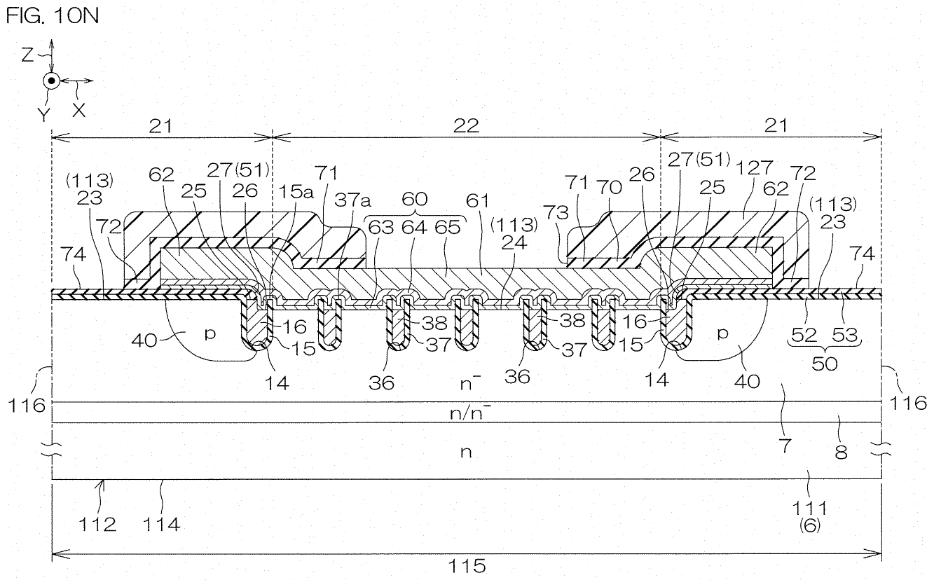

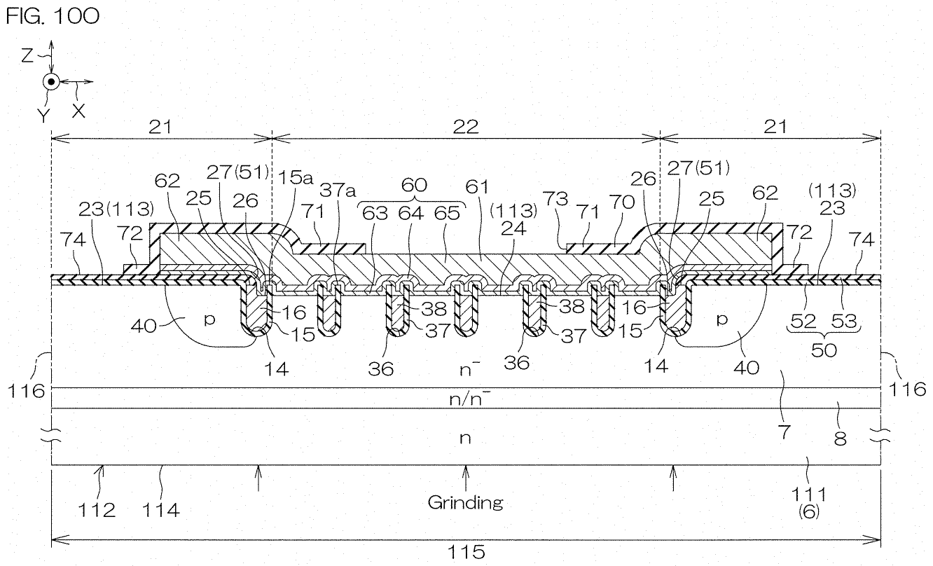

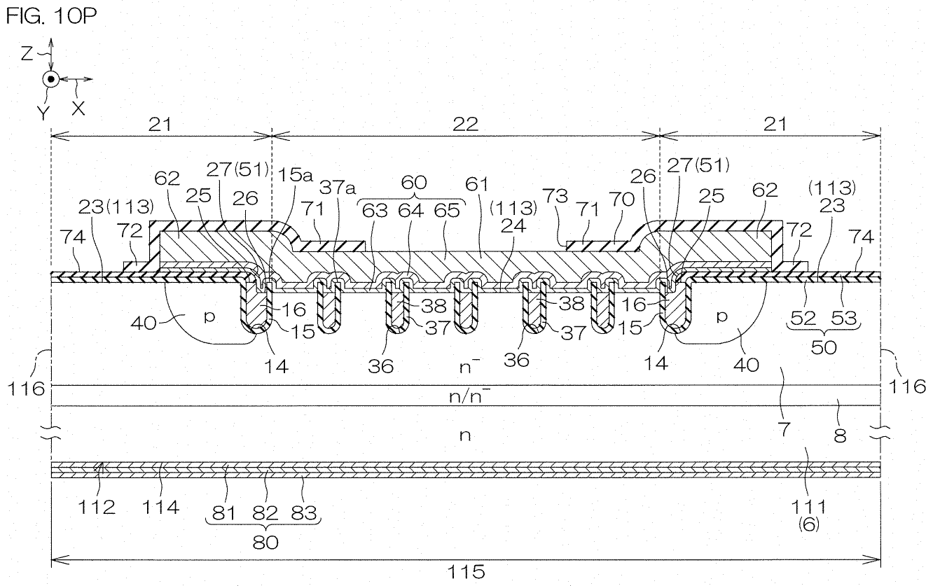

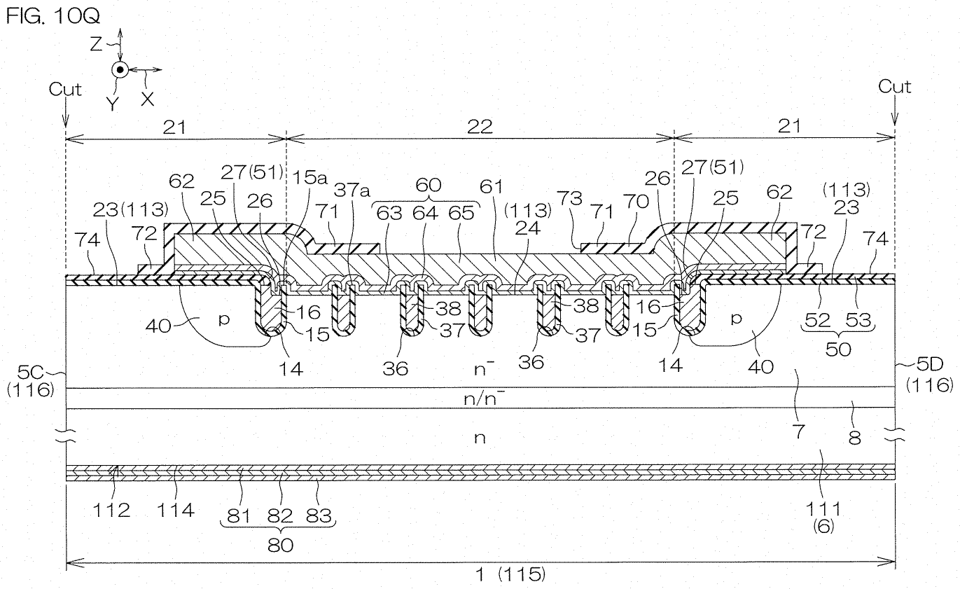

FIG. 10A to FIG. 10Q are each a cross-sectional view for describing an example of a method for manufacturing the semiconductor device 1 shown in FIG. 1.

With reference to FIG. 10A, a semiconductor wafer 111 (silicon wafer) which serves as a base of the cathode layer 6 is prepared. Next, silicon is subjected to crystal growth from one side of the semiconductor wafer 111 by an epitaxial growth method. Thereby, the buffer layer 8 having a predetermined n-type impurity concentration and the drift layer 7 having a predetermined n-type impurity concentration are formed in this order on the semiconductor wafer 111.

Hereinafter, a wafer structure which includes the semiconductor wafer 111 (cathode layer 6), the buffer layer 8 and the drift layer 7 is referred to as an epi-wafer 112. The epi-wafer 112 has a first wafer main surface 113 on one side and a second wafer main surface 114 on the other side. The first wafer main surface 113 and the second wafer main surface 114 respectively correspond to the first main surface 3 and the second main surface 4 of the semiconductor chip 2.

Next, a plurality of device regions 115 and an intended cutting line 116 for demarcating the plurality of device regions 115 are set in the first wafer main surface 113. The plurality of device regions 115 are set, for example, in a matrix shape at an interval in a first direction X and in a second direction Y in plan view. The intended cutting line 116 is set in a lattice shape according to an array of the plurality of device regions 115 in plan view. In FIG. 10A, one device region 115 is shown and the intended cutting line 116 is indicated by an alternate long and short dashed line (hereinafter, the same will be applied in FIG. 10B to FIG. 10Q).

Next, a hard mask 117 is formed on the first wafer main surface 113. The hard mask 117 is constituted of a silicon oxide film. The hard mask 117 may be formed by a CVD (Chemical Vapor Deposition) method and/or a thermal oxidation treatment method. In this embodiment, the hard mask 117 is formed by the thermal oxidation treatment method.

Next, with reference to FIG. 10B, a first resist mask 118 having a predetermined pattern is formed on the hard mask 117. The first resist mask 118 has an opening exposing a region in which a separation trench 14 and a plurality of trenches 36 are to be formed in the first wafer main surface 113.

Next, an unnecessary portion of the hard mask 117 is removed by an etching method via the first resist mask 118. The etching method may be a wet etching method and/or a dry etching method. Thereby, the plurality of openings exposing the regions in which the separation trench 14 and the plurality of trenches 36 are to be formed in the first wafer main surface 113 are formed in the hard mask 117. After the hard mask 117 is subjected to patterning, the first resist mask 118 is removed.

Next, with reference to FIG. 10C, an unnecessary portion of the first wafer main surface 113 is removed by an etching method via the hard mask 117. The etching method may be a wet etching method and/or a dry etching method. The etching method is preferably a dry etching method. The dry etching method may be an RIE (Reactive Ion Etching) method. Thereby, the separation trench 14 and the plurality of trenches 36 are formed in the first wafer main surface 113. Further, the outer region 21 and the active region 22 are demarcated by the separation trench 14 in the device region 115. After formation of the separation trench 14 and the plurality of trenches 36, the hard mask 117 is removed.

Next, with reference to FIG. 10D, a first base insulating film 119 is formed on the first wafer main surface 113. The first base insulating film 119 serves as a base of the separation insulating film 15, the insulating film 37 and the first main surface insulating film 52. The first base insulating film 119 is formed as a film along the first wafer main surface 113, the inner wall of the separation trench 14 and the inner walls of the trenches 36. The first base insulating film 119 is constituted of a silicon oxide film. The first base insulating film 119 may be formed by a CVD method and/or a thermal oxidation treatment method.

In this embodiment, the first base insulating film 119 is formed by the thermal oxidation treatment method. That is, the first base insulating film 119 is constituted of a field oxide film which contains an oxide of the epi-wafer 112 (specifically, drift layer 7). The first base insulating film 119 grows while absorbing the n-type impurity near the first wafer main surface 113. Therefore, the first base insulating film 119 contains the n-type impurity of the drift layer 7. On the other hand, in the first wafer main surface 113, a concentration of the n-type impurity is slightly decreased at an interface portion with the first base insulating film 119.

Next, with reference to FIG. 10E, a first base electrode film 120 is formed on the first wafer main surface 113. The first base electrode film 120 serves as a base of the separation electrode 16 and the electrodes 38. The first base electrode film 120 refills the separation trench 14 and the plurality of trenches 36 across the first base insulating film 119 and covers an entire area of the first wafer main surface 113 across the first base insulating film 119. In this embodiment, the first base electrode film 120 is constituted of a conductive polysilicon film. The first base electrode film 120 may be formed by a CVD method.

Next, with reference to FIG. 10F, an unnecessary portion of the first base electrode film 120 is removed by an etching method. The etching method may be a wet etching method and/or a dry etching method. The first base electrode film 120 is removed until the first base insulating film 119 is exposed. Thereby, the trench separation structure 10 which includes the separation trench 14, a part of the first base insulating film 119 (separation insulating film 15) and the separation electrode 16 embedded in the separation trench 14 across the first base insulating film 119 is formed. Also, the trench structure 30 which includes the trench 36, a part of the first base insulating film 119 (insulating film 37) and the electrode 38 embedded in the trench 36 across the first base insulating film 119 is formed.

Next, with reference to FIG. 10G, a second resist mask 121 which has a predetermined pattern on the first base insulating film 119 is formed. The second resist mask 121 has an opening exposing a region through which the floating region 40 is to be formed in the first wafer main surface 113. Specifically, the opening of the second resist mask 121 exposes a portion along the outer peripheral wall 12 of the trench separation structure 10 in the outer region 21.

Next, a p-type impurity is introduced into a surface layer portion of the first wafer main surface 113 by an ion implantation method via the second resist mask 121. The p-type impurity is introduced into the surface layer portion of the first wafer main surface 113 via the first main surface insulating film 52. Next, the p-type impurity which has been introduced into the surface layer portion of the first wafer main surface 113 is diffused in a width direction and a depth direction of the drift layer 7 by a drive-in treatment method. Thereby, the floating region 40 is formed. A specific mode of the floating region 40 is as described with reference to FIG. 1 to FIG. 5. A specific description of the floating region 40 is omitted. After formation of the floating region 40, the second resist mask 121 is removed.

Next, with reference to FIG. 10H, a second base insulating film 122 is formed on the first wafer main surface 113. The second base insulating film 122 serves as a base of the second main surface insulating film 53. The second base insulating film 122 covers the trench separation structure 10, the plurality of trench structures 30 and the first base insulating film 119. The second base insulating film 122 is constituted of an insulating material which is different from the first base insulating film 119. Specifically, the second base insulating film 122 is constituted of a silicon oxide film different in property from the first base insulating film 119. In this embodiment, the second base insulating film 122 includes at least one among a BPSG film, a PSG film and a USG film. The second base insulating film 122 may be formed by a CVD method.

Next, with reference to FIG. 10I, a third resist mask 123 having a predetermined pattern is formed on the second base insulating film 122. The third resist mask 123 has an opening exposing a region in which the through hole 51 is to be formed in the second base insulating film 122. Next, an unnecessary portion of the second base insulating film 122 is removed by an etching method via the third resist mask 123. The etching method may be a wet etching method and/or a dry etching method. The etching method is preferably a dry etching method (for example, RIE method). Thereby, the through hole 51 is formed in the second base insulating film 122.

Further, in this step, an unnecessary portion of the first base insulating film 119 is also removed by an etching method via the third resist mask 123 (through hole 51 of second base insulating film 122). The etching method may be a wet etching method and/or a dry etching method. The etching method is preferably the dry etching method (for example, RIE method).

Thereby, the first base insulating film 119 is separated into the separation insulating film 15, the insulating film 37 and the first main surface insulating film 52. Further, the second base insulating film 122 is given as the second main surface insulating film 53, and the main surface insulating film 50 which has a laminated structure including the first main surface insulating film 52 and the second main surface insulating film 53 is formed on the first wafer main surface 113. After patterning of the first base insulating film 119 and the second base insulating film 122, the third resist mask 123 is removed.

Next, with reference to FIG. 10J, a surface layer portion of the first wafer main surface 113 which is exposed from the through hole 51 is removed by an etching method via the through hole 51 of the second main surface insulating film 53. That is, in this step, a portion which forms the active region 22 in the first wafer main surface 113 (specifically, active main surface 24) is partially removed. The etching method may be a wet etching method and/or a dry etching method. The etching method is preferably an isotropic CDE (Chemical Dry Etching) method.

In this step, a part of the separation electrode 16 of the trench separation structure 10 and a part of the electrode 38 of the plurality of trench structures 30 are removed at the same time with the surface layer portion of the first wafer main surface 113 such that the separation insulating film 15 and the insulating film 37 remain. Thereby, the contact opening 27 which is communicatively connected to the through hole 51 is formed in the active region 22 and, at the same time, the separation protrusion portion 15a of the separation insulating film 15 and the protrusion portion 37a of the insulating film 37 are formed. The contact opening 27 is formed such as to be depressed to the bottom portion side of the drift layer 7 with respect to a portion positioned in the outer region 21 (that is, outer main surface 23) in the first wafer main surface 113.

This step includes a step in which a damage layer resulting from the step of forming the trench separation structure 10 and the trench structures 30 is removed from the portion which forms the active region 22 in the first wafer main surface 113 (specifically, active main surface 24). The damage layer includes, for example, a coarse portion produced in the first wafer main surface 113 by etching and/or a portion in which an n-type impurity concentration is changed in accordance with the formation of the first base insulating film 119. This step also includes a step in which an insulation distance between the separation electrode 16 and the active main surface 24 is increased by the separation protrusion portion 15a of the separation insulating film 15. This step also includes a step in which an insulation distance between the electrode 38 and the active main surface 24 is increased by the protrusion portion 37a of the insulating film 37.

Next, with reference to FIG. 10K, a second base electrode film 124 is formed on the first wafer main surface 113. The second base electrode film 124 serves as a base of the Schottky electrode 60. The second base electrode film 124 refills the contact opening 27 and the through hole 51 and covers an entire area of the main surface insulating film 50. The second base electrode film 124 is electrically connected to the separation electrode 16 such as to retain the floating region 40 in the electrically floating state in the outer region 21. The second base electrode film 124 is electrically connected to the first main surface 3 and the electrode 38 of each of the trench structures 30 in the active region 22. The second base electrode film 124 forms the Schottky junction with the first main surface 3 in the active region 22.

The second base electrode film 124 has a laminated structure which includes the first electrode film 63, the second electrode film 64 and the third electrode film 65 laminated in this order from the first wafer main surface 113 side. The first electrode film 63 is constituted of various metals which form the Schottky junction with the first wafer main surface 113. In this embodiment, the first electrode film 63 is constituted of a molybdenum film. The second electrode film 64 is constituted of a Ti-based metal film. In this embodiment, the second electrode film 64 is constituted of a TiN film.

The third electrode film 65 is constituted of a Cu-based metal film or an Al-based metal film. In this embodiment, the third electrode film 65 is constituted of an AlCu alloy film. The first electrode film 63, the second electrode film 64 and the third electrode film 65 may be formed at least by one method among a sputtering method, a vapor deposition method and a plating method. In this embodiment, the first electrode film 63, the second electrode film 64 and the third electrode film 65 are each formed by the sputtering method.

Next, with reference to FIG. 10L, a fourth resist mask 125 having a predetermined pattern is formed on the second base electrode film 124. The fourth resist mask 125 covers a region in which the Schottky electrode 60 is to be formed in the second base electrode film 124 and has an opening exposing the other region. Next, an unnecessary portion of the second base electrode film 124 is removed by an etching method via the fourth resist mask 125. The etching method may be a wet etching method and/or a dry etching method. The Schottky electrode 60 is thereby formed. After formation of the Schottky electrode 60, the fourth resist mask 125 is removed.

Next, with reference to FIG. 10M, a third base insulating film 126 is formed on the main surface insulating film 50 such as to cover the Schottky electrode 60. The third base insulating film 126 serves as a base of the upper insulating film 70. The third base insulating film 126 is constituted of an insulating material which is different from the main surface insulating film 50. The third base insulating film 126 includes at least one of a silicon oxynitride film and a silicon nitride film. In this embodiment, the third base insulating film 126 is constituted of a silicon oxynitride film. The third base insulating film 126 may be formed by a CVD method.

Next, with reference to FIG. 10N, a fifth resist mask 127 having a predetermined pattern is formed on the third base insulating film 126. The fifth resist mask 127 covers a region in which the upper insulating film 70 is to be formed in the third base insulating film 126 and has an opening exposing the other region. Next, an unnecessary portion of the third base insulating film 126 is removed by an etching method via the fifth resist mask 127. The etching method may be a wet etching method and/or a dry etching method. The upper insulating film 70 is thereby formed. The upper insulating film 70 demarcates the dicing street 74 which exposes the intended cutting line 116 on the first wafer main surface 113. After formation of the upper insulating film 70, the fifth resist mask 127 is removed.

Next, with reference to FIG. 10O, the epi-wafer 112 is thinned until a desired thickness by a grinding to the second wafer main surface 114. The grinding step may be performed by a CMP (Chemical Mechanical Polishing) method. Thereby, grinding marks are formed in the second wafer main surface 114. The grinding step of the second wafer main surface 114 is not necessarily performed and may be omitted, if necessary. However, thinning of the cathode layer 6 is effective in reducing a resistance value of the semiconductor chip 2.

Next, with reference to FIG. 10P, the cathode electrode 80 is formed on the second wafer main surface 114. The cathode electrode 80 forms an ohmic contact with the second wafer main surface 114. The cathode electrode 80 has a laminated structure which includes the titanium film 81, the nickel film 82 and the gold film 83 laminated in this order from the second wafer main surface 114 side. The titanium film 81, the nickel film 82 and the gold film 83 may be formed at least by one method among a sputtering method, a vapor deposition method and a plating method.

In this embodiment, the titanium film 81, the nickel film 82 and the gold film 83 are each formed by the sputtering method. A step of forming the cathode electrode 80 may include a step of forming a palladium film which covers the nickel film 82 prior to a step of forming the gold film 83. The palladium film may be formed at least by one method (for example, sputtering method) among a sputtering method, a vapor deposition method and a plating method. In this case, the gold film 83 is formed such as to cover the palladium film.

Next, with reference to FIG. 10Q, the epi-wafer 112 is cut along the intended cutting line 116. A step of cutting the epi-wafer 112 may include a cutting step by a dicing blade. In this case, the epi-wafer 112 is cut along the intended cutting line 116 demarcated by the dicing street 74. The dicing blade preferably has a blade width which is less than a width of the dicing street 74.

The step of cutting the epi-wafer 112 may include a cleavage step which uses a laser light irradiation method. In this case, an interior of the epi-wafer 112 is irradiated with laser light via the dicing street 74 from a laser light irradiation unit (not shown). The interior of the epi-wafer 112 is preferably irradiated with laser light in a pulse shape from the first wafer main surface 113 side in which no cathode electrode 80 is provided. A light condensing portion (focus) of laser light is set in the interior of the epi-wafer 112 (intermediate portion in thickness direction) and an irradiation position of laser light is moved along the dicing street 74 (specifically, intended cutting line 116).

Thereby, a modified layer which extends along the dicing street 74 in plan view is formed in the interior of the epi-wafer 112. That is, the modified layer is formed in a lattice shape in plan view. The modified layer is constituted of a laser light irradiation mark and constituted of a region in which a part of the crystalline structure of the epi-wafer 112 is modified to another property. That is, the modified layer is constituted of a region in which a density, a refractive index, a mechanical intensity (crystal strength) and other physical characteristics are modified such as to be different from those of a crystalline structure of the epi-wafer 112.

The modified layer is preferably formed at an interval from the first wafer main surface 113 in the interior of the epi-wafer 112. In this case, the modified layer is preferably formed at a portion which is constituted of the cathode layer 6 (semiconductor wafer 111) in the interior of the epi-wafer 112. It is particularly preferable that the modified layer is formed at the portion which is constituted of the cathode layer 6 (semiconductor wafer 111) at an interval from the drift layer 7 (epitaxial layer) in the interior of the epi-wafer 112. It is most preferable that the modified layer is not formed in the drift layer 7 (epitaxial layer) in the interior of the epi-wafer 112.

After the step of forming the modified layer, an external force is applied to the epi-wafer 112 to cleave the epi-wafer 112, with the modified layer given as a starting point. The external force is preferably applied to the epi-wafer 112 from the second wafer main surface 114 side. The main surface insulating film 50 and the cathode electrode 80 are cleaved at the same time with cleavage of the epi-wafer 112. Since the upper insulating film 70 demarcates the dicing street 74 and is not positioned on the intended cutting line 116, it is not cleaved.

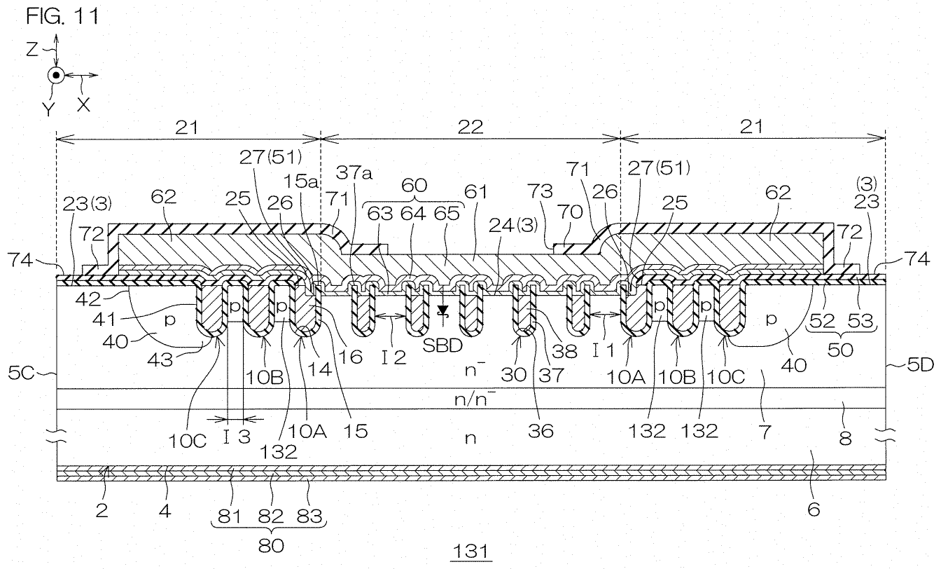

FIG. 11 is a drawing which corresponds to FIG. 4 and a cross-sectional view which shows a semiconductor device 131 according to the second embodiment of the present invention. Hereinafter, a structure corresponding to the structure described in the semiconductor device 1 will be given the same reference number, with a description thereof omitted.

The semiconductor device 1 according to the first embodiment has one trench separation structure 10. In contrast thereto, the semiconductor device 131 according to the second embodiment has a plurality of the trench separation structures 10. The number of the trench separation structures 10 is arbitrary, and two or more trench separation structures 10 may be formed. In this embodiment, an example in which the three trench separation structures 10 are formed is shown. The three trench separation structures 10 include a first trench separation structure 10A, a second trench separation structure 10B and a third trench separation structure 10C.

The first to third trench separation structures 10A to 10C each has the separation trench 14, the separation insulating film 15 and the separation electrode 16. The first to third trench separation structures 10A to 10C each has the first width W1 and the first depth D1. The first to third trench separation structures 10A to 10C are formed in this order at intervals from the active region 22 side to the outer region 21 side.

The first trench separation structure 10A corresponds to the trench separation structure 10 according to the first embodiment and surrounds the active region 22 in plan view. The second trench separation structure 10B is formed in a band shape which extends along the first trench separation structure 10A in plan view. Specifically, the second trench separation structure 10B surrounds the first trench separation structure 10A. The third trench separation structure 10C is formed in a band shape which extends along the second trench separation structure 10B in plan view. Specifically, the third trench separation structure 10C surrounds the second trench separation structure 10B. That is, in this embodiment, the plurality of trench separation structures 10 are formed in a concentric pattern such as to surround the active region 22 in plan view.

The plurality of trench separation structures 10 are formed at intervals of a third interval I3. The third interval I3 is preferably less than the first interval I1 between the trench separation structure 10 and the trench structure 30 (I3<I1). The third interval I3 is also preferably less than the second interval I2 between the plurality of trench structures 30 (I3<I2). That is, the number of the trench separation structures 10 per unit area is preferably in excess of the number of the trench structures 30 per unit area. The third interval I3 may be not less than 0.1 μm and not more than 5 μm.

In this embodiment, the floating region 40 is adjacent to the outermost trench separation structure 10 (that is, third trench separation structure 10C) in the outer region 21. The floating region 40 is formed in a band shape along the outer peripheral wall 12 of the third trench separation structure 10C in plan view. Specifically, the floating region 40 is formed in an annular shape which surrounds the third trench separation structure 10C in plan view.

The floating region 40 has the inner peripheral edge 41 on the third trench separation structure 10C side and the outer peripheral edge 42 on the first to fourth side surfaces 5A to 5D side. The inner peripheral edge 41 of the floating region 40 is connected to the outer peripheral wall 12 of the third trench separation structure 10C. The outer peripheral edge 42 of the floating region 40 extends along the outer peripheral wall 12 of the third trench separation structure 10C in plan view. In this embodiment, the outer peripheral edge 42 of the floating region 40 extends substantially in parallel with the outer peripheral wall 12 of the third trench separation structure 10C in plan view.

The floating region 40 is formed at the surface layer portion of the first main surface 3 at an interval from the bottom portion of the drift layer 7 to the first main surface 3 side. The floating region 40 is formed in a depth range between the first main surface 3 and the bottom wall 13 of the third trench separation structure 10C. The floating region 40 is formed deeper than each of the trench separation structures 10. The floating region 40 is also formed deeper than each of the trench structures 30.

The floating region 40 (specifically, inner peripheral edge 41) has the covering portion 43 which covers at least the bottom wall 13 of the third trench separation structure 10C. Specifically, the covering portion 43 covers a portion of the third trench separation structure 10C on the outer region 21 side such as to expose a portion of the third trench separation structure 10C on the active region 22 side. The covering portion 43 is positioned on the bottom portion side of the drift layer 7 with respect to the bottom wall 35 of each of the trench structures 30.

As with the first embodiment, as with the first embodiment, the floating region 40 may have the region thickness TF and the region width WF. The floating region 40 may also include the first region 44 on the inner peripheral edge 41 (trench separation structure 10) side which is substantially constant in region thickness TF, and a second region 45 on the external edge side in which the region thickness TF is decreased gradually to the first main surface 3 side.

The semiconductor device 131 includes a plurality of p-type second floating regions 132, each of which is formed in a region between the two adjacent trench separation structures 10 at a surface layer portion of the first main surface 3 of the outer region 21 (that is, outer main surface 23). That is, in this embodiment, one second floating region 132 is formed in a region between the first trench separation structure 10A and the second trench separation structure 10B, and another second floating region 132 is formed in a region between the second trench separation structure 10B and the third trench separation structure 10C.

In this embodiment, each of the second floating regions 132 includes a portion which is positioned on the outer main surface 23 side with respect to the active main surface 24 and a portion which is positioned on the bottom portion side of the drift layer 7 with respect to the active main surface 24 with regard to the normal direction Z. Each of the second floating regions 132 is formed in the electrically floating state. That is, each of the second floating regions 132 is formed electrically in separation from the active region 22, the trench separation structures 10 and the trench structures 30. Each of the second floating regions 132 may have a p-type impurity concentration which is not less than 1×10¹⁷ cm⁻³ and not more than 1×10¹⁹ cm⁻³. The p-type impurity concentration of each of the second floating regions 132 has a concentration gradient which is decreased gradually in a width direction and a thickness direction of the drift layer 7 from the first main surface 3 (outer main surface 23).

Each of the second floating regions 132 is formed in a band shape along two of the first to third trench separation structures 10A to 10C which are adjacent to each other in plan view. Specifically, each of the second floating regions 132 is formed in an annular shape extending along two trench separation structures 10 adjacent to each other in plan view. Each of the second floating regions 132 is connected to the two adjacent trench separation structures 10. Each of the second floating regions 132 is formed in an entire area of a region between the two adjacent trench separation structures 10.

Each of the second floating regions 132 is formed at the surface layer portion of the first main surface 3 at an interval from the bottom portion of the drift layer 7 to the first main surface 3 side. Each of the second floating regions 132 is formed in a depth range between the first main surface 3 and the bottom wall 13 of each of the trench separation structures 10. In this embodiment, each of the second floating regions 132 is formed shallower than each of the trench separation structures 10. Also, each of the second floating regions 132 is formed shallower than each of the trench structures 30. That is, each of the second floating regions 132 is formed at an interval on the first main surface 3 side with respect to the bottom wall 13 of each of the trench separation structures 10.

As described above, as with the semiconductor device 131 according to the second embodiment, the structure in which the floating region 40 and the second floating region 132 are combined with the plurality of trench separation structures 10 may be adopted. In this embodiment, a description has been given of an example in which each of the second floating regions 132 is formed shallower than each of the trench separation structures 10. However, each of the second floating regions 132 may be formed deeper than each of the trench separation structures 10.

In this case, each of the second floating regions 132 may be formed integral with the floating region 40. That is, each of the second floating regions 132 may form the covering portion 43 which covers the plurality of trench separation structures 10 in the floating region 40. In this case, as with the first embodiment, the covering portion 43 (second floating region 132) preferably covers a portion of the innermost trench separation structure 10 on the outer region 21 side such as to expose a portion of the innermost trench separation structure 10 (that is, first trench separation structure 10A) on the active region 22 side.

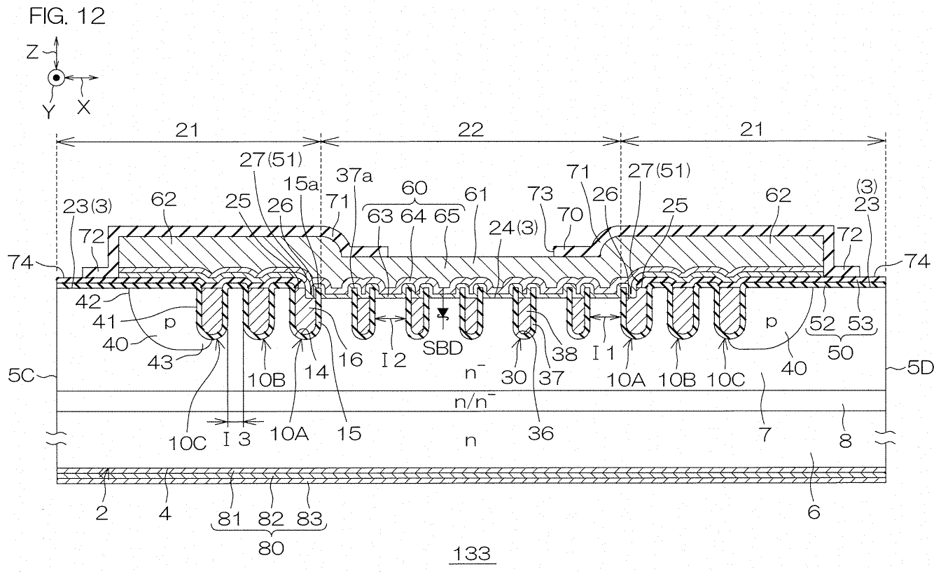

FIG. 12 is a drawing which corresponds to FIG. 11 and a cross-sectional view which shows a semiconductor device 133 according to the third embodiment of the present invention. The semiconductor device 133 has a mode in which the second floating region 132 is removed from the semiconductor device 131 according to the second embodiment. As described above, as with the semiconductor device 133 according to the third embodiment, the structure in which the floating region 40 is combined with the plurality of trench separation structures 10 may be adopted.

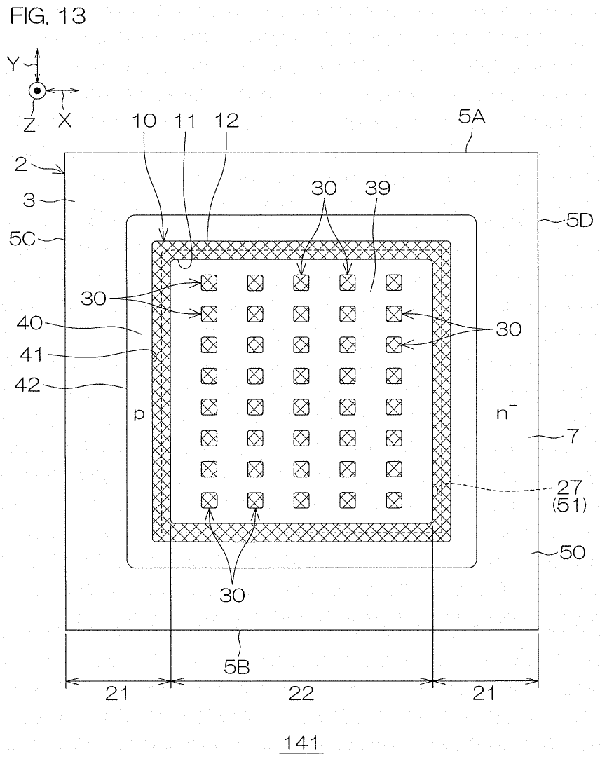

FIG. 13 is a drawing which corresponds to FIG. 2 and a plan view which shows a semiconductor device 141 according to the fourth embodiment of the present invention. Hereinafter, a structure corresponding to the structure described in the semiconductor device 1 will be given the same reference number, with a description thereof omitted.

The semiconductor device 1 according to the first embodiment has the plurality of trench structures 30 which are arrayed in the stripe shape extending in the second direction Y in plan view. That is, in the semiconductor device 1, the plurality of mesa portions 39 extending in the second direction Y are demarcated in the active main surface 24 by the plurality of trench structures 30 in plan view. In contrast thereto, the semiconductor device 141 according to the fourth embodiment includes the plurality of trench structures 30 which are arrayed in a matrix pattern at intervals in the first direction X and in the second direction Y in plan view.

Thereby, the single lattice-shaped mesa portion 39 which extends in the first direction X and in the second direction Y in plan view and has a plurality of crossroads demarcated by the plurality of trench structures 30 in the active main surface 24. Planar shapes of the trench structures 30 are arbitrary. The trench structures 30 may each be formed in a square shape, a rectangular shape, a circular shape, etc., in plan view.

As described above, the semiconductor device 141 according to the fourth embodiment is also able to achieve the same effects as those described in the semiconductor device 1. The plurality of trench structures 30 according to the fourth embodiment are applicable to other embodiments. As a matter of course, the plurality of trench structures 30 according to the fourth embodiment may be applied to the first to the fourth reference embodiments.

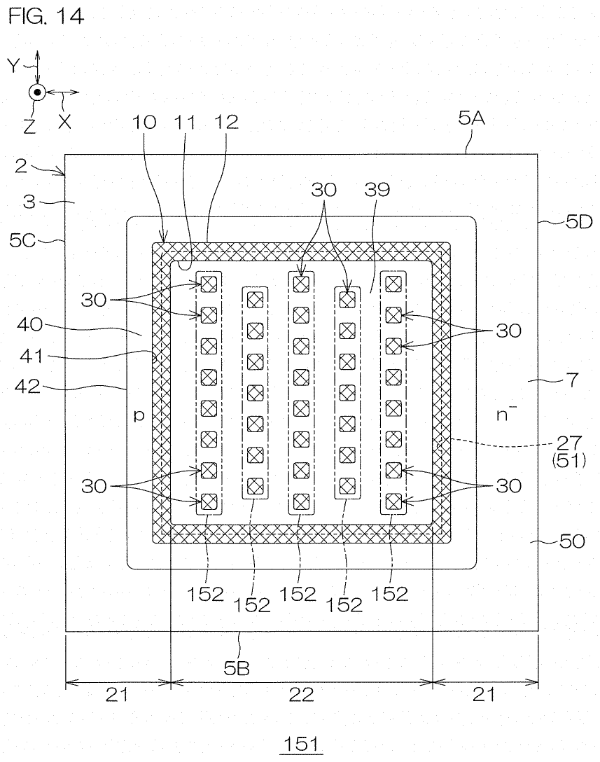

FIG. 14 is a drawing which corresponds to FIG. 2 and a plan view which shows a semiconductor device 151 according to the fifth embodiment of the present invention. Hereinafter, a structure corresponding to the structure described in the semiconductor device 1 will be given the same reference number, with a description thereof omitted.

The semiconductor device 1 according to the first embodiment has the plurality of trench structures 30 which are arrayed in the stripe shape extending in the second direction Y in plan view. That is, in the semiconductor device 1, the plurality of mesa portions 39 which extend in the second direction Y are demarcated by the plurality of trench structures 30 in the active main surface 24 in plan view. In contrast thereto, the semiconductor device 151 according to the fifth embodiment includes the plurality of trench structures 30 which are arrayed in a staggered pattern at intervals in the first direction X and in the second direction Y in plan view.

In this embodiment, the plurality of trench structures 30 are categorized into a plurality of groups 152. The plurality of groups 152 are arrayed at intervals in the first direction X and each includes a plurality of trench structures 30 arrayed in a line at intervals in the second direction Y. A group 152 of the plurality of groups 152 which is positioned at the 2n^{th} (n≥1) is arranged such as to shift only by a half pitch of one trench structure 30 in the second direction Y with respect to a group 152 of the plurality of groups 152 which is positioned at the (2n−1)^{th} (n≥1).

Thereby, the mesa portion 39 which extends in the first direction X and in the second direction Y and has a plurality of T-junctions is demarcated by the plurality of trench structures 30 in the active main surface 24 in plan view. Planar shapes of the trench structures 30 are arbitrary. The trench structures 30 may each be formed in a square shape, a rectangular shape, a hexagonal shape, a circular shape, etc., in plan view. The mesa portion 39 may have a plurality of Y-junctions depending on the planar shapes of the trench structures 30.

As described above, the semiconductor device 151 according to the fifth embodiment is also able to achieve the same effects as those of the semiconductor device 1.

The plurality of trench structures 30 according to the fifth embodiments are applicable to other embodiments. As a matter of course, the plurality of trench structures 30 according to the fifth embodiment may be applied to the first to the fourth reference embodiments.

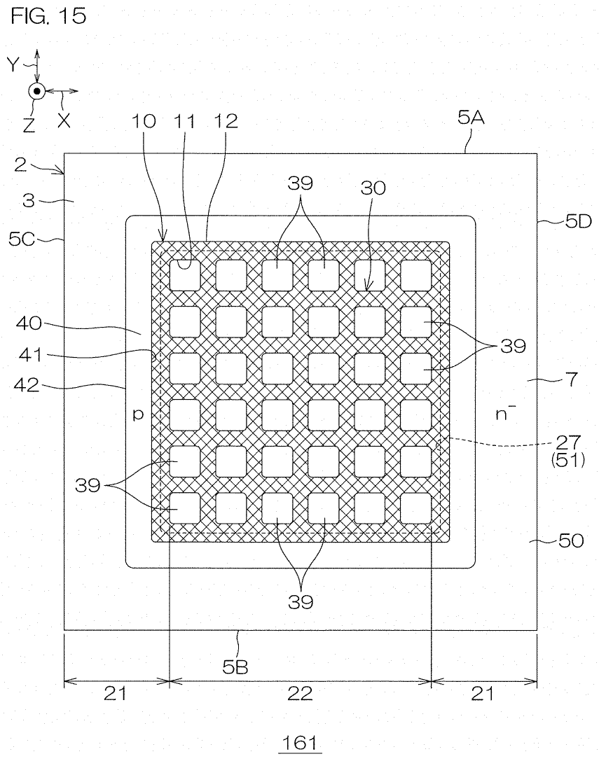

FIG. 15 is a drawing which corresponds to FIG. 2 and a plan view which shows a semiconductor device 161 according to the sixth embodiment of the present invention. Hereinafter, a structure corresponding to the structure described in the semiconductor device 1 will be given the same reference number, with a description thereof omitted.

The semiconductor device 1 according to the first embodiment has the plurality of trench structures 30 which are arrayed in the stripe shape extending in the second direction Y in plan view. That is, in the semiconductor device 1, the plurality of mesa portions 39 which extend in the second direction Y are demarcated by the plurality of trench structures 30 in the active main surface 24 in plan view. In contrast thereto, the semiconductor device 161 according to the sixth embodiment includes the single trench structure 30 which has a lattice pattern extending in the first direction X and in the second direction Y in plan view. The trench structure 30 in the lattice shape has a plurality of crossroads and is connected to the four inner peripheral walls 11 of the trench separation structure 10.

Thereby, the plurality of mesa portions 39 are demarcated by the lattice-shaped trench structure 30 in the active main surface 24 in plan view. The plurality of mesa portions 39 are demarcated in a matrix pattern at intervals in the first direction X and in the second direction Y. Planar shapes of the plurality of mesa portions 39 are arbitrary. The mesa portions 39 may each be demarcated in a square shape, a rectangular shape, a hexagonal shape, a circular shape, etc., in plan view.

As described above, the semiconductor device 161 according to the sixth embodiment is also able to achieve the same effects as those of the semiconductor device 1. In this embodiment, a description has been given of an example in which the trench structure 30 is formed in the lattice shape which has the plurality of crossroads in plan view. However, the trench structure 30 may be formed in a lattice shape which has a plurality of T-junctions or a plurality of Y-junctions. In this case, the plurality of mesa portions 39 may be demarcated in a staggered pattern at intervals in the first direction X and in the second direction Y. The trench structure 30 according to the sixth embodiment is applicable to other embodiments. As a matter of course, the trench structure 30 according to the sixth embodiment may be applied to the first to the fourth reference embodiments.

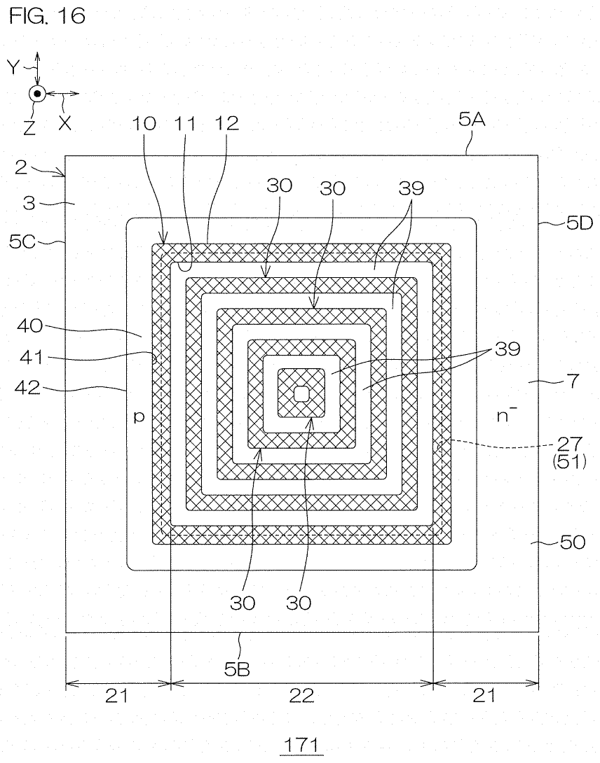

FIG. 16 is a drawing which corresponds to FIG. 2 and a plan view which shows a semiconductor device 171 according to the seventh embodiment of the present invention. Hereinafter, a structure corresponding to the structure described in the semiconductor device 1 will be given the same reference number, with a description thereof omitted.

The semiconductor device 1 according to the first embodiment has the plurality of trench structures 30 which are arrayed in the stripe shape extending in the second direction Y in plan view. That is, in the semiconductor device 1, the plurality of mesa portions 39 which extend in the second direction Y are demarcated by the plurality of trench structures 30 in the active main surface 24 in plan view. In contrast thereto, the semiconductor device 171 according to the seventh embodiment includes the plurality of trench structures 30 which are formed in a concentric pattern in plan view. The plurality of trench structures 30 are formed at intervals from the active region 22 to the outer region 21 in plan view and each formed in an annular shape which surrounds an inner portion (central portion) of the active region 22.

Thereby, a plurality of mesa portions 39 which give a concentric pattern are demarcated in the active main surface 24 by the plurality of trench structures 30 which give a concentric pattern in plan view. The planar shapes of the trench structures 30 is arbitrary. The plurality of trench structures 30 may each be formed in a quadrilateral annular shape, a circular annular shape, etc., in plan view. The plurality of mesa portions 39 may be formed in a quadrilateral annular shape, a circular annular shape, etc., depending on the planar shape of the trench structures 30.

As described above, the semiconductor device 171 according to the seventh embodiment is also able to achieve the same effects as those of the semiconductor device 1. The plurality of trench structures 30 according to the seventh embodiment are applicable to other embodiments. As a matter of course, the plurality of trench structures 30 according to the seventh embodiment may be applied to the first to the fourth reference embodiments.

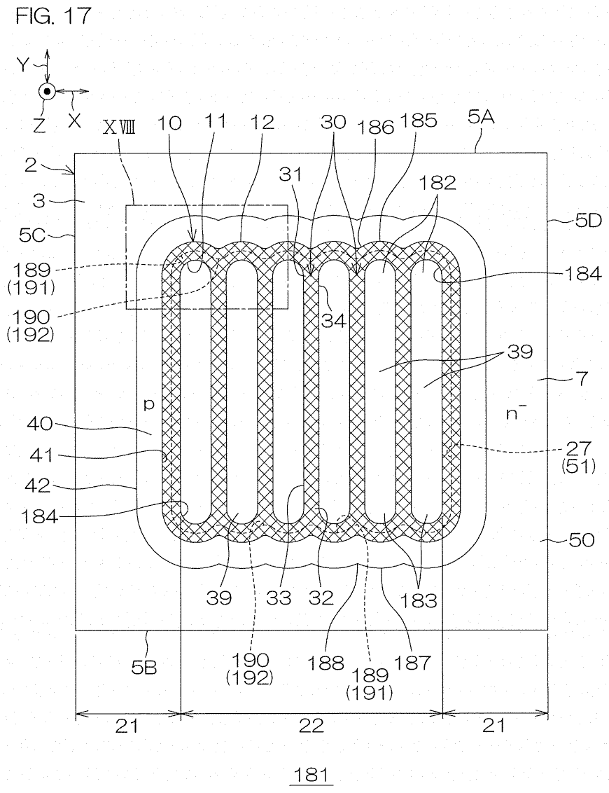

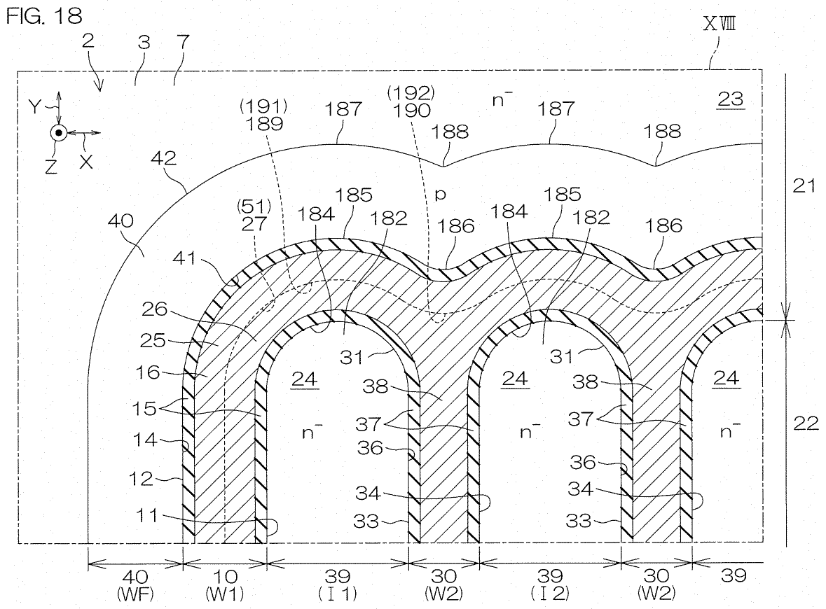

FIG. 17 is a drawing which corresponds to FIG. 2 and a plan view which shows a semiconductor device 181 according to the eighth embodiment of the present invention. FIG. 18 is an enlarged view of a region XVIII shown in FIG. 17. Hereinafter, a structure corresponding to the structure described in the semiconductor device 1 will be given the same reference number, with a description thereof omitted.

In the semiconductor device 1 according to the first embodiment, the plurality of mesa portions 39 in the rectangular shape extending in the second direction Y are demarcated by the trench separation structure 10 and the plurality of trench structures 30 in plan view. In contrast thereto, in the semiconductor device 181 according to the eighth embodiment, the plurality of mesa portions 39 in an elliptical shape extending in the second direction Y are demarcated by the trench separation structure 10 and the plurality of trench structures 30 in plan view.

Specifically, the plurality of mesa portions 39 each has a first end portion 182 on one side in the second direction Y and a second end portion 183 on the other side in the second direction Y in plan view. The first end portion 182 and the second end portion 183 of each of the mesa portions 39 are each formed by the inner peripheral wall 11 of the trench separation structure 10. The first end portion 182 and the second end portion 183 are each formed in a semicircular shape which is curved from the active region 22 to the outer region 21 in plan view.

That is, the inner peripheral wall 11 of the trench separation structure 10 has a plurality of internally curved portions 184 which are curved in semicircular shapes from the active region 22 to the outer region 21 at portions which demarcate the first end portion 182 and the second end portion 183 of each of the mesa portions 39 in plan view. On the other hand, the outer peripheral wall 12 of the trench separation structure 10 has a plurality of first externally curved portions 185 which are curved in circular-arc shapes from the active region 22 side to the outer region 21 side such as to follow the plurality of internally curved portions 184 of the inner peripheral wall 11 in plan view.

Further, the outer peripheral wall 12 of the trench separation structure 10 has a plurality of second externally curved portions 186 which are depressed toward the plurality of trench structures 30 in plan view. Specifically, the plurality of second externally curved portions 186 are each formed at a portion which faces a connecting portion of the trench separation structure 10 and the plurality of trench structures 30 in the outer peripheral wall 12. In this embodiment, the plurality of second externally curved portions 186 are depressed in a circular arc shape toward the plurality of trench structures 30 in plan view. The plurality of second externally curved portions 186 are connecting portions of the plurality of first externally curved portions 185.

The floating region 40 is formed in a mode substantially similar to that of the previously described first embodiment. The floating region 40 has the inner peripheral edge 41 on the trench separation structure 10 side and the outer peripheral edge 42 on the first to fourth side surfaces 5A to 5D side. The inner peripheral edge 41 of the floating region 40 is connected to the outer peripheral wall 12 of the trench separation structure 10. Thereby, the inner peripheral edge 41 of the floating region 40 is formed along the plurality of first externally curved portions 185 and the plurality of second externally curved portions 186 of the trench separation structure 10.

The outer peripheral edge 42 of the floating region 40 extends along the outer peripheral wall 12 of the trench separation structure 10 in plan view. In this embodiment, the outer peripheral edge 42 of the floating region 40 extends substantially in parallel with the outer peripheral wall 12 of the trench separation structure 10 in plan view. The outer peripheral edge 42 of the floating region 40 includes a plurality of first curved regions 187 which are each curved in a circular arc shape from the active region 22 side to the outer region 21 side such as to follow the plurality of first externally curved portions 185 of the trench separation structure 10 in plan view.

Further, the outer peripheral edge 42 of the floating region 40 includes a plurality of second curved regions 188 which are depressed toward the active region 22 side from the outer region 21 side such as to follow the plurality of second externally curved portions 186 of the trench separation structure 10 in plan view. In this embodiment, each of the second curved regions 188 is depressed in a circular arc shape toward each of the second externally curved portions 186 of the trench separation structure 10 in plan view. The plurality of second curved regions 188 are connecting regions of the plurality of first curved regions 187.

Although not shown specifically, the covering portion 43 of the floating region 40 covers the bottom wall 13 of the trench separation structure 10 at an interval from the active region 22 to the outer region 21 side at the plurality of first externally curved portions 185 and the plurality of second externally curved portions 186 of the trench separation structure 10. That is, the covering portion 43 exposes a portion of the bottom wall 13 of the trench separation structure 10 on the active region 22 side in the plurality of first externally curved portions 185 and the plurality of second externally curved portions 186.

As with the previously described first embodiment, the second portion 26 of the trench separation structure 10 is further depressed to the bottom portion side of the drift layer 7 with respect to the first portion 25 and demarcates the contact opening 27 with the active main surface 24. The second portion 26 of the trench separation structure 10 includes a plurality of first curved wall portions 189 which are each curved in a circular arc shape toward the outer region 21 side from the active region 22 side such as to follow the plurality of first externally curved portions 185 (the plurality of internally curved portions 184) of the trench separation structure 10.

Further, the second portion 26 of the trench separation structure 10 includes a plurality of second curved wall portions 190 which protrude toward the active region 22 side from the outer region 21 side such as to follow the plurality of second externally curved portions 186 of the trench separation structure 10. In this embodiment, each of the second curved wall portions 190 is each formed in a circular arc shape along the plurality of second externally curved portions 186 of the trench separation structure 10 in plan view.

As with the previously described first embodiment, the through hole 51 of the main surface insulating film 50 is communicatively connected to the contact opening 27. The through hole 51 includes a plurality of first curved penetration portions 191 which are each curved in a circular arc shape toward the outer region 21 side from the active region 22 side such as to follow the plurality of first externally curved portions 185 (the plurality of internally curved portions 184) of the trench separation structure 10. Each of the first curved penetration portions 191 is communicatively connected to each of the first curved wall portions 189 of the contact opening 27.

The through hole 51 also includes a plurality of second curved penetration portions 192 which protrude toward the active region 22 side from the outer region 21 side such as to follow the plurality of second externally curved portions 186 of the trench separation structure 10. In this embodiment, each of the second curved penetration portions 192 is formed in a circular arc shape along the plurality of second externally curved portions 186 of the trench separation structure 10 in plan view. Each of the first curved penetration portions 191 is communicatively connected to each of the second curved wall portions 190 of the contact opening 27.

As described above, the semiconductor device 181 according to the eighth embodiment is also able to achieve the same effects as those of the semiconductor device 1. Further, in the semiconductor device 181 according to the eighth embodiment, an edge portion of the trench separation structure 10, an edge portion of each of the plurality of trench structures 30 and an edge portion of each of the plurality of mesa portions 39 are chamfered. Therefore, it is possible to appropriately suppress an electric field concentration at the edge portion of the trench separation structure 10, the edge portion of each of the plurality of trench structures 30 and the edge portion of each of the plurality of mesa portions 39. The structure according to the eighth embodiment is applicable to other embodiments. As a matter of course, the structure according to the eighth embodiment may be applied to the first to the fourth reference embodiments.

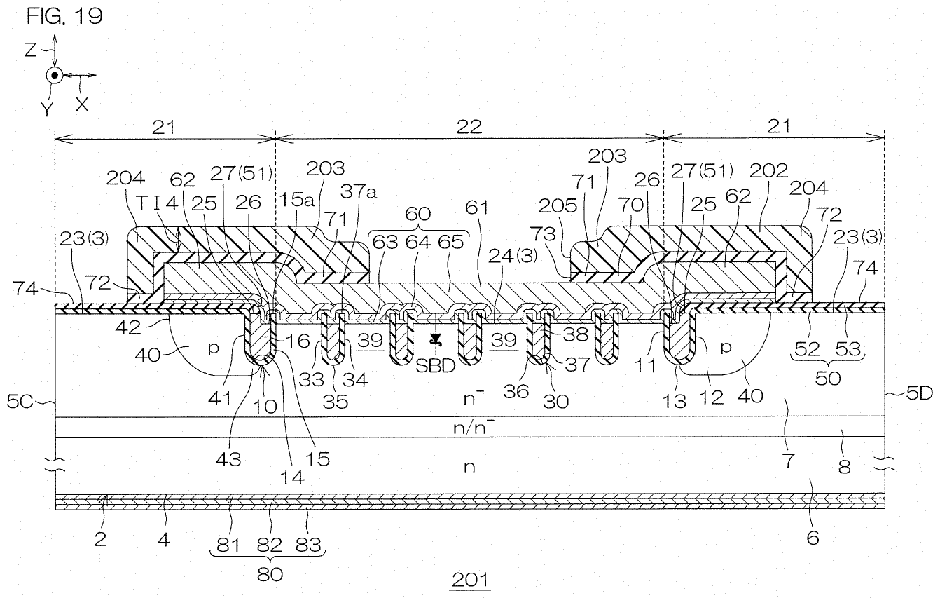

FIG. 19 is a drawing which corresponds to FIG. 4 and a cross-sectional view which shows a semiconductor device 201 according to the ninth embodiment of the present invention. Hereinafter, a structure corresponding to the structure described in the semiconductor device 1 will be given the same reference number, with a description thereof omitted.

With reference to FIG. 19, the semiconductor device 201 includes an organic insulating film 202 which covers the upper insulating film 70. The organic insulating film 202 includes a photosensitive resin. The photosensitive resin may be a negative type or a positive type. The organic insulating film 202 may contain at least one among polyimide, polyamide and polybenzoxazole. In this embodiment, the organic insulating film 202 contains polyimide.

The organic insulating film 202 is formed as a film on the upper insulating film 70. Specifically, the organic insulating film 202 is formed as a film along a main surface of the main surface insulating film 50, a side wall of a Schottky electrode 60 and a main surface of the Schottky electrode 60 on the upper insulating film 70. Thereby, the organic insulating film 202 has a first covering portion 203 which covers the Schottky electrode 60 across the upper insulating film 70 and a second covering portion 204 which covers the main surface insulating film 50 across the upper insulating film 70.

The first covering portion 203 covers a part of the main body portion 61 of the Schottky electrode 60 and an entire area of the lead-out portion 62 of the Schottky electrode 60 across the upper insulating film 70. The first covering portion 203 has a second pad opening 205 which is communicatively connected to the pad opening 73 of the upper insulating film 70 and forms a single pad opening with the pad opening 73. The second pad opening 205 exposes the central portion of the main body portion 61 of the Schottky electrode 60 together with the pad opening 73.

The first covering portion 203 faces the trench separation structure 10 and the floating region 40 across the upper insulating film 70 and the Schottky electrode 60 with regard to the normal direction Z. The first covering portion 203 preferably faces at least one trench structure 30 across the upper insulating film 70 and the Schottky electrode 60. That is, the organic insulating film 202 (first covering portion 203) preferably overlaps the trench separation structure 10, the floating region 40 and the trench structure 30 in plan view. In this embodiment, the organic insulating film 202 faces an entire area of the trench separation structure 10 and an entire area of the floating region 40 in plan view.

The second covering portion 204 covers the upper insulating film 70 at an interval from the first to fourth side surfaces 5A to 5D to the active region 22 side in plan view. In this embodiment, the second covering portion 204 covers the upper insulating film 70 at an interval from the floating region 40 to the outside (first to fourth side surfaces 5A to 5D side) in plan view. In this embodiment, the second covering portion 204 is formed in a quadrilateral shape having four sides which are parallel to the first to fourth side surfaces 5A to 5D.

The second covering portion 204 exposes a side wall portion of the upper insulating film 70 and forms the single dicing street 74 with the upper insulating film 70. The organic insulating film 202 has a fourth insulation thickness T4. The fourth insulation thickness T4 may be not less than 1 μm and not more than 50 μm. The fourth insulation thickness T4 is preferably not less than 5 μm and not more than 30 μm. The fourth insulation thickness T4 is preferably in excess of a third insulation thickness T3 of the upper insulating film 70.

As described above, the semiconductor device 201 according to the ninth embodiment is also able to achieve the same effects as those of the semiconductor device 1. The organic insulating film 202 according to the ninth embodiment is applicable to the previously described second to eighth embodiments. As a matter of course, the organic insulating film 202 according to the ninth embodiment may be applied to the first to the fourth reference embodiments.

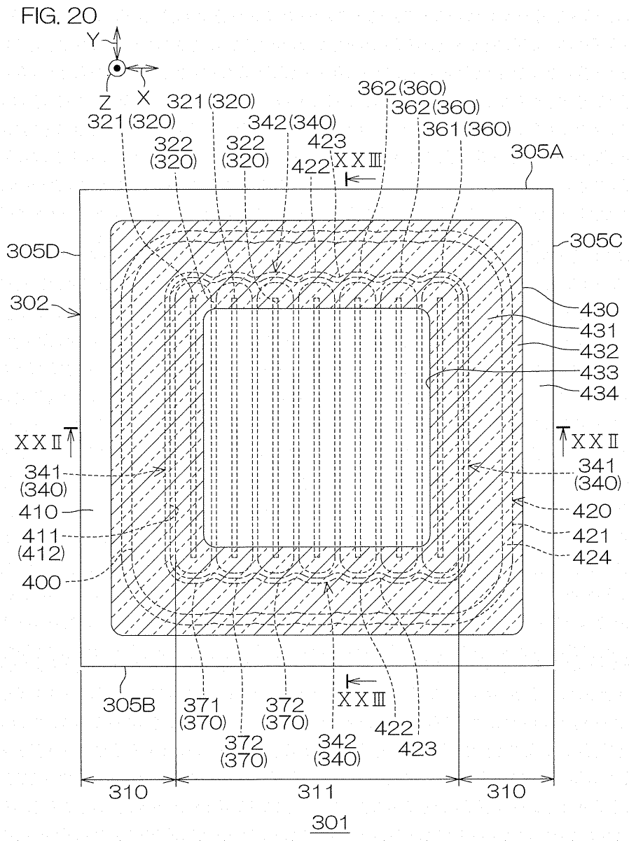

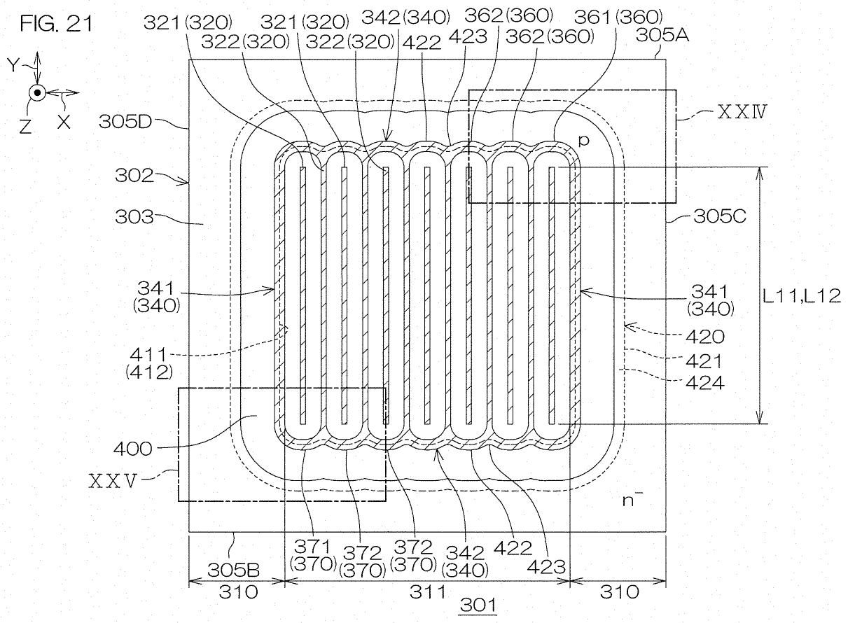

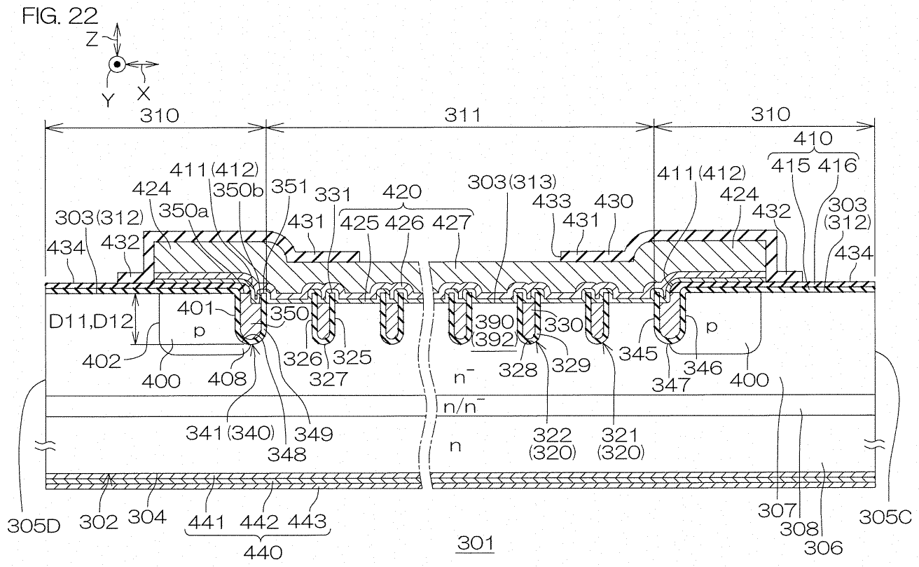

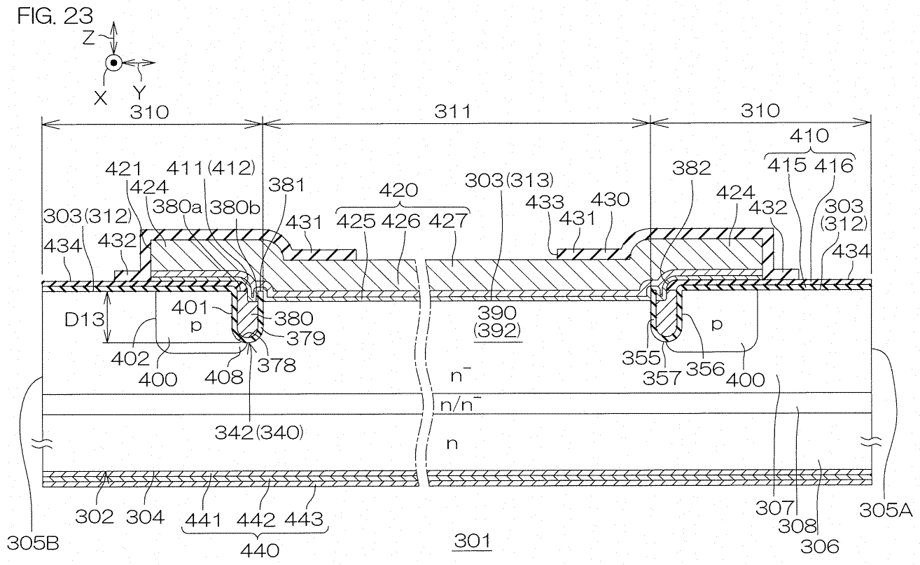

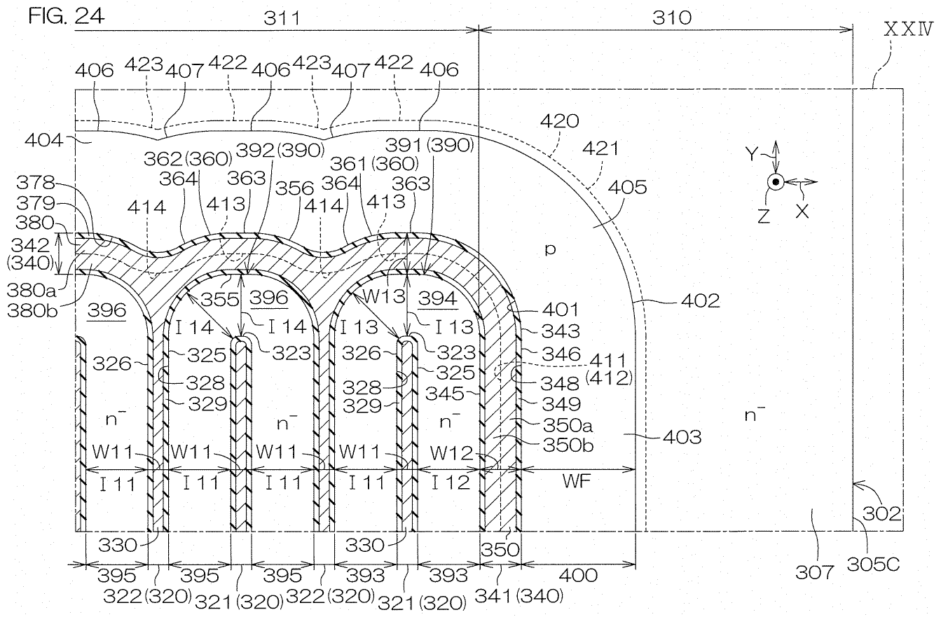

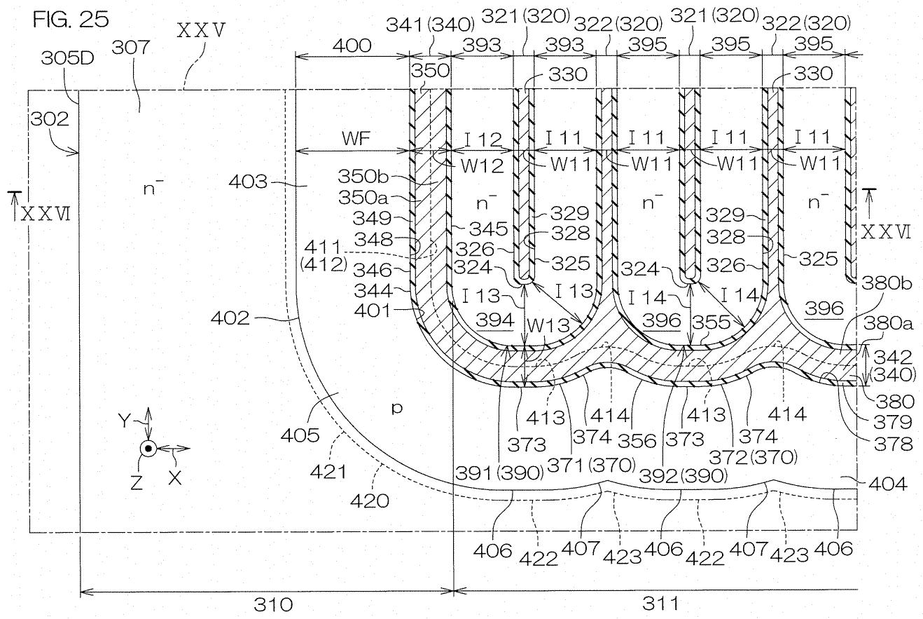

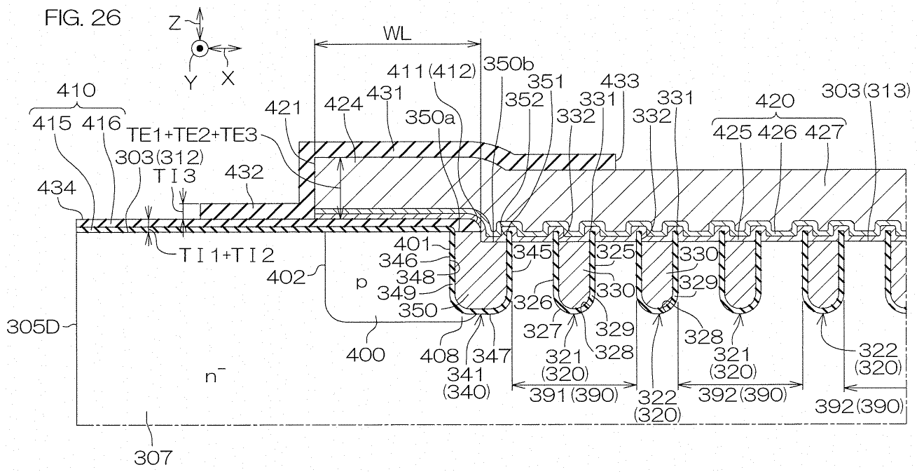

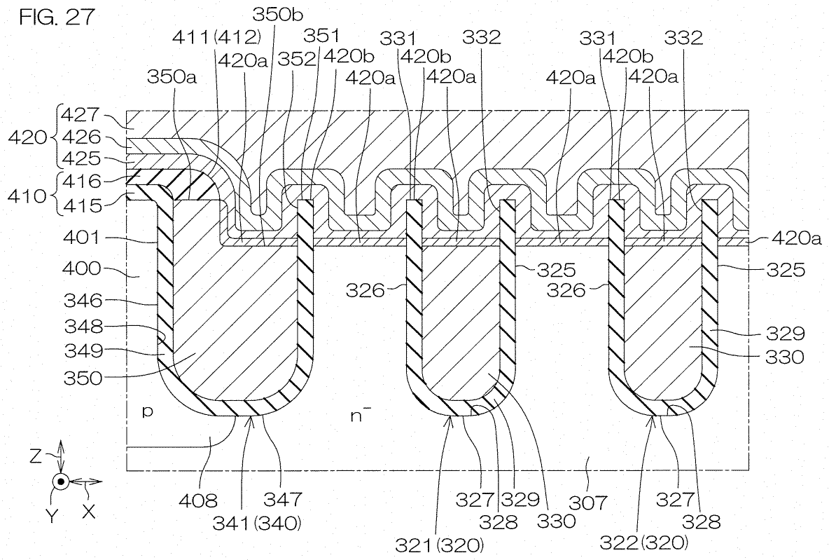

FIG. 20 is a plan view which shows a semiconductor device 301 according to the tenth embodiment of the present invention. FIG. 21 is a plan view which shows a structure of a first main surface 303 of a semiconductor chip 302 shown in FIG. 20. FIG. 22 is a cross-sectional view along line XXII-XXII shown in FIG. 20. FIG. 23 is a cross-sectional view along line XXIII-XXIII shown in FIG. 20. FIG. 24 is an enlarged view of a region XXIV shown in FIG. 21. FIG. 25 is an enlarged view of a region XXV shown in FIG. 21. FIG. 26 is a cross-sectional view along line XXVI-XXVI shown in FIG. 25. FIG. 27 is an enlarged view of a main portion shown in FIG. 26.

With reference to FIG. 20 to FIG. 27, the semiconductor device 301 is a semiconductor rectifying device which having an SBD (Schottky Barrier Diode). The semiconductor device 301 includes the semiconductor chip 302 in a rectangular parallelepiped shape. In this embodiment, the semiconductor chip 302 is constituted of an Si (silicon) chip. The semiconductor chip 302 has a first main surface 303 on one side, a second main surface 304 on the other side and first to fourth side surfaces 305A to 305D which connect the first main surface 303 and the second main surface 304.

The first main surface 303 and the second main surface 304 are each formed in a quadrilateral shape in plan view as viewed in the normal direction Z thereto (hereinafter, simply referred to as “in plan view”). The first main surface 303 is a device surface in which the SBD is formed. The second main surface 304 is a non-device surface. The second main surface 304 may be a ground surface having grinding marks. The first side surface 305A and the second side surface 305B extend in a first direction X along the first main surface 303 and faces each other in a second direction Y which intersects (specifically, orthogonal to) the first direction X. The third side surface 305C and the fourth side surface 305D extend in the second direction Y and faces each other in the first direction X.

The first to fourth side surfaces 305A to 305D may each be constituted of a ground surface which has grinding marks formed by cutting with a dicing blade or may each be constituted of a cleavage surface which has a modified layer formed by laser light irradiation. Specifically, the modified layer is constituted of a region in which a part of a crystalline structure of the semiconductor chip 302 is modified to other properties. That is, the modified layer is constituted of a region in which a density, a refractive index, a mechanical intensity (crystal strength) or other physical characteristics are modified to other properties different from the crystalline structure of the semiconductor chip 302.

The modified layer may include at least one layer among an amorphous layer, a melt re-hardened layer, a defect layer, a dielectric breakdown layer and a refractive index change layer. The amorphous layer is a layer in which a part of the semiconductor chip 302 is made amorphous. The melt re-hardened layer is a layer in which a part of the semiconductor chip 302 is hardened after being melted. The defect layer is a layer which includes a hole, a crack, etc., formed in the semiconductor chip 302. The dielectric breakdown layer is a layer in which a part of the semiconductor chip 302 has undergone dielectric breakdown. The refractive index change layer is a layer in which a part of the semiconductor chip 302 has changed to a refractive index different from the semiconductor chip 302.

The semiconductor device 301 includes an n-type (first conductivity type) cathode layer 306 (high concentration semiconductor layer) which is formed at a surface layer portion of the second main surface 304 of the semiconductor chip 302. The cathode layer 306 forms a cathode of the SBD. The cathode layer 306 is formed in an entire area of the surface layer portion of the second main surface 304 and exposed from the second main surface 304 and the first to fourth side surfaces 305A to 305D. That is, the cathode layer 306 has the second main surface 304 and a part of the first to fourth side surfaces 305A to 305D. The cathode layer 306 has a first electric resistivity. The first electric resistivity may be not less than 0.5 mΩ·cm and not more than 3 mΩ·cm.

The cathode layer 306 has an n-type impurity concentration which is substantially constant in a thickness direction. The n-type impurity concentration of the cathode layer 306 may be not less than 1×10¹⁸ cm⁻³ and not more than 1×10²¹ cm⁻³. A thickness of the cathode layer 306 may be not less than 5 μm and not more than 300 μm. The thickness of the cathode layer 306 is typically not less than 50 μm and not more than 300 μm. The thickness of the cathode layer 306 is adjusted by grinding the second main surface 304. In this embodiment, the cathode layer 306 is formed of an n-type semiconductor substrate (Si substrate).

The semiconductor device 301 includes an n-type drift layer 307 (semiconductor layer) which is formed at a surface layer portion of the first main surface 303 of the semiconductor chip 302. The drift layer 307 is formed in an entire area of the surface layer portion of the first main surface 303 and exposed from the first main surface 303 and the first to fourth side surfaces 305A to 305D. That is, the drift layer 307 has the first main surface 303 and a part of the first to fourth side surfaces 305A to 305D. The drift layer 307 is electrically connected to the cathode layer 306 and forms the cathode of the SBD together with the cathode layer 306. The drift layer 307 has a second electric resistivity in excess of the first electric resistivity of the cathode layer 306. The second electric resistivity may be not less than 0.1 Ω·cm and not more than 4 Ω·cm.

The drift layer 307 has an n-type impurity concentration which is less than the n-type impurity concentration of the cathode layer 306. The n-type impurity concentration of the drift layer 307 may be not less than 1×10¹⁵ cm⁻³ and not more than 1×10¹⁶ cm⁻³. A thickness of the drift layer 307 may be not less than 2 μm and not more than 20 μm. In this embodiment, the drift layer 307 is formed of an n-type epitaxial layer (Si epitaxial layer).

The semiconductor device 301 includes an n-type buffer layer 308 which is interposed between the cathode layer 306 and the drift layer 307 in the semiconductor chip 302. The buffer layer 308 is interposed in an entire area of a region between the cathode layer 306 and the drift layer 307 and exposed from the first to fourth side surfaces 305A to 305D. That is, the buffer layer 308 has a part of the first to fourth side surfaces 305A to 305D.

The buffer layer 308 is electrically connected to the cathode layer 306 and the drift layer 307 and forms the cathode of the SBD together with the cathode layer 306 and the drift layer 307. The buffer layer 308 has a concentration gradient in which the n-type impurity concentration decreases (specifically, decrease gradually) from the n-type impurity concentration of the cathode layer 306 to the n-type impurity concentration of the drift layer 307. A thickness of the buffer layer 308 may be not less than 1 μm and not more than 10 μm. In this embodiment, the buffer layer 308 is formed by an n-type epitaxial layer (Si epitaxial layer).

The semiconductor device 301 includes an outer region 310 which is set in the first main surface 303. The outer region 310 is a region in which no SBD is formed. The outer region 310 is set at a peripheral edge portion of the first main surface 303. In this embodiment, the outer region 310 is set in an annular shape (specifically, in a quadrilateral annular shape) which extends in a band shape along a peripheral edge (first to fourth side surfaces 305A to 305D) of the first main surface 303 in plan view and surrounds an inner portion of the first main surface 303.

The semiconductor device 301 includes an active region 311 which is set in the first main surface 303. The active region 311 is a region in which the SBD is formed. The active region 311 is set at an inner portion of the first main surface 303 at an interval internally from the peripheral edge of the first main surface 303 in plan view. Specifically, the active region 311 is set in a region which is surrounded by the outer region 310 in plan view. In this embodiment, the active region 311 is set in a quadrilateral shape which has four sides extending along the peripheral edge of the first main surface 303 in plan view.

The semiconductor device 301 includes an outer main surface 312 which is positioned in the outer region 310 on the first main surface 303 and an active main surface 313 which is positioned in the active region 311 on the first main surface 303. In this embodiment, the active main surface 313 is depressed to the bottom portion side of the drift layer 307 (the second main surface 304 side) with respect to the outer main surface 312. An n-type impurity concentration of the drift layer 307 at a surface layer portion of the active main surface 313 is higher than an n-type impurity concentration of the drift layer 307 at a surface layer portion of the outer region 310. With regard to the normal direction Z, the active main surface 313 is preferably depressed in a range in excess of 0 μm and not more than 0.5 μm (preferably, not more than 0.1 μm) with respect to the outer main surface 312.

The semiconductor device 301 includes a plurality of trench structures 320 which are formed in the first main surface 303. In FIG. 20 and FIG. 21, for the sake of convenience, 13 trench structures 320 are shown. However, in reality, the number of the trench structures 320 is set in various numbers depending on a size of the semiconductor chip 302. The number of the trench structures 320 may be, for example, not less than 50 and not more than 1000. The number of the trench structures 320 may be any one of the number ranges such as not less than 50 and not more than 250, not less than 250 and not more than 500, not less than 500 and not more than 750, and not less than 750 and not more than 1000.

The plurality of trench structures 320 are formed in the active region 311. That is, the plurality of trench structures 320 are formed in the active main surface 313 which is depressed to the bottom portion side of the drift layer 307 with respect to the outer main surface 312. Therefore, the plurality of trench structures 320 are formed in the bottom portion side of the drift layer 307 with respect to the outer main surface 312. The plurality of trench structures 320 are formed at intervals from the bottom portion of the drift layer 307 (that is, buffer layer 308) to the first main surface 303 side and faces the cathode layer 306 (buffer layer 308) across a part of the drift layer 307.

The plurality of trench structures 320 are arrayed in the first main surface 303 at a first interval I11 in the first direction X in plan view and each formed in a band shape extending in the second direction Y. That is, the plurality of trench structures 320 are arrayed in a stripe shape extending in one direction (second direction Y). The first interval I11 may be not less than 0.5 μm and not more than 5 μm. The first interval I11 is preferably not less than 0.7 μm and not more than 4 μm.

Specifically, the plurality of trench structures 320 include an n+1 number (n≥1) of first trench structures 321 and an n number (n≥1) of second trench structures 322. That is, a total number of the plurality of trench structures 320 is an odd number. The n+1 number (n≥1) of the first trench structures 321 and the n number (n≥1) of the second trench structures 322 are alternately arrayed at the first interval I11 in the first direction X, with the two first trench structures 321 given as a starting point of the array and an ending point of the array.

Each of the trench structures 320 has a first end portion 323 on one side (first side surface 305A side) and a second end portion 324 on the other side (second side surface 305B side) with regard to the second direction Y. Each of the trench structures 320 has a first side wall 325 on one side (third side surface 305C side), a second side wall 326 on the other side (fourth side surface 305D side) and a bottom wall 327.

The first side wall 325 and the second side wall 326 extend substantially in parallel in the second direction Y. The bottom wall 327 connects the first side wall 325 and the second side wall 326. The bottom wall 327 is preferably formed in a curved shape toward the second main surface 304. The bottom wall 327 may have a flat surface parallel to the first main surface 303. In this case, it is preferable that a corner portion which connects the first side wall 325 and the bottom wall 327 and a corner portion which connects the second side wall 326 and the bottom wall 327 are each formed in a curved shape.

Each of the trench structures 320 may be formed in a vertical shape in which a width (that is, opening width) between the first side wall 325 and the second side wall 326 is substantially constant toward the bottom wall 327. Each of the trench structures 320 may be formed in a tapered shape in which the width (that is, opening width) between the first side wall 325 and the second side wall 326 is narrowed toward the bottom wall 327.

Each of the trench structures 320 has a first width W11. The first width W11 is a width in a direction (that is, first direction X) orthogonal to a direction in which each of the trench structures 320 extends. The first width W11 may be equal to or less than the first interval I11 (W11≤I11). The first width W11 is preferably less than the first interval I11 (W11<I11). The first width W11 may be not less than 0.1 μm and not more than 2 μm. The first width W11 is preferably not less than 0.4 μm and not more than 1.2 μm.

Each of the trench structures 320 has a first length L11. The first length L11 is a length in a direction (that is, second direction Y) in which each of the trench structures 320 extends. The first length L11 is arbitrary and may be in excess of the first width W11. The first length L11 may be not less than 100 times and not more than 2000 times larger than the first width W11. The first length L11 may be not less than 100 μm and not more than 1500 μm.

Each of the trench structures 320 has a first depth D11. The first depth D11 is a distance between the outer main surface 312 and the bottom wall 327 of each of the trench structures 320 and may be not less than 1 μm and not more than 5 μm. The first depth D11 is preferably not less than 1.5 μm and not more than 3 μm. Each of the trench structures 320 may be formed at an interval of not less than 1 μm and not more than 6 μm from a bottom portion of the drift layer 307. Each of the trench structures 320 is preferably formed at an interval of not less than 1.5 μm and not more than 5 μm from the bottom portion of the drift layer 307.

The plurality of trench structures 320 each include a trench 328, an insulating film 329 and an electrode 330. The trench 328 is dug down from the first main surface 303 to the second main surface 304. The trench 328 forms the first side wall 325, the second side wall 326 and the bottom wall 327 of the trench structure 320. The first side wall 325, the second side wall 326 and the bottom wall 327 form a wall surface (inner wall and outer wall) of the trench 328. The trench 328 exposes the drift layer 307 from the first side wall 325, the second side wall 326 and the bottom wall 327.

The insulating film 329 is formed as a film along the wall surface of the trench 328 and demarcates a recess space inside the trench 328. In this embodiment, the insulating film 329 includes a silicon oxide film. A thickness of the insulating film 329 may be not less than 0.05 μm and not more than 0.5 μm. The thickness of the insulating film 329 is preferably not less than 0.1 μm and not more than 0.4 μm.

The electrode 330 is embedded in the trench 328 across the insulating film 329. An upper end portion of the electrode 330 is preferably positioned on the bottom wall side of the trench 328 with respect to the outer main surface 312. In this embodiment, the electrode 330 contains conductive polysilicon. The conductive polysilicon may be n-type polysilicon or p-type polysilicon.

The semiconductor device 301 includes a first protrusion portion 331 which is constituted of an upper end portion of the insulating film 329 and protrudes as a wall from the first main surface 303. In other words, the insulating film 329 has the first protrusion portion 331 which protrudes as a wall from the first main surface 303. That is, the first protrusion portion 331 is also one constituent of the trench structure 320. Specifically, the first protrusion portion 331 protrudes upper than the electrode 330 from the active main surface 313 and separates the active main surface 313 and the electrode 330.

The first protrusion portion 331 is formed in a depth range between the outer main surface 312 and the active main surface 313. The first protrusion portion 331 may be formed at an interval on the active main surface 313 side with respect to the outer main surface 312. A leading end portion of the first protrusion portion 331 may be inclined downward in an oblique direction toward an inner portion of the trench 328. The first protrusion portion 331 demarcates a first recess 332 with the electrode 330 at the inner portion of the trench 328.

The first protrusion portion 331 extends in a band shape along the wall surface of the trench 328 in plan view. The first protrusion portion 331 on the first trench structure 321 side is formed in an annular shape which surrounds the electrode 330 in plan view. The first protrusion portion 331 on the second trench structure 322 side is formed in a band shape extending along the electrode 330 in plan view. The first protrusion portion 331 preferably protrudes in a range in excess of 0 μm and not more than 0.5 μm (preferably, not more than 0.1 μm) with respect to the active main surface 313.

The semiconductor device 301 includes a trench separation structure 340 formed in the first main surface 303. The trench separation structure 340 is formed in the outer region 310 at an interval from the peripheral edge (first to fourth side surfaces 305A to 305D) of the first main surface 303 and formed in an annular shape (in this embodiment, in a quadrilateral annular shape) which surrounds the active region 311. That is, the trench separation structure 340 collectively surrounds the plurality of trench structures 320 in plan view and demarcates the outer region 310 and the active region 311 in the first main surface 303. Further, the trench separation structure 340 is formed in the outer main surface 312 which protrudes upper than the active main surface 313. The trench separation structure 340 is formed at an interval from the bottom portion of the drift layer 307 (that is, buffer layer 308) to the first main surface 303 side and faces the cathode layer 306 (buffer layer 308) across a part of the drift layer 307.

The trench separation structure 340 includes integrally a pair of first trench separation structures 341 and a pair of second trench separation structures 342. The pair of first trench separation structures 341 are formed at an interval in the first direction X such as to sandwich the active region 311 and each formed in a band shape extending in the second direction Y. One of the first trench separation structures 341 is formed in one side (third side surface 305C side) with respect to the active region 311 and the other of the first trench separation structures 341 is formed in the other side (fourth side surface 305D side) with respect to the active region 311.

Each of the first trench separation structures 341 is formed in the first main surface 303 at a second interval I12 in the first direction X from the outermost first trench structure 321 such as to face the outermost second trench structure 322 across the outermost first trench structure 321. The second interval I12 may be equal to or larger than the first width W11 of each of the trench structures 320 (W11≤I12). The second interval I12 is preferably in excess of the first width W11 (W11<I12). The second interval I12 preferably falls within a range of not less than 0.9 times and not more than 1.1 times larger than the first interval I11 of the plurality of trench structures 320. It is particularly preferable that the second interval 112 is substantially equal to the first interval I11 (I11≈I12). The second interval I12 may be not less than 0.5 μm and not more than 5 μm. The second interval I12 is preferably not less than 0.7 μm and not more than 4 μm.

Each of the first trench separation structures 341 has a first end portion 343 on one side (first side surface 305A side) and a second end portion 344 on the other side (second side surface 305B side) with regard to the second direction Y. The first end portion 343 of each of the first trench separation structure 341 is preferably positioned on the same line with the first end portion 323 of each of the trench structures 320. The second end portion 344 of each of the first trench separation structures 341 is preferably positioned on the same line with the second end portion 324 of each of the trench structures 320. Each of the first trench separation structures 341 has a first side wall 345 on one side (active region 311 side), a second side wall 346 on the other side (outer region 310 side) and a bottom wall 347.

The first side wall 345 and the second side wall 346 extend substantially in parallel in the second direction Y. The bottom wall 347 connects the first side wall 345 and the second side wall 346. The bottom wall 347 is preferably formed in a curved shape toward the second main surface 304. The bottom wall 347 may have a flat surface which is parallel to the first main surface 303. In this case, it is preferable that a corner portion which connects the first side wall 345 and the bottom wall 347 and a corner portion which connects the second side wall 346 and the bottom wall 347 are each formed in a curved shape.

Each of the first trench separation structures 341 may be formed in a vertical shape in which a width (that is, opening width) between the first side wall 345 and the second side wall 346 is substantially constant toward the bottom wall 347. Each of the first trench separation structures 341 may be formed in a tapered shape in which the width (that is, opening width) between the first side wall 345 and the second side wall 346 is narrowed toward the bottom wall 347.

Each of the first trench separation structures 341 has a second width W12. The second width W12 is a width in a direction (first direction X) orthogonal to a direction in which the first trench separation structure 341 extends. The second width W12 may be equal to or less than the second interval I12 (W12≤I12). The second width W12 is preferably less than the second interval I12 (W12<I12). The second width W12 may be equal to or larger than the first width W11 of each of the trench structures 320 (W11≤W12). The second width W12 is preferably in excess of the first width W11 (W11<W12). That is, each of the first trench separation structures 341 is preferably formed wider than the each of the trench structures 320. The second width W12 may be not less than 0.5 μm and not more than 3 μm. The second width W12 is preferably not less than 0.8 μm and not more than 1.5 μm.

Each of the first trench separation structures 341 has a second length L12. The second length L12 is a length in a direction (that is, second direction Y) in which each of the first trench separation structures 341 extends. The second length L12 is arbitrary and may be in excess of the second width W12. The second length L12 preferably falls within a range of not less than 0.9 times and not more than 1.1 times larger than the first length L11. It is particularly preferable that the second length L12 is substantially equal to the first length L11 (L11≈L12).

Each of the first trench separation structures 341 has a second depth D12. The second depth D12 is a distance between the outer main surface 312 and the bottom wall 347 of each of the first trench separation structures 341. The second depth D12 may be equal to or larger than the first depth D11 of each of the trench structures 320 (D11≤D12). The second depth D12 is preferably in excess of the first depth D11 (D11<D12). That is, each of the first trench separation structures 341 is preferably formed deeper than each of the trench structures 320.

In this case, the bottom wall 347 of each of the first trench separation structures 341 is positioned on the bottom portion (that is, buffer layer 308) side of the drift layer 307 with respect to the bottom wall 327 of each of the trench structures 320. A difference between the second depth D12 and the first depth D11 (D12−D11) is preferably in excess of 0 μm and not more than 0.5 μm. It is particularly preferable that the difference (D12−D11) is not more than 0.2 μm. As a matter of course, the second depth D12 may be substantially equal to the first depth D11.

The second depth D12 may be not less than 1 μm and not more than 5 μm. The second depth D12 is preferably not less than 1.5 μm and not more than 3 μm. Each of the first trench separation structures 341 may be formed at an interval of not less than 1 μm and not more than 6 μm from the bottom portion of the drift layer 307. Each of the first trench separation structures 341 is preferably formed at an interval of not less than 1.5 μm and not more than 5 μm from the bottom portion of the drift layer 307.

Each of the first trench separation structures 341 includes a first separation trench 348, a first separation insulating film 349 and a first separation electrode 350. The first separation trench 348 is dug down toward the second main surface 304 from the first main surface 303. The first separation trench 348 forms the first side wall 345, the second side wall 346 and the bottom wall 347 of each of the first trench separation structures 341. The first side wall 345, the second side wall 346 and the bottom wall 347 form the wall surface (inner wall and outer wall) of the first separation trench 348. The first separation trench 348 exposes the drift layer 307 from the first side wall 345, the second side wall 346 and the bottom wall 347.

The first separation insulating film 349 is formed as a film along the wall surface of the first separation trench 348 and demarcates a recess space inside the first separation trench 348. In this embodiment, the first separation insulating film 349 includes a silicon oxide film. A thickness of the first separation insulating film 349 may be not less than 0.05 μm and not more than 0.5 μm. The thickness of the first separation insulating film 349 is preferably not less than 0.1 μm and not more than 0.4 μm. The thickness of the first separation insulating film 349 is preferably in excess of the thickness of the insulating film 329. As a matter of course, in consideration of the convenience of the manufacturing method, the first separation insulating film 349 which is substantially equal in thickness to the insulating film 329 may be formed.

The first separation electrode 350 is embedded in the first separation trench 348 across the first separation insulating film 349. In this embodiment, the first separation electrode 350 contains conductive polysilicon. The conductive polysilicon may be n-type polysilicon or p-type polysilicon. The first separation electrode 350 includes the same electrode material as the electrode 330 of each of the trench structures 320.

An upper end portion of the first separation electrode 350 includes a first portion 350a on the outer region 310 side and a second portion 350b on the active region 311 side. The second portion 350b is depressed to the bottom wall 347 side of the first separation trench 348 with respect to the first portion 350a. The second portion 350b is preferably positioned on the bottom wall 347 side of the first separation trench 348 with respect to the outer main surface 312. The second portion 350b is preferably depressed in a range in excess of 0 μm and not more than 0.5 μm (preferably, not more than 0.1 μm) with respect to the first portion 350a.

The semiconductor device 301 includes a second protrusion portion 351 which is constituted of an upper end portion of the first separation insulating film 349 and protrudes as a wall from the first main surface 303 at a portion which covers the first side wall 345 in the first separation insulating film 349. In other words, the first separation insulating film 349 has the second protrusion portion 351 which protrudes as a wall from the first main surface 303. That is, the second protrusion portion 351 is also one constituent of each of the first trench separation structures 341. Specifically, the second protrusion portion 351 protrudes upper than the first separation electrode 350 (specifically, second portion 350b) from the active main surface 313 and separates the active main surface 313 and the first separation electrode 350.

The second protrusion portion 351 is formed in a depth range between the outer main surface 312 and the active main surface 313. The second protrusion portion 351 may be formed at an interval on the active main surface 313 side with respect to the outer main surface 312. A leading end portion of the second protrusion portion 351 may be inclined downward in an oblique direction to an inner portion of the first separation trench 348. The second protrusion portion 351 demarcates a second recess 352 between the first portion 350a and the second portion 350b of the first separation electrode 350 at an inner portion of the first separation trench 348. The second protrusion portion 351 extends in a band shape along the first side wall 345 of the first separation trench 348 in plan view. The second protrusion portion 351 preferably protrudes in a range in excess of 0 μm and not more than 0.5 μm (preferably, not more than 0.1 μm) with respect to the active main surface 313.

The pair of second trench separation structures 342 are formed at an interval in the second direction Y such as to sandwich the active region 311 and each formed in a band shape extending in the first direction X. One of the second trench separation structures 342 is formed in one side (first side surface 305A side) in the second direction Y with respect to the active region 311. The other of the second trench separation structures 342 is formed in the other side (second side surface 305B side) in the second direction Y with respect to the active region 311.

That is, one of the second trench separation structures 342 is formed on the first end portion 323 side of the plurality of trench structures 320 and on the first end portion 343 side of the pair of first trench separation structures 341. Further, the other of the second trench separation structures 342 is formed on the second end portion 324 side of the plurality of trench structures 320 and on the second end portion 344 side of the pair of first trench separation structures 341.

Each of the second trench separation structures 342 has a first side wall 355 on one side (active region 311 side), a second side wall 356 on the other side (outer region 310 side) and a bottom wall 357. The first side wall 355 and the second side wall 356 extend substantially in parallel with each other. The bottom wall 357 connects the first side wall 355 and the second side wall 356. The bottom wall 357 is preferably formed in a curved shape toward the second main surface 304. The bottom wall 357 may have a flat surface which is parallel to the first main surface 303. In this case, it is preferable that a corner portion which connects the first side wall 355 and the bottom wall 357 and a corner portion which connects the second side wall 356 and the bottom wall 357 are each formed in a curved shape.

Each of the second trench separation structures 342 may be formed in a vertical shape in which a width (that is, opening width) between the first side wall 355 and the second side wall 356 is substantially constant toward the bottom wall 357. Each of the second trench separation structures 342 may be formed in a tapered shape in which the width (that is, opening width) between the first side wall 355 and the second side wall 356 is narrowed toward the bottom wall 357.

Each of the second trench separation structures 342 has a third width W13. The third width W13 is a width in a direction orthogonal to a direction in which each of the second trench separation structures 342 extends. The third width W13 may be equal to or less than the second interval I12 between each of the first trench separation structures 341 (W13≤I12). The third width W13 is preferably less than the second interval I12 (W13<I12). The third width W13 may be equal to or larger than the first width W11 of each of the trench structures 320 (W11≤W13). The third width W13 is preferably in excess of the first width W11 (W11<W13).

That is, each of the second trench separation structures 342 is preferably formed wider than each of the trench structures 320. The third width W13 preferably falls within a range of not less than 0.9 times and not more than 1.1 times larger than the second width W12 of the first trench separation structure 341. It is particularly preferable that the third width W13 is substantially equal to the second width W12 (W12≈W13). The third width W13 may be not less than 0.5 μm and not more than 3 μm. The third width W13 is preferably not less than 0.8 μm and not more than 1.5 μm.

Each of the second trench separation structures 342 has a third depth D13. The third depth D13 is a distance between the outer main surface 312 and the bottom wall 357 of each of the second trench separation structures 342. The third depth D13 may be equal to or more than the first depth D11 of each of the trench structures 320 (D11≤D13). The third depth D13 is preferably in excess of the first depth D11 (D11<D13). That is, each of the second trench separation structures 342 is preferably formed deeper than each of the trench structures 320. In this case, the bottom wall 357 of each of the second trench separation structures 342 is positioned on the bottom portion (that is, buffer layer 308) side of the drift layer 307 with respect to the bottom wall 327 of each of the trench structures 320. As a matter of course, the third depth D13 may be substantially equal to the first depth D11.

The third depth D13 preferably falls within a range of not less than 0.9 times and not more than 1.1 times larger than the second depth D12 of the first trench separation structure 341. It is preferable that the third depth D13 is substantially equal to the second depth D12 (D12≈D13). A difference between the third depth D13 and the first depth D11 (D13−D11) is preferably in excess of 0 μm and not more than 0.5 μm. It is particularly preferable that the difference (D13−D11) is not more than 0.2 μm.

The third depth D13 may be not less than 1 μm and not more than 5 μm. The third depth D13 is preferably not less than 1.5 μm and not more than 3 μm. Each of the second trench separation structures 342 may be formed at an interval of not less than 1 μm and not more than 6 μm from the bottom portion of the drift layer 307. Each of the second trench separation structures 342 is preferably formed at an interval of not less than 1.5 μm and not more than 5 μm from the bottom portion of the drift layer 307.

With reference to FIG. 24, one of the second trench separation structures 342 has a plurality of first connecting portions 360. The plurality of first connecting portions 360 include two first outer connecting portions 361 and a plurality of first internal connecting portions 362. Since the two first outer connecting portions 361 are similar in mode, hereinafter, a description will be given of one first outer connecting portion 361. The first outer connecting portion 361 is connected to the first end portion 343 of the first trench separation structure 341 and the first end portion 323 of the outermost second trench structure 322 at a third interval I13 from the first end portion 323 of the outermost first trench structure 321.

The first side wall 355 of the first outer connecting portion 361 continues to the first side wall 325 of the second trench structure 322 and the first side wall 345 of the first trench separation structure 341. The second side wall 356 of the first outer connecting portion 361 continues to the second side wall 346 of the first trench separation structure 341 and extends substantially in parallel with the first side wall 355.

The first outer connecting portion 361 extends between the first end portion 323 of the second trench structure 322 and the first end portion 343 of the first trench separation structure 341 in a circular arc shape which is curved in a direction away from the first end portion 323 of the first trench structure 321 (that is, toward the peripheral edge of the first main surface 303). The first outer connecting portion 361 extends in a circular arc shape, with the first end portion 323 of the first trench structure 321 given as a central portion. The first outer connecting portion 361 preferably extends in a semicircular arc shape, with the first end portion 323 of the first trench structure 321 given as a central portion.

That is, the first outer connecting portion 361 preferably extends between the first end portion 323 of the second trench structure 322 and the first end portion 343 of the first trench separation structure 341 in a circular arc shape which has a circular-arc angle of 180°. The first outer connecting portion 361 preferably extends in a circular arc shape at the third interval I13 which is substantially constant from the first end portion 323 of the first trench structure 321. That is, the first outer connecting portion 361 preferably extends in a circular arc shape which has the third interval I13 as a curvature radius with respect to the first end portion 323 of the first trench structure 321.

The first outer connecting portion 361 has a facing portion which faces the first end portion 323 of the first trench structure 321 with regard to the second direction Y. The facing portion of the first outer connecting portion 361 linearly extends along the first direction X. That is, the facing portion of the first outer connecting portion 361 extends substantially in parallel with the first end portion 323 of the first trench structure 321.

The plurality of first internal connecting portions 362 are continuously led out in the first direction X from the plurality of first outer connecting portions 361. Since the plurality of first internal connecting portions 362 are similar in mode, hereinafter, a description will be given of one first internal connecting portion 362. The first internal connecting portion 362 is connected to the first end portions 323 of the two adjacent second trench structures 322 at a fourth interval I14 from the first end portion 323 of the first trench structure 321.

The first side wall 355 of the first internal connecting portion 362 continues to the first side wall 325 of one of the second trench structures 322 and the second side wall 326 of the other of the second trench structure 322. The second side wall 356 of the first internal connecting portion 362 continues to the second side wall 356 of the first outer connecting portion 361 and the second side wall 356 of the adjacent first internal connecting portion 362 and extends substantially in parallel with the first side wall 355.

The first internal connecting portion 362 extends between the first end portions 323 of the two adjacent second trench structures 322 in a circular arc shape which is curved in a direction away from the first end portion 323 of the first trench structure 321 (that is, toward the peripheral edge of the first main surface 303). The first internal connecting portion 362 extends in a circular arc shape, with the first end portion 323 of the first trench structure 321 given as a central portion. The first internal connecting portion 362 preferably extends in a semicircular arc shape, with the first end portion 323 of the first trench structure 321 given as a central portion.

That is, the first internal connecting portion 362 preferably extends between the first end portions 323 of the two adjacent second trench structures 322 in a circular arc shape which has a circular-arc angle of 180°. The first internal connecting portion 362 preferably extends in a circular arc shape at the fourth interval I14 which is substantially constant from the first end portion 323 of the first trench structure 321. That is, the first internal connecting portion 362 preferably extends in a circular arc shape which has the fourth interval I14 as a curvature radius with respect to the first end portion 323 of the first trench structure 321.

The first internal connecting portion 362 has a facing portion which faces the first end portion 323 of the first trench structure 321 with regard to the second direction Y. The facing portion of the first internal connecting portion 362 linearly extends along the first direction X. That is, the facing portion of the first internal connecting portion 362 extends substantially in parallel with the first end portion 323 of the first trench structure 321.

As described above, one of the second trench separation structures 342 is formed in a band shape which extends in the first direction X while meandering along the plurality of first connecting portions 360 in plan view. That is, one of the second trench separation structures 342 has a plurality of first externally curved portions 363 and a plurality of first internally curved portions 364 which are formed alternately in the first direction X in plan view. The plurality of first externally curved portions 363 face the plurality of first trench structures 321 in a one-to-one correspondence relationship in the second direction Y in plan view and are curved in a circular arc shape in a direction away from the plurality of first trench structures 321. The plurality of first internally curved portions 364 face the plurality of second trench structures 322 in a one-to-one correspondence relationship in the second direction Y in plan view and are depressed to the plurality of second trench structures 322.

With reference to FIG. 25, the other of the second trench separation structures 342 has a plurality of second connecting portions 370. The plurality of second connecting portions 370 include two second outer connecting portions 371 and a plurality of second internal connecting portions 372. Since the two second outer connecting portions 371 are similar in mode, hereinafter, a description will be given of one second outer connecting portion 371. The second outer connecting portion 371 is connected to the second end portion 324 of the outermost second trench structure 322 and the second end portion 344 of the first trench separation structure 341 at the third interval I13 from the second end portion 324 of the outermost first trench structure 321. The second outer connecting portion 371 faces the first outer connecting portion 361 in the second direction Y across the outermost first trench structure 321.

The first side wall 355 of the second outer connecting portion 371 continues to the second side wall 326 of the second trench structure 322 and the first side wall 345 of the first trench separation structure 341. The second side wall 356 of the second outer connecting portion 371 continues to the second side wall 346 of the first trench separation structure 341 and extends substantially in parallel with the first side wall 355.

The second outer connecting portion 371 extends between the second end portion 324 of the second trench structure 322 and the second end portion 344 of the first trench separation structure 341 in a circular arc shape which is curved in a direction away from the second end portion 324 of the first trench structure 321 (that is, toward the peripheral edge of the first main surface 303). The second outer connecting portion 371 extends in a circular arc shape, with the second end portion 324 of the first trench structure 321 given as a central portion. The second outer connecting portion 371 preferably extends in a semicircular arc shape, with the second end portion 324 of the first trench structure 321 given as a central portion.

That is, the second outer connecting portion 371 preferably extends between the second end portion 324 of the second trench structure 322 and the second end portion 344 of the first trench separation structure 341 in a circular arc shape which has a circular-arc angle of 180°. The second outer connecting portion 371 preferably extends in a circular arc shape at the third interval I13 which is substantially constant from the second end portion 324 of the first trench structure 321. That is, the second outer connecting portion 371 preferably extends in a circular arc shape which has the third interval I13 as a curvature radius with respect to the second end portion 324 of the first trench structure 321.

The second outer connecting portion 371 has a facing portion which faces the second end portion 324 of the first trench structure 321 with regard to the second direction Y. The facing portion of the second outer connecting portion 371 linearly extends along the first direction X. That is, the facing portion of the second outer connecting portion 371 extends substantially in parallel with the second end portion 324 of the first trench structure 321.

The plurality of second internal connecting portions 372 are continuously led out from the plurality of second outer connecting portions 371 in the first direction X. Since the plurality of second internal connecting portions 372 are similar in mode, hereinafter, a description will be given of one second internal connecting portion 372. The second internal connecting portion 372 is connected to the second end portions 324 of the two adjacent second trench structures 322 at the fourth interval I14 from the second end portion 324 of the first trench structure 321. The second internal connecting portion 372 faces the first internal connecting portion 362 in the second direction Y across the first trench structure 321.

The first side wall 355 of the second internal connecting portion 372 continues to the first side wall 325 of one of the second trench structures 322 and the second side wall 326 of the other of the second trench structures 322. The second side wall 356 of the second internal connecting portion 372 continues to the second side wall 356 of the second outer connecting portion 371 and the second side wall 356 of the adjacent second internal connecting portion 372, extending substantially in parallel with the first side wall 355.

The second internal connecting portion 372 extends in the second end portions 324 of the two adjacent second trench structures 322 in a circular arc shape which is curved in a direction away from the second end portion 324 of the first trench structure 321 (that is, toward the peripheral edge of the first main surface 303). The second internal connecting portion 372 extends in a circular arc shape, with the second end portion 324 of the first trench structure 321 given as a central portion. The second internal connecting portion 372 preferably extends in a semicircular arc shape, with the second end portion 324 of the first trench structure 321 given as a central portion.

That is, the second internal connecting portion 372 preferably extends between the second end portions 324 of the two adjacent second trench structures 322 in a circular arc shape which has a circular-arc angle of 180°. The second internal connecting portion 372 preferably extends in a circular arc shape at the fourth interval I14 which is substantially constant from the second end portion 324 of the first trench structure 321. That is, the second internal connecting portion 372 preferably extends in a circular arc shape which has the fourth interval I14 as a curvature radius with respect to the second end portion 324 of the first trench structure 321.

The second internal connecting portion 372 has a facing portion which faces the second end portion 324 of the first trench structure 321 with regard to the second direction Y. The facing portion of the second internal connecting portion 372 linearly extends along the first direction X. That is, the facing portion of the second internal connecting portion 372 extends substantially in parallel with the second end portion 324 of the first trench structure 321.

As described above, the other of the second trench separation structure 342 is formed in a band shape which extends in the first direction X, while meandering along the second outer connecting portion 371 and the second internal connecting portion 372 in plan view. That is, the other of the second trench separation structure 342 has a plurality of second externally curved portions 373 and a plurality of second internally curved portions 374 which are alternately formed in the first direction X in plan view. The plurality of second externally curved portions 373 face the plurality of first trench structures 321 in a one-to-one correspondence relationship in the second direction Y in plan view and are curved in a circular arc shape in a direction away from the plurality of first trench structures 321. The plurality of second internally curved portions 374 face the plurality of second trench structures 322 in a one-to-one correspondence relationship in the second direction Y in plan view and are depressed toward the plurality of second trench structures 322.

The third interval I13 between each of the second trench separation structures 342 preferably falls within a range of not less than 0.9 times and not more than 1.1 times larger than the first interval I11 between the plurality of trench structures 320. It is particularly preferable that the third interval I13 is substantially equal to the first interval I11 (I11≈I13). The third interval I13 preferably falls within a range of not less than 0.9 times and not more than 1.1 times larger than the second interval I12 between the first trench separation structures 341. It is particularly preferable that the third interval I13 is substantially equal to the second interval I12 (I12≈I13). The third interval I13 may be not less than 0.5 μm and not more than 5 μm. The third interval I13 is preferably not less than 0.7 μm and not more than 4 μm.

The fourth interval I14 between each of the second trench separation structures 342 preferably falls within a range of not less than 0.9 times and not more than 1.1 times larger than the first interval I11 between the plurality of trench structures 320. It is particularly preferable that the fourth interval I14 is substantially equal to the first interval I11 (I11≈I14). The fourth interval I14 preferably falls within a range of not less than 0.9 times and not more than 1.1 times larger than the second interval I12 between the first trench separation structures 341.

It is particularly preferable that the fourth interval I14 is substantially equal to the second interval 112 (I12≈I14). The fourth interval I14 preferably falls within a range of not less than 0.9 times and not more than 1.1 times larger than the third interval I13 between the second outer connecting portions 371. It is particularly preferable that the fourth interval I14 is substantially equal to the third interval I13 (I13≈I14). The fourth interval I14 may be not less than 1 μm and not more than 5 μm. The third interval I13 is preferably not less than 2 μm and not more than 4 μm.

Each of the second trench separation structures 342 includes a second separation trench 378, a second separation insulating film 379 and a second separation electrode 380. The second separation trench 378 is dug down from the first main surface 303 toward the second main surface 304. The second separation trench 378 forms the first side wall 355, the second side wall 356 and the bottom wall 357 of the second trench separation structure 342. The first side wall 355, the second side wall 356 and the bottom wall 357 form the wall surface (an inner wall and an outer wall) of the second separation trench 378.

The second separation trench 378 exposes the drift layer 307 from the first side wall 355, the second side wall 356 and the bottom wall 357. The second separation trench 378 is communicatively connected to the trenches 328 of the plurality of trench structures 320 and the first separation trenches 348 of the plurality of first trench separation structures 341 on the first side wall 355 side.

The second separation insulating film 379 is formed as a film along the wall surface of the second separation trench 378 and demarcates a recess space inside the second separation trench 378. The second separation insulating film 379 continues to the insulating film 329 at a communicatively connecting portion with each of the trenches 328 and continues to the first separation insulating film 349 at a communicatively connecting portion with each of the first separation trenches 348. In this embodiment, the second separation insulating film 379 includes a silicon oxide film.

A thickness of the second separation insulating film 379 may be not less than 0.05 μm and not more than 0.5 μm. The thickness of the second separation insulating film 379 is preferably not less than 0.1 μm and not more than 0.4 μm. The thickness of the second separation insulating film 379 is preferably in excess of the thickness of the insulating film 329. As a matter of course, in consideration of the convenience of the manufacturing method, the second separation insulating film 379 having the thickness which is substantially equal to the thickness of the insulating film 329 may be formed.

The second separation electrode 380 is embedded in the second separation trench 378 across the second separation insulating film 379. The second separation electrode 380 continues to the electrode 330 at the communicatively connecting portion with each of the trenches 328 and continues to the first separation electrode 350 at the communicatively connecting portion with each of the first separation trenches 348. In this embodiment, the second separation electrode 380 contains conductive polysilicon. The conductive polysilicon may be n-type polysilicon or p-type polysilicon. The second separation electrode 380 includes the same electrode material as the electrode 330 of each trench structure 320.

An upper end portion of the second separation electrode 380 includes a first portion 380a on the outer region 310 side and a second portion 380b on the active region 311 side. The second portion 380b is depressed to the bottom wall 357 side of the second separation trench 378 with respect to the first portion 380a. The second portion 380b is preferably positioned on the bottom wall 357 side of the second separation trench 378 with respect to the outer main surface 312. The second portion 380b is preferably depressed to the first portion 380a in a range in excess of 0 μm and not more than 0.5 μm (preferably, not more than 0.1 μm).

The first portion 380a continues to the first portion 350a of the first separation electrode 350 at the communicatively connecting portion with each of the first separation trenches 348. The second portion 380b continues to the electrode 330 at the communicatively connecting portion with each of the trenches 328 and continues to the second portion 350b of the first separation electrode 350 at the communicatively connecting portion with each of the first separation trenches 348.

The semiconductor device 301 includes a third protrusion portion 381 which is constituted of an upper end portion of the second separation insulating film 379 and protrudes as a wall from the first main surface 303 at a portion which covers the first side wall 355 in the second separation insulating film 379. In other words, the second separation insulating film 379 has the third protrusion portion 381 which protrudes as a wall from the first main surface 303. That is, the third protrusion portion 381 is also one constituent of each of the second trench separation structures 342. Specifically, the third protrusion portion 381 protrudes upper than the second separation electrode 380 (specifically, second portion 380b) from the active main surface 313 to separate the active main surface 313 and the second separation electrode 380.

The third protrusion portion 381 is formed in a depth range between the outer main surface 312 and the active main surface 313. The third protrusion portion 381 may be formed at an interval on the active main surface 313 side with respect to the outer main surface 312. A leading end portion of the third protrusion portion 381 may be inclined downward in an oblique direction toward an interior of the second trench separation structure 342. The third protrusion portion 381 demarcates a third recess 382 with the second portion 380b of the second separation electrode 380 at an inner portion of the second separation trench 378.

The third protrusion portion 381 extends in a band shape along the first side wall 355 of the second separation trench 378 in plan view. The third protrusion portion 381 is connected to the first protrusion portion 331 at the communicatively connecting portion with the second trench structure 322 and connected to the second protrusion portion 351 at the communicatively connecting portion with the first trench separation structure 341. The third protrusion portion 381 preferably protrudes to the active main surface 313 in a range in excess of 0 μm and not more than 0.5 μm (preferably, not more than 0.1 μm).

The semiconductor device 301 includes a plurality of mesa portions 390 which are demarcated into the semiconductor chip 302. The plurality of mesa portions 390 are demarcated in the active region 311 by the plurality of trench structures 320 and the plurality of first and second trench separation structures 341, 342. The plurality of mesa portions 390 are each demarcated in the active main surface 313 by the first protrusion portion 331 of each of the plurality of trench structures 320, the second protrusion portion 351 of each of the plurality of first trench separation structures 341 and the third protrusion portion 381 of each of the plurality of second trench separation structures 342. The plurality of mesa portions 390 include two outer mesa portions 391 and a plurality of inner mesa portions 392. Hereinafter, a description will be given of one outer mesa portion 391 and one inner mesa portion 392.

The outer mesa portion 391 is demarcated by the first and the second trench structures 321, 322 as well as the first and the second trench separation structures 341, 342. The outer mesa portion 391 has two first mesa main bodies 393 and two first mesa end portions 394. The two first mesa main bodies 393 are each demarcated in a band shape which extends between the first trench structure 321 and the second trench structure 322 as well as between the first trench structure 321 and the first trench separation structure 341 in the second direction Y.

The two first mesa end portions 394 are each demarcated between the first end portion 323 of the first trench structure 321 and the first outer connecting portion 361 as well as between the second end portion 324 of the first trench structure 321 and the second outer connecting portion 371. In this embodiment, the two first mesa end portions 394 are each demarcated in a semicircular shape in plan view. The outer mesa portion 391 is demarcated by the first mesa main body 393 and the first mesa end portion 394 in an annular shape (specifically, in an elliptically annular shape) which surrounds the first trench structure 321 in plan view.

The inner mesa portion 392 is demarcated by the first trench structure 321, the second trench structure 322 and the second trench separation structure 342. The inner mesa portion 392 has two second mesa main bodies 395 and two second mesa end portions 396. The two second mesa main bodies 395 are each demarcated in a band shape which extends between the first trench structure 321 and one of the second trench structures 322 as well as between the first trench structure 321 and the other of the second trench structures 322 in the second direction Y.

The two second mesa end portions 396 are each demarcated between the first end portion 323 of the first trench structure 321 and the first internal connecting portion 362 as well as between the second end portion 324 of the first trench structure 321 and the second internal connecting portion 372. In this embodiment, the two first mesa end portions 394 are each demarcated in a semicircular shape in plan view. The inner mesa portion 392 is demarcated by the second mesa main body 395 and the second mesa end portion 396 in an annular shape (specifically, in an elliptically annular shape) which surrounds the first trench structure 321 in plan view. That is, in this embodiment, the plurality of mesa portions 390 are arrayed at an interval in the first direction X in plan view and each formed in an elliptically annular shape which extends in the second direction Y. The plurality of mesa portions 390 are demarcated by the plurality of trench structures 320 and the plurality of first and second trench separation structures 341, 342.

The semiconductor device 301 has no trench which extends along the trench separation structure 340 (first and second trench separation structures 341, 342) in the outer region 310. That is, in the outer region 310, no trench which extends along one of or both of the first and the second trench separation structures 341, 342 is formed.

The semiconductor device 301 includes a p-type semiconductor region 400 which is formed at the surface layer portion of the first main surface 303 along the trench separation structure 340 in the outer region 310. That is, the semiconductor region 400 is formed in the outer main surface 312. In this embodiment, the semiconductor region 400 includes a portion which is positioned on the outer main surface 312 side with respect to the active main surface 313 and a portion which is positioned on the bottom portion side of the drift layer 307 with respect to the active main surface 313 with regard to the normal direction Z.

The semiconductor region 400 is preferably formed along one of or both of the first and the second trench separation structures 341, 342. In this embodiment, the semiconductor region 400 is formed along both of the first and the second trench separation structures 341, 342. That is, the semiconductor region 400 surrounds the trench separation structure 340 in plan view.

The semiconductor region 400 is constituted of a p-type floating region which is formed in an electrically floating state. That is, the semiconductor region 400 is electrically separated from the active region 311, the plurality of trench structures 320 and the first and the second trench separation structures 341, 342. The semiconductor region 400 has a p-type impurity concentration which is not less than 1×10¹⁷ cm⁻³ and not more than 1×10¹⁹ cm⁻³. The semiconductor region 400 has a concentration gradient in which the p-type impurity concentration is decreased gradually from the first main surface 303 (outer main surface 312) in a width direction and a thickness direction of the drift layer 307.

The semiconductor region 400 is adjacent to the first and the second trench separation structures 341, 342 in the outer region 310. The semiconductor region 400 is formed in a band shape along the first and the second trench separation structures 341, 342 in plan view. Specifically, the semiconductor region 400 is formed in an annular shape which surrounds the first and the second trench separation structures 341, 342 in plan view.

The semiconductor region 400 has an inner peripheral edge 401 on the active region 311 side and an outer peripheral edge 402 on the outer region 310 side. The inner peripheral edge 401 of the semiconductor region 400 is connected to the first and the second trench separation structures 341, 342. In this embodiment, the outer peripheral edge 402 of the semiconductor region 400 extends substantially in parallel with the first and the second trench separation structures 341, 342 in plan view.

Specifically, the semiconductor region 400 includes a first region 403, a second region 404 and a third region 405. The first region 403 extends in a band shape along the first trench separation structure 341 in the second direction Y. The second region 404 extends in a band shape along the second trench separation structure 342 in the first direction X. The third region 405 extends in a circular arc shape along the second trench separation structure 342 from the communicatively connecting portion of the first and the second trench separation structures 341, 342 to connect the first region 403 and the second region 404.

Specifically, the second region 404 is formed in a band shape which extends in the first direction X, while meandering along the second trench separation structure 342 in plan view. The second region 404 has a plurality of externally curved regions 406 and a plurality of internally curved regions 407 which are formed alternately in the first direction X in plan view.

The plurality of externally curved regions 406 extend along the plurality of the first and the second connecting portions 360, 370 such as to face the plurality of first trench structures 321 in a one-to-one correspondence relationship in the second direction Y in plan view and are curved in a circular arc shape in a direction away from the plurality of first trench structures 321. The plurality of internally curved regions 407 extend along the plurality of first and second connecting portions 360, 370 such as to face the plurality of second trench structures 322 in a one-to-one correspondence relationship in the second direction Y in plan view and are depressed toward the plurality of second trench structures 322.

The semiconductor region 400 is formed at the surface layer portion of the first main surface 303 at an interval from the bottom portion of the drift layer 307 to the first main surface 303 side. The semiconductor region 400 is formed in a depth range between the first main surface 303 and the bottom walls 347, 357 of the first and the second trench separation structures 341, 342. The semiconductor region 400 is formed deeper than the first and the second trench separation structures 341, 342. The semiconductor region 400 is also formed deeper than each of the trench structures 320.

The semiconductor region 400 (specifically, inner peripheral edge 401) has a covering portion 408 which covers the bottom walls 347, 357 of the first and the second trench separation structures 341, 342. Specifically, the covering portion 408 covers the bottom walls 347, 357 of the first and the second trench separation structures 341, 342 at an interval from the active region 311 to the outer region 310 side in plan view. That is, the covering portion 408 covers a portion on the outer region 310 side such as to expose a portion on the active region 311 side in the bottom walls 347, 357 of the first and the second trench separation structures 341, 342.

The semiconductor region 400 has a region width WF. The region width WF is a width (maximum width) in a direction orthogonal to a direction in which the semiconductor region 400 extends, with the second side walls 346, 356 of the first and the second trench separation structures 341, 342 given as a reference. The region width WF is preferably equal to or larger than the first width W11 of the trench structure 320 (W11≤WF). The region width WF is preferably equal to or larger than the second width W12 of the first trench separation structure 341 (W12≤WF). The region width WF is preferably equal to or larger than the third width W13 of the second trench separation structure 342 (W13≤WF). In this embodiment, the region width WF is in excess of the second width W12 and the third width W13 (W12<WF, W13<WF).

That is, in view of the first direction X, from the active region 311 side to the outer region 310 side, the width is increased in an ascending order of the first width W11 of the trench structure 320, the second and the third width W12, W13 of the first and the second trench separation structures 341, 342 and the region width WF of the semiconductor region 400 (W11<W12(W13)<WF). The region width WF may be not less than 2 μm and not more than 20 μm. The region width WF is preferably not less than 5 μm and not more than 15 μm.

The semiconductor region 400 has a region thickness TF. The region thickness TF is a distance (maximum value) between the first main surface 303 (outer main surface 312) and the bottom portion of the semiconductor region 400. The region thickness TF may be not less than 1 μm and not more than 5 μm. The region thickness TF is preferably not less than 1.5 μm and not more than 3.5 μm. The semiconductor region 400 may be formed at an interval of not less than 1 μm and not more than 6 μm from the bottom portion (that is, buffer layer 308) of the drift layer 307. The semiconductor region 400 is preferably formed at an interval of not less than 1.5 μm and not more than 5 μm from the bottom portion (that is, buffer layer 308) of the drift layer 307.

An aspect ratio WF/TF of the semiconductor region 400 is preferably in excess of 1. The aspect ratio, WF/TF, is a ratio of the region width WF with respect to the region thickness TF. That is, the semiconductor region 400 preferably has a horizontally long structure along the first main surface 303 (outer main surface 312) in a cross-sectional view. The aspect ratio, WF/TF, is preferably in excess of 1 and not more than 5.

The semiconductor device 301 includes a main surface insulating film 410 which selectively covers the first main surface 303. In this embodiment, the main surface insulating film 410 includes a silicon oxide film. The main surface insulating film 410 covers the first main surface 303 (outer main surface 312) in the outer region 310 and has an inner wall portion 412 which demarcates a contact opening 411 that exposes the first main surface 303 (active main surface 313) in the active region 311. The main surface insulating film 410 covers an entire area of the semiconductor region 400 in the outer region 310 and electrically insulates the semiconductor region 400 from outside. In this embodiment, the main surface insulating film 410 covers an entire area of the outer main surface 312 and continues to the first to fourth side surfaces 305A to 305D.

The main surface insulating film 410 covers a part of the first and the second trench separation structures 341, 342 on the active region 311 side and partially exposes the first and the second trench separation structures 341, 342. Specifically, the main surface insulating film 410 covers the first portions 350a, 380a of the first and the second separation electrodes 350, 380 and exposes the second portions 350b, 380b of the first and the second separation electrodes 350, 380. That is, the main surface insulating film 410 covers the upper end portions of the first and the second separation electrodes 350, 380 on the outer region 310 side such as to expose the upper end portions of the first and the second separation electrodes 350, 380 on the active region 311 side.

The inner wall portion 412 (contact opening 411) of the main surface insulating film 410 is communicatively connected to the second and the third recesses 352, 382 of the first and the second trench separation structures 341, 342. A portion of the inner wall portion 412 (contact opening 411) along the second trench separation structure 342 extends in the first direction X, while meandering along the second trench separation structure 342 in plan view. That is, the portion of the inner wall portion 412 along the second trench separation structure 342 has a plurality of externally curved wall portions 413 and a plurality of internally curved wall portions 414 which are alternately formed in the first direction X in plan view.

The plurality of externally curved wall portions 413 extend along the plurality of first and second connecting portions 360, 370 such as to face the plurality of first trench structures 321 in a one-to-one correspondence relationship in the second direction Y in plan view and are curved in a circular arc shape in a direction away from the plurality of first trench structures 321. The plurality of internally curved wall portions 414 extend along the plurality of first and second connecting portions 360, 370 such as to face the plurality of second trench structures 322 in a one-to-one correspondence relationship in the second direction Y in plan view and are depressed toward the plurality of second trench structures 322.

In this embodiment, the main surface insulating film 410 has a laminated structure which includes a first main surface insulating film 415 and a second main surface insulating film 416 laminated in this order from the first main surface 303 side. In this embodiment, the first main surface insulating film 415 includes a silicon oxide film. Specifically, the first main surface insulating film 415 is constituted of a field oxide film which contains an oxide of the semiconductor chip 302 (drift layer 307). On the other hand, the second main surface insulating film 416 includes a silicon oxide film which is different in property from the first main surface insulating film 415.

The second main surface insulating film 416 may include at least one among a BPSG (Boron and Phosphorus Silicate Glass) film, a PSG (Phosphorus Silicate Glass) film and a USG (Undoped Silicate Glass) film. The BPSG film is a silicon oxide film which contains boron and phosphorus, the PSG film is a silicon oxide film which contains phosphorus, and the USG film is a silicon oxide film that is not doped with an impurity.

The second main surface insulating film 416 may have a laminated structure in which at least two among a BPSG film, a PSG film and a USG film are laminated in an arbitrary order. The second main surface insulating film 416 may have a laminated structure which includes a PSG film and a BPSG film which are laminated in this order from the first main surface 303 side. The second main surface insulating film 416 may have a single layer structure which is constituted of a BPSG film, a PSG film or a USG film. In this embodiment, the second main surface insulating film 416 has a single layer structure which is constituted of a BPSG film.

The first main surface insulating film 415 covers an entire area of the semiconductor region 400 in the outer region 310 and electrically insulates the semiconductor region 400 from outside. The first main surface insulating film 415 continues to the first and the second separation insulating films 349, 379 of the first and the second trench separation structures 341, 342 and exposes the first and the second separation electrodes 350, 380. In this embodiment, the first main surface insulating film 415 covers an entire area of the outer region 310 (outer main surface 312) and continues to the first to fourth side surfaces 305A to 305D.

The second main surface insulating film 416 covers an entire area of the first main surface insulating film 415 and continues to the first to fourth side surfaces 305A to 305D. The second main surface insulating film 416 faces the drift layer 307 and the semiconductor region 400 across the first main surface insulating film 415. The second main surface insulating film 416 covers a part of the first and the second trench separation structures 341, 342 and partially exposes the first and the second trench separation structures 341, 342. Specifically, the second main surface insulating film 416 covers the first portions 350a, 380a of the first and the second separation electrodes 350, 380 and exposes the second portions 350b, 380b of the first and the second separation electrodes 350, 380. The second main surface insulating film 416 demarcates the inner wall portion 412 (contact opening 411) of the main surface insulating film 410.

The first main surface insulating film 415 has a first insulation thickness TI1. The first insulation thickness TI1 may be not less than 1000 Å and not more than 5000 Å. The first insulation thickness TI1 is preferably not less than 1500 Å and not more than 3500 Å. The second main surface insulating film 416 has a second insulation thickness TI2. The second insulation thickness TI2 may be not less than 1000 Å and not more than 6000 Å. The second insulation thickness TI2 is preferably not less than 2500 Å and not more than 4500 Å. The second insulation thickness TI2 is preferably in excess of the first insulation thickness TI1 (TI1<=2).

The semiconductor device 301 includes a Schottky electrode 420 which is formed on the first main surface 303. The Schottky electrode 420 is an anode electrode of the SBD. The Schottky electrode 420 is electrically connected to the first main surface 303 (active main surface 313) and the electrodes 330 of the plurality of trench structures 320 in the active region 311. That is, the Schottky electrode 420 forms a Schottky junction with the active main surface 313 which is depressed to the bottom portion side of the drift layer 307 with respect to the outer main surface 312.

Specifically, the Schottky electrode 420 covers the first to third protrusion portions 331, 351, 381 and the plurality of mesa portions 390 in the active region 311 and forms the Schottky junction with the active main surface 313 (the plurality of mesa portions 390). Specifically, the Schottky electrode 420 forms the Schottky junction with the first mesa main body 393 and the first mesa end portion 394 of the outer mesa portion 391. The Schottky electrode 420 also forms the Schottky junction with the second mesa main body 395 and the second mesa end portion 396 of the inner mesa portion 392. Further, the Schottky electrode 420 enters into the first recess 332 of the trench structure 320 from above the first protrusion portion 331 and is electrically connected to the electrode 330.

The Schottky electrode 420 is electrically connected to the first and the second separation electrodes 350, 380 of the first and the second trench separation structures 341, 342 such as to retain the semiconductor region 400 in the electrically floating state in the outer region 310. Specifically, the Schottky electrode 420 enters into the second and the third recesses 352, 382 of the first and the second trench separation structures 341, 342 from above the second and the third protrusion portions 351, 381 and is electrically connected to the first and the second separation electrodes 350, 380 inside the second and the third recesses 352, 382.

The Schottky electrode 420 refills the contact opening 411 and protrudes upper than a main surface of the main surface insulating film 410. The Schottky electrode 420 is formed at an interval from a peripheral edge of the first main surface 303 to the active region 311 side in plan view. The Schottky electrode 420 has four electrode side walls 421 which are positioned on the main surface insulating film 410 to extend along the peripheral edge (first to the fourth side surfaces 305A to 305D) of the first main surface 303.

The electrode side wall 421 extends in the first direction X, while meandering along the second trench separation structure 342 in plan view. That is, a portion of the electrode side wall 421 along the second trench separation structure 342 has a plurality of externally curved side walls 422 and a plurality of internally curved side walls 423 which are formed alternately in the first direction X in plan view.

The plurality of externally curved side walls 422 extend along the plurality of first and second connecting portions 360, 370 such as to face the plurality of first trench structures 321 in a one-to-one correspondence relationship in the second direction Y in plan view and are curved in a circular arc shape in a direction away from the plurality of first trench structures 321. The plurality of internally curved side walls 423 extend along the plurality of first and second connecting portions 360, 370 such as to face the plurality of second trench structures 322 in a one-to-one correspondence relationship in the second direction Y in plan view and are depressed toward the plurality of second trench structures 322.

The Schottky electrode 420 includes a lead-out portion 424 which is led out on the main surface insulating film 410. The lead-out portion 424 faces a part of the first and the second separation electrodes 350, 380 (first portions 350a, 380a) and the semiconductor region 400 across the main surface insulating film 410. Specifically, the lead-out portion 424 faces an entire area of the semiconductor region 400 across the main surface insulating film 410. A peripheral edge of the lead-out portion 424 is formed at an interval from the peripheral edge of the first main surface 303 to the active region 311 side.

The lead-out portion 424 has a lead-out width WL. The lead-out width WL is a width of the lead-out portion 424 when the inner wall portion 412 of the contact opening 411 is given as a reference. The lead-out width WL may be not less than 2 μm and not more than 25 μm. The lead-out width WL is preferably not less than 5 μm and not more than 20 μm. The lead-out width WL is preferably in excess of the region width WF of the semiconductor region 400 (WL<WF).

The Schottky electrode 420 has a laminated structure which includes a first electrode film 425, a second electrode film 426 and a third electrode film 427 which are laminated in this order from the semiconductor chip 302 side. The first electrode film 425 is formed as a film along the active main surface 313, the first to third protrusion portions 331, 351, 381, the inner wall portion 412 of the contact opening 411 and the main surface of the main surface insulating film 410. The first electrode film 425 includes a portion which is positioned inside a region that is demarcated by the first to third recesses 332, 352, 382. The first electrode film 425 is electrically connected to the electrodes 330, the first and the second separation electrodes 350, 380 and the mesa portions 390 (active main surface 313) inside the region that is demarcated by the first to third recesses 332, 352, 382.

The first electrode film 425 is constituted of a Schottky barrier electrode film and forms the Schottky junction with the first main surface 303. An electrode material of the first electrode film 425 is arbitrary as long as it forms the Schottky junction with the first main surface 303. The first electrode film 425 may contain at least one among magnesium (Mg), aluminum (Al), titanium (Ti), vanadium (V), chromium (Cr), manganese (Mn), cobalt (Co), nickel (Ni), copper (Cu), zirconium (Zr), niobium (Nb), molybdenum (Mo), palladium (Pd), silver (Ag), indium (In), tin (Sn), tantalum (Ta), tungsten (W), platinum (Pt) and

The first electrode film 425 may be constituted of an alloy film which contains at least one type among the above-described types of metals. In this embodiment, the first electrode film 425 has a single layer structure which is constituted of a molybdenum film. The first electrode film 425 has a first electrode thickness TE1. The first electrode thickness TE1 may be not less than 50 Å and not more than 1000 Å. The first electrode thickness TE1 is preferably not less than 250 Å and not more than 500 Å. The first electrode thickness TE1 is preferably less than the thickness of the insulating film 329. The first electrode thickness TE1 is preferably less than the thickness of each of the first and the second separation insulating films 349, 379. The first electrode thickness TE1 is preferably less than a protrusion extent of the first to third protrusion portions 331, 351, 381.

The second electrode film 426 is formed as a film along the first electrode film 425. The second electrode film 426 includes a portion which is positioned inside a region that is demarcated by the first to third recesses 332, 352, 382. The second electrode film 426 refills the first to third recesses 332, 352, 382 and faces the first to third protrusion portions 331, 351, 381 across the first electrode film 425. The second electrode film 426 is electrically connected to the electrodes 330, the first and the second separation electrodes 350, 380 and the mesa portions 390 (active main surface 313) across the first electrode film 425 inside the region demarcated by the first to third recesses 332, 352, 382.

The second electrode film 426 is constituted of a metal barrier film. In this embodiment, the second electrode film 426 is constituted of a Ti-based metal film. The second electrode film 426 includes at least one of a titanium (Ti) film and a titanium nitride (TiN) film. The second electrode film 426 may have a single layer structure which is constituted of a titanium film or a titanium nitride film or a laminated structure which includes a titanium film and a titanium nitride film in an arbitrary order.

In this embodiment, the second electrode film 426 has a single layer structure which is constituted of a titanium nitride film. The second electrode film 426 has a second electrode thickness TE2. The second electrode thickness TE2 may be not less than 500 Å and not more than 5000 Å. The second electrode thickness TE2 is preferably not less than 1500 Å and not more than 4500 Å. The second electrode thickness TE2 is preferably in excess of the first electrode thickness TE1 (TE1<TE2). The second electrode thickness TE2 is preferably in excess of the protrusion extent of the first to third protrusion portions 331, 351, 381.

The third electrode film 427 is formed as a film along the main surface of the second electrode film 426. The third electrode film 427 faces the electrodes 330, the first and the second separation electrodes 350, 380 and the mesa portions 390 (active main surface 313) across the first electrode film 425 and the second electrode film 426. The third electrode film 427 is electrically connected to the electrodes 330, the first and the second separation electrodes 350, 380 and the mesa portions 390 (active main surface 313) across the first electrode film 425 and the second electrode film 426. The third electrode film 427 is in its entirety positioned upper than the first to third protrusion portions 331, 351, 381. That is, the third electrode film 427 is in its entirety positioned outside the first to third recesses 332, 352, 382.

The third electrode film 427 may be a terminal electrode (pad electrode) which is to be externally connected by a conductive wire (for example, bonding wire). The third electrode film 427 is constituted of a Cu-based metal film or an Al-based metal film. The third electrode film 427 may include at least one among a pure Cu film (Cu film with purity of not less than 99%), a pure Al film (Al film with purity of not less than 99%), an AlCu alloy film, an AlSi alloy film and an AlSiCu alloy film. In this embodiment, the third electrode film 427 has a single layer structure which is constituted of an AlCu alloy film.

The third electrode film 427 has a third electrode thickness TE3. The third electrode thickness TE3 may be not less than 0.5 μm (=5000 Å) and not more than 10 μm (=100000 Å). The third electrode thickness TE3 is preferably not less than 2.5 μm and not more than 7.5 μm. The third electrode thickness TE3 is preferably in excess of the first electrode thickness TE1 and the second electrode thickness TE2 (TE1<TE3,TE2<TE3). It is particularly preferable that the third electrode thickness TE3 is in excess of a sum (TE1+TE2) of the first electrode thickness TE1 and the second electrode thickness TE2 (TE1+TE2<TE3).

With reference to FIG. 27, the Schottky electrode 420 includes a first covering portion 420a and a second covering portion 420b on the active main surface 313. The first covering portion 420a covers the active main surface 313, the electrodes 330 and the first and the second separation electrodes 350, 380 in the Schottky electrode 420. The first covering portion 420a includes a silicide region in which a part of the first electrode film 425 is silicided with the first main surface 303 (active main surface 313), the electrodes 330 and the first and the second separation electrodes 350, 380. In this embodiment, the silicide region contains molybdenum silicide (MoSi). The silicide region is formed at an interval from the upper end portions of the first to third protrusion portions 331, 351, 381 to the first main surface 303 (active main surface 313) side.

The second covering portion 420b covers the insulating films 329 and the first and the second separation insulating films 349, 379 in the Schottky electrode 420. The second covering portion 420b is constituted of a non-silicide region and separated above from the first covering portion 420a by the first to third protrusion portions 331, 351, 381. The non-silicide region is a region lower in Si content compared with the first covering portion 420a. The region lower in Si content may include a region which does not contain Si.

Where the first to third protrusion portions 331, 351, 381 are not present, the first covering portion 420a and the second covering portion 420b are formed adjacent to each other in a plane direction parallel to the active main surface 313. In this case, a tunneling leakage current due to the second covering portion 420b occurs between the second covering portion 420b and the active main surface 313 (Schottky junction portion), thus resulting in a possible change in electrical characteristics.

In the semiconductor device 301, since the second covering portion 420b is separated above from the first covering portion 420a (Schottky junction portion) by the first to third protrusion portions 331, 351, 381, the tunneling leakage current to the active main surface 313 (Schottky junction portion) due to the second covering portion 420b is suppressed. Thus, the change in electrical characteristics resulting from the tunneling leakage current is suppressed to improve reliability.

The semiconductor device 301 includes an upper insulating film 430 which is formed on the main surface insulating film 410 such as to cover the Schottky electrode 420. In this embodiment, the upper insulating film 430 has a single layer structure which is constituted of an inorganic insulating film. The upper insulating film 430 is preferably constituted of an insulator different from the main surface insulating film 410. The upper insulating film 430 preferably includes at least one of a silicon nitride (SiN) film and a silicon oxynitride (SiON) film. In this embodiment, the upper insulating film 430 has a single layer structure which is constituted of a silicon oxynitride film.

The upper insulating film 430 is formed as a film along the main surface of the main surface insulating film 410, the electrode side wall 421 of the Schottky electrode 420 and the main surface of the Schottky electrode 420. Thereby, the upper insulating film 430 has a first covering portion 431 which covers the Schottky electrode 420 and a second covering portion 432 which covers the main surface insulating film 410. The first covering portion 431 covers an entire area of the lead-out portion 424 of the Schottky electrode 420.

The first covering portion 431 has a pad opening 433 which exposes a central portion of the Schottky electrode 420. The first covering portion 431 faces the first and the second trench separation structures 341, 342 and the semiconductor region 400 across the Schottky electrode 420 with regard to the normal direction Z. The first covering portion 431 preferably faces at least one trench structure 320 across the Schottky electrode 420. In this embodiment, the upper insulating film 430 faces an entire area of the first and the second trench separation structures 341, 342 and an entire area of the semiconductor region 400 in plan view.

The second covering portion 432 covers the main surface insulating film 410 at an interval from a peripheral edge of the first main surface 303 to the active region 311 side in plan view. In this embodiment, the second covering portion 432 covers the main surface insulating film 410 at an interval from the semiconductor region 400 to the peripheral edge of the first main surface 303 in plan view. In this embodiment, the second covering portion 432 is formed in a quadrilateral shape which has four sides parallel to the peripheral edge of the first main surface 303.

The second covering portion 432 demarcates a dicing street 434 which exposes a peripheral edge portion of the main surface insulating film 410 with the peripheral edge of the first main surface 303. The drift layer 307 is positioned directly under the dicing street 434, and the semiconductor region 400 is not arranged. A width of the dicing street 434 may be not less than 10 μm and not more than 50 μm. The width of the dicing street 434 is a width of a direction orthogonal to a direction in which the dicing street 434 extends.

The upper insulating film 430 has a third insulation thickness TI3. The third insulation thickness TI3 is preferably in excess of the first insulation thickness TI1 of the first main surface insulating film 415 (TI1<TI3). The third insulation thickness TI3 is preferably in excess of the second insulation thickness TI2 of the second main surface insulating film 416 (TI2<TI3). The third insulation thickness TI3 is preferably in excess of a sum of the first insulation thickness TI1 and the second insulation thickness TI2 (TI1+TI2<TI3).

Further, the third insulation thickness TI3 is preferably in excess of the first electrode thickness TE1 of the first electrode film 425 (TE1<TI3). The third insulation thickness TI3 is preferably in excess of the second electrode thickness TE2 of the second electrode film 426 (TE2<TI3). The third insulation thickness TI3 is preferably in excess of a sum of the first electrode thickness TE1 and the second electrode thickness TE2 (TE1+TE2<TI3). The third insulation thickness TI3 is preferably less than the third electrode thickness TE3 of the third electrode film 427 (TE3>TI3). The third insulation thickness TI3 may be not less than 0.2 μm (=2000 Å) and not more than 4 μm (=40000 Å). The third insulation thickness TI3 is preferably not less than 0.5 μm and not more than 2 μm.

The semiconductor device 301 includes a cathode electrode 440 which covers the second main surface 304. The cathode electrode 440 covers an entire area of the second main surface 304 and continues to the first to fourth side surfaces 305A to 305D. The cathode electrode 440 is electrically connected to a cathode layer 306. Specifically, the cathode electrode 440 forms an ohmic contact with the cathode layer 306 (second main surface 304). The cathode electrode 440 has a laminated structure which includes a titanium film 441, a nickel film 442 and a gold film 443 which are laminated in this order from the second main surface 304 side.

The titanium film 441 may have a thickness which is not less than 500 Å and not more than 2000 Å. The nickel film 442 preferably has a thickness in excess of the thickness of the titanium film 441. The nickel film 442 may have the thickness of not less than 2000 Å and not more than 6000 Å. The gold film 443 preferably has a thickness which is less than the thickness of the nickel film 442. It is particularly preferable that the gold film 443 has the thickness which is less than the thickness of the titanium film 441. The gold film 443 may have the thickness of not less than 100 Å and not more than 1000 Å. The cathode electrode 440 may further include a palladium film which is interposed between the nickel film 442 and the gold film 443.

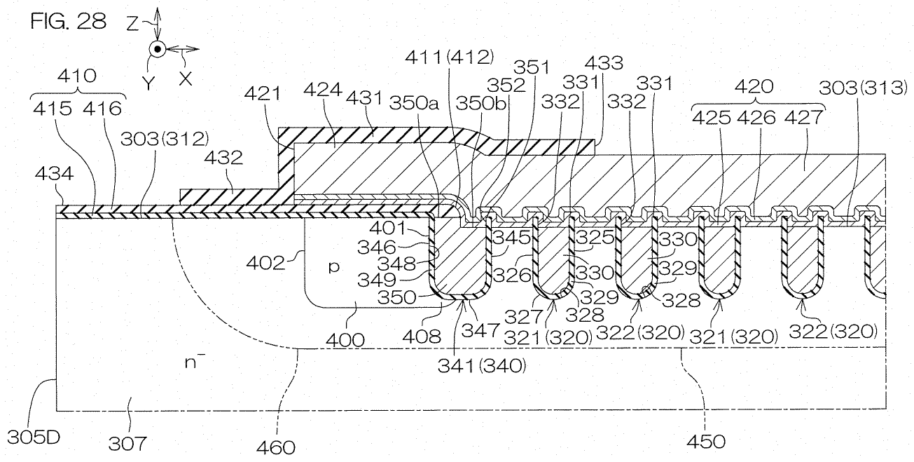

FIG. 28 corresponds to FIG. 26 and is a drawing which describes a depletion layer inside the drift layer 307. With reference to FIG. 28, in the semiconductor device 301, where a reverse voltage VR is applied between the Schottky electrode 420 and the cathode electrode 440, a first depletion layer 450 (refer to the double chain line in FIG. 28) expands from the active region 311. Specifically, the first depletion layer 450 which expands from the active region 311 expands in a depth direction and a width direction of the drift layer 307, with the plurality of trench structures 320 given as a starting point.

Further, in the drift layer 307, a second depletion layer 460 (refer to the double chain line in FIG. 28) expands also from the semiconductor region 400. The second depletion layer 460 which expands from the semiconductor region 400 is made integral with the first depletion layer 450 in a mode that the first depletion layer 450 which expands from the active region 311 is enlarged toward the outer region 310. A terminal portion of the second depletion layer 460 is positioned in the outer region 310 (outer main surface 312) at an interval from the peripheral edge of the first main surface 303 to the semiconductor region 400 side.

In the semiconductor device 301, since the first depletion layer 450 expands, with the plurality of trench structures 320 (particularly, bottom wall 327) given as a starting point, it is possible to relax an electric field intensity at the surface layer portion of the first main surface 303. Further, in the semiconductor device 301, since the first depletion layer 450 at the peripheral edge portion of the active region 311 is enlarged by the second depletion layer 460 which expands from the semiconductor region 400, the electric field intensity at the peripheral edge portion of the active region 311 is relaxed by the semiconductor region 400.

Since the semiconductor region 400 is formed in the electrically floating state, it does not form a pn-junction (that is, pn-junction diode) with the drift layer 307. Therefore, a breakdown voltage VB (withstand voltage) of the SBD is not limited by a breakdown voltage VB of the pn-junction diode. It is thereby possible to suppress a reverse current IR and also improve the breakdown voltage VB. The second trench separation structure 342 suppresses an electric current concentration (electric field concentration) of the reverse current IR at the end portions (first end portion 323 and second end portion 324) of the trench structure 320 and the end portions (first end portion 343 and second end portion 344) of the first trench separation structure 341.

As described above, the semiconductor device 301 includes the n-type drift layer 307 (semiconductor layer), the plurality of trench structures 320, the first trench separation structure 341, the second trench separation structure 342 and the Schottky electrode 420. The drift layer 307 has the first main surface 303. The plurality of trench structures 320 include the first trench structure 321 and the second trench structure 322. The first trench structure 321 and the second trench structure 322 are formed in the first main surface 303 at an interval in the first direction X, and each extends in a band shape in the second direction Y which intersects the first direction X.

The first trench separation structure 341 is formed in the first main surface 303 at an interval in the first direction X from the first trench structure 321 such as to face the second trench structure 322 across the first trench structure 321 and extends in a band shape in the second direction Y. The second trench separation structure 342 has first and second outer connecting portions 361, 371 which connect the end portion of the first trench separation structure 341 and the end portion of the second trench structure 322 at an interval from an end portion of the first trench structure 321 and extends in a band shape in the first direction X. The Schottky electrode 420 is connected to a portion which is exposed from the plurality of trench structures 320 in the first main surface 303.

According to this structure, it is possible to suppress the electric current concentration (electric field concentration) at the end portions (first end portion 323 and second end portion 324) of the trench structure 320 and the end portions (first end portion 343 and second end portion 344) of the first trench separation structure 341 by the second trench separation structure 342. Thereby, the breakdown voltage VB can be improved. It is, thus, possible to provide the semiconductor device 301 capable of improving the electrical characteristics.

The first and the second outer connecting portions 361, 371 preferably extend between the end portion of the first trench separation structure 341 and the end portion of the second trench structure 322 in a circular arc shape. According to this structure, it is possible to appropriately suppress the electric current concentration (electric field concentration) at the end portions (first end portion 323 and second end portion 324) of the trench structure 320 and the end portions (first end portion 343 and second end portion 344) of the first trench separation structure 341 by the second trench separation structure 342.

In this embodiment, the plurality of trench structures 320 include the plurality of first trench structures 321 and the plurality of second trench structures 322 which are arrayed alternately at intervals in the first direction X. In this structure, the second trench separation structure 342 has the first and second internal connecting portions 362, 372 which connect end portions of the two second trench structures 322 which are adjacent to each other at an interval from the end portion of the first trench structure 321. According to this structure, it is possible to suppress the electric current concentration (electric field concentration) at the end portions (first end portion 323 and second end portion 324) of the trench structure 320 by the second trench separation structure 342.

The first and the second internal connecting portions 362, 372 preferably extend in a circular arc shape at the end portions of the two adjacent second trench structures 322. According to this structure, it is possible to appropriately suppress the electric current concentration (electric field concentration) at the end portions (first end portion 323 and second end portion 324) of the trench structure 320 by the second trench separation structure 342.

The semiconductor device 301 preferably includes the p-type semiconductor region 400 which is formed at the surface layer portion of the first main surface 303 along at least one of the first and the second trench separation structures 341, 342. According to this structure, it is possible to relax the electric field intensity at the peripheral edge portion of at least one of the first and the second trench separation structures 341, 342 by the second depletion layer 460 which expands from the semiconductor region 400 and by the semiconductor region 400. It is thereby possible to improve the breakdown voltage VB.

The semiconductor region 400 is preferably fixed in the electrically floating state. According to this structure, the semiconductor region 400 does not form a pn-junction (that is, pn-junction diode) with the drift layer 307. Therefore, it is possible to suppress the breakdown voltage VB of the SBD from being limited by the breakdown voltage VB of the pn-junction diode. It is thereby possible to suppress the reverse current IR, with the peripheral edge portion of at least one of the first and the second trench separation structures 341, 342 given as a starting point, and also to suppress a decrease in breakdown voltage VB.

The embodiments of the present invention can be implemented still in other modes. In the previously described first to ninth embodiments, a description has been given of an example in which the semiconductor chip 2 is constituted of silicon. However, the semiconductor chip 2 may be constituted of a wide band gap semiconductor which is higher in band gap than silicon. In this case, the semiconductor chip 2 may be constituted of an SiC (silicon carbide) chip. Further, the cathode layer 6 may be formed of an n-type SiC semiconductor substrate. Further, the drift layer 7 and the buffer layer 8 may be formed of an n-type SiC epitaxial layer.

In the previously described tenth embodiment, a description has been given of an example in which the second region 404 of the semiconductor region 400 has the plurality of externally curved regions 406 and the plurality of internally curved regions 407. However, the second region 404 does not need to have the externally curved region 406 and the internally curved region 407 and may linearly extend in the first direction X.

In the previously described tenth embodiment, a description has been given of an example in which the electrode side wall 421 of the Schottky electrode 420 has the plurality of externally curved side walls 422 and the plurality of internally curved side wall 423. However, the electrode side wall 421 does not need to have the externally curved side wall 422 and the internally curved side wall 423 and may linearly extend in the first direction X.

In the previously described tenth embodiment, a description has been given of an example in which the semiconductor chip 302 is constituted of silicon. However, the semiconductor chip 302 may be constituted of a wide band gap semiconductor which is higher in band gap than silicon. In this case, the semiconductor chip 302 may be constituted of an SiC (silicon carbide) chip. Further, the cathode layer 306 may be formed of an n-type SiC semiconductor substrate. Further, the drift layer 307 and the buffer layer 308 may be formed of an n-type SiC epitaxial layer.

In the previously described tenth embodiment, the semiconductor device 301 may include an organic insulating film which covers the upper insulating film 430. The organic insulating film preferably includes a photosensitive resin. The photosensitive resin may be a negative type or a positive type. The organic insulating film may contain at least one among polyimide, polyamide and polybenzoxazole.

Hereinafter, examples of features extracted from the present specification and the drawings. The following [A1] to [A20], [B1] to [B20], [C1] to [C20], [D1] to [D20] and [E1] to [E20] provide a semiconductor device capable of improving the electrical characteristics are shown. [A1] to [A20] are effective in suppressing a decrease in withstand voltage, with the peripheral edge of the active region given as a starting point. [B1] to [B20] are effective in improving reliability. Hereinafter, although alphanumeric characters inside the parenthesis indicate corresponding constituents in the previously described embodiments, they are not to limit a scope of each claim to the embodiments.

[A1] A semiconductor device (1, 131, 133, 141, 151, 161, 171, 181, 201) comprising: a semiconductor layer (7) of a first conductivity type (n type) which has a main surface (3); a trench separation structure (10) which includes a separation trench (14) that is formed in the main surface (3), a separation insulating film (15) that covers a wall surface of the separation trench (14) and a separation electrode (16) that is embedded in the separation trench (14) across the separation insulating film (15), the trench separation structure (10) demarcating an outer region (21) and an active region (22) in the main surface (3); a floating region (40) of a second conductivity type (p-type) which is formed in an electrically floating state at a surface layer portion of the main surface (3) along the trench separation structure (10) in the outer region (21); and a Schottky electrode (60) which is electrically connected to the separation electrode (16) such as to retain the floating region (40) in the electrically floating state in the outer region (21) and forms a Schottky junction with the main surface (3) in the active region (22).

[A2] The semiconductor device (1, 131, 133, 141, 151, 161, 171, 181, 201) according to A1, wherein the floating region (40) is adjacent to the trench separation structure (10) in the outer region (21).

[A3] The semiconductor device (1, 131, 133, 141, 151, 161, 171, 181, 201) according to A1 or A2, wherein the floating region (40) is formed in a depth range between the main surface (3) and a bottom wall of the trench separation structure (10) in the outer region (21).

[A4] The semiconductor device (1, 131, 133, 141, 151, 161, 171, 181, 201) according to any one of A1 to A3, wherein the floating region (40) is formed deeper than the trench separation structure (10).

[A5] The semiconductor device (1, 131, 133, 141, 151, 161, 171, 181, 201) according to any one of A1 to A4, wherein the floating region (40) has a covering portion (43) which covers the bottom wall of the trench separation structure (10).

[A6] The semiconductor device (1, 131, 133, 141, 151, 161, 171, 181, 201) according to A5, wherein the covering portion (43) covers a portion on the outer region (21) side such as to expose a portion on the active region (22) side in the bottom wall of the trench separation structure (10).

[A7] The semiconductor device (1, 131, 133, 141, 151, 161, 171, 181, 201) according to any one of A1 to A6, wherein the trench separation structure (10) is formed in an annular shape having an inner peripheral wall (11) and an outer peripheral wall (12) as viewed in plan and demarcates the outer region (21) and the active region (22) by the inner peripheral wall (11) in the main surface (3), and the floating region (40) is formed along the outer peripheral wall (12) of the trench separation structure (10) in the outer region (21).

[A8] The semiconductor device (1, 131, 133, 141, 151, 161, 171, 181, 201) according to A7, wherein the floating region (40) surrounds the trench separation structure (10) as viewed in plan.

[A9] The semiconductor device (1, 131, 133, 141, 151, 161, 171, 181, 201) according to any one of A1 to A8, wherein the Schottky electrode (60) is connected to a portion of the separation electrode (16) on the active region (22) side such as to expose a portion of the separation electrode (16) on the outer region (21) side.

[A10] The semiconductor device (1, 131, 133, 141, 151, 161, 171, 181, 201) according to any one of A1 to A9, wherein the main surface (3) inside the active region (22) is depressed in a thickness direction with respect to the main surface (3) inside the outer region (21).

[A11] The semiconductor device (1, 131, 133, 141, 151, 161, 171, 181, 201) according to A10, wherein the trench separation structure (10) includes a first portion (25) which is positioned on the outer region (21) side and a second portion (26) which is positioned on the active region (22) side and depressed in a thickness direction of the semiconductor layer (7) with respect to the first portion (25), and the trench separation structure (10) demarcates a contact opening (27) which is depressed from the main surface (3) inside the outer region (21) in a thickness direction of the semiconductor layer (7) outer region (21), with the main surface (3) inside the active region (22).

[A12] The semiconductor device (1, 131, 133, 141, 151, 161, 171, 181, 201) according to any one of A1 to A11, further comprising: a main surface insulating film (50) which is formed on the outer region (21) such as to cover an entire area of the floating region (40).

[A13] The semiconductor device (1, 131, 133, 141, 151, 161, 171, 181, 201) according to A12, wherein the main surface insulating film (50) covers a portion of the separation electrode (16) on the outer region (21) side such as to expose a portion of the separation electrode (16) on the active region (22) side.

[A14] The semiconductor device (1, 131, 133, 141, 151, 161, 171, 181, 201) according to A12 or A13, wherein the main surface insulating film (50) has a wall portion which demarcates a through hole (51) that exposes the active region (22) on the separation electrode (16), and the Schottky electrode (60) is electrically connected to the main surface (3) and the separation electrode (16) inside the through hole (51).

[A15] The semiconductor device (1, 131, 133, 141, 151, 161, 171, 181, 201) according to any one of A12 to A14, wherein the Schottky electrode (60) has a lead-out portion (62) which is led out on the main surface insulating film (50) from the active region (22) and faces a part of the separation electrode (16) and the floating region (40) across the main surface insulating film (50).

[A16] The semiconductor device (1, 131, 133, 141, 151, 161, 171, 181, 201) according to A15, wherein the lead-out portion (62) faces an entire area of the floating region (40) across the main surface insulating film (50).

[A17] The semiconductor device (1, 131, 133, 141, 151, 161, 171, 181, 201) according to any one of A1 to A16, further comprising: a trench structure (30) which includes a trench (36) that is formed in the main surface (3), an insulating film (37) that covers a wall surface of the trench (36) and an electrode (38) that is embedded in the trench (36) across the insulating film (37) and is formed at an interval on the main surface (3) in the active region (22); wherein the Schottky electrode (60) is electrically connected to the electrode (38) in the active region (22) and forms the Schottky junction with the main surface (3).

[A18] The semiconductor device (1, 131, 133, 141, 151, 161, 171, 181, 201) according to A17, further comprising: a protrusion portion (37a) which is constituted of an upper end portion of the insulating film (37) and protrudes as a wall from the main surface (3) such as to separate the electrode (38) and the main surface (3).

[A19] The semiconductor device (1, 131, 133, 141, 151, 161, 171, 181, 201) according to A17 or 18, wherein the trench separation structure (10) is formed wider than the trench structure (30).

[A20] The semiconductor device (1, 131, 133, 141, 151, 161, 171, 181, 201) according to any one of A17 to A19, wherein the trench structure (30) is connected to the trench separation structure (10).

[B1] A semiconductor device (1, 131, 133, 141, 151, 161, 171, 181, 201) comprising: a semiconductor layer (7) which has a main surface (3); a trench structure (30) which includes a trench (36) that is formed in the main surface (3), an insulating film (37) that covers a wall surface of the trench (36) and an electrode (38) that is embedded in the trench (36) across the insulating film (37); a protrusion portion (37a) which is constituted of an upper end portion of the insulating film (37) and protrudes as a wall from the main surface (3) such as to separate the electrode (38) and the main surface (3); and a Schottky electrode (60) which covers the main surface (3) and the trench structure (30) and which forms a Schottky junction with the main surface (3).

According to this semiconductor device, an insulation distance between the electrode (38) and the main surface (3) is increased by the protrusion portion (15a). It is thereby possible to suppress a change in electrical characteristics resulting from a boundary leakage which occurs between the electrode (38) and the main surface (3). Thus, it is possible to provide the semiconductor device capable of improving reliability.

[B2] The semiconductor device (1, 131, 133, 141, 151, 161, 171, 181, 201) according to B1, wherein the protrusion portion (37a) protrudes upper than the electrode (38).

[B3] The semiconductor device (1, 131, 133, 141, 151, 161, 171, 181, 201) according to B1 or B2, wherein the electrode (38) is positioned on a bottom wall (35) side of the trench (36) with respect to the main surface (3).

[B4] The semiconductor device (1, 131, 133, 141, 151, 161, 171, 181, 201) according to any one of B1 to B3, wherein the protrusion portion (37a) linearly extends along the wall surface of the trench (36) as viewed in plan.

[B5] The semiconductor device (1, 131, 133, 141, 151, 161, 171, 181, 201) according to any one of B1 to B4, wherein the protrusion portion (37a) is formed in an entire area of the trench structure (30).

[B6] The semiconductor device (1, 131, 133, 141, 151, 161, 171, 181, 201) according to any one of B1 to B5, wherein the protrusion portion (37a) demarcates a recess with the electrode (38) at an inner portion of the trench structure (30), and the Schottky electrode (60) enters into the recess from above the protrusion portion (37a) and is connected to the electrode (38) inside the recess.

[B7] The semiconductor device (1, 131, 133, 141, 151, 161, 171, 181, 201) according to any one of B1 to B6, wherein the main surface (3) includes an outer main surface (23) that is positioned at a peripheral edge portion and an active main surface (24) that is positioned at an inner portion and depressed in a thickness direction with respect to the outer main surface (23), the trench structure (30) is formed in the active main surface (24), the protrusion portion (37a) protrudes in the wall shape from the active main surface (24), and the Schottky electrode (60) forms the Schottky junction with the active main surface (24).

[B8] The semiconductor device (1, 131, 133, 141, 151, 161, 171, 181, 201) according to B7, wherein the protrusion portion (37a) is formed in a depth range between the outer main surface (23) and the active main surface (24).

[B9] The semiconductor device (1, 131, 133, 141, 151, 161, 171, 181, 201) according to B7 or B8, wherein the Schottky electrode (60) is electrically separated from the outer main surface (23).

[B10] The semiconductor device (1, 131, 133, 141, 151, 161, 171, 181, 201) according to any one of B1 to B9, wherein the plurality of trench structures (30) are formed at an interval in the main surface (3) such that at least one mesa portion (39) of a mesa shape is demarcated in the main surface (3), and the plurality of protrusion portions (37a) are formed such as to separate the plurality of trench structures (30) and the mesa portion (39).

[B11] The semiconductor device (1, 131, 133, 141, 151, 161, 171, 181, 201) according to B10, wherein the plurality of protrusion portions (37a) demarcate a mesa recess with the mesa portion (39), and the Schottky electrode (60) enters into the mesa recess from above the plurality of protrusion portions (37a) and forms a Schottky junction with the main surface (3) inside the mesa recess.

[B12] The semiconductor device (1, 131, 133, 141, 151, 161, 171, 181, 201) according to any one of B1 to B11, further comprising: a trench separation structure (10) which includes a separation trench (14) that is formed in the main surface (3), a separation insulating film (15) that covers a wall surface of the separation trench (14) and a separation electrode (16) that is embedded in the separation trench (14) across the separation insulating film (15), the trench separation structure (10) demarcating an outer region (21) and an active region (22) in the main surface (3); wherein the trench structure (30) is formed in the main surface (3) in the active region (22).

[B13] The semiconductor device (1, 131, 133, 141, 151, 161, 171, 181, 201) according to B12, further comprising: a separation protrusion portion (15a) which is constituted of an upper end portion of the separation insulating film (15) and protrudes as a wall from the main surface (3) such as to separate the separation electrode (16) and the main surface (3).

[B14] The semiconductor device (1, 131, 133, 141, 151, 161, 171, 181, 201) according to B13, wherein the trench structure (30) is connected to the trench separation structure (10), and the protrusion portion (37a) is connected to the separation protrusion portion (15a).

[B15] The semiconductor device (1, 131, 133, 141, 151, 161, 171, 181, 201) according to any one of B12 to B14, wherein the trench separation structure (10) is formed in an annular shape having an inner peripheral wall and an outer peripheral wall as viewed in plan and demarcates the outer region (21) and the active region (22) in the main surface (3) by the inner peripheral wall.

[B16] The semiconductor device (1, 131, 133, 141, 151, 161, 171, 181, 201) according to any one of B12 to B15, wherein the Schottky electrode (60) is connected to the separation electrode (16).

[B17] The semiconductor device (1, 131, 133, 141, 151, 161, 171, 181, 201) according to any one of B12 to B16, further comprising: a semiconductor layer (7) of a first conductivity type; and a floating region (40) of a second conductivity type which is formed in an electrically floating state at a surface layer portion of the main surface (3) along the trench separation structure (10) in the outer region (21); wherein the Schottky electrode (60) forms the Schottky junction with the main surface (3) in the active region (22) such as to retain the floating region (40) in the electrically floating state in the outer region (21).

[B18] A semiconductor device (1, 131, 133, 141, 151, 161, 171, 181, 201) comprising: a semiconductor layer (7) which has a main surface (3); a trench separation structure (10) which includes a separation trench (36) that is formed in the main surface (3), a separation insulating film (37) that covers a wall surface of the separation trench (36) and a separation electrode (38) that is embedded in the separation trench (36) across the separation insulating film (37), the trench separation structure (10) demarcating an outer region (21) and an active region (22) in the main surface (3); a separation protrusion portion (37a) which is constituted of an upper end portion of the separation insulating film (37) and protrude as a wall from the main surface (3) such as to separate the separation electrode (38) and the main surface (3) on the active region (22) side; and a Schottky electrode (38) which forms a Schottky junction with the main surface (3) on the active region (22) side.

According to this semiconductor device, an insulation distance between the separation electrode (38) and the main surface (3) on the active region (22) side is increased by the separation protrusion portion (37a). It is thereby possible to suppress a change in electrical characteristics resulting from a boundary leakage which occurs between the separation electrode (38) and the main surface (3). Thus, it is possible to provide the semiconductor device capable of improving reliability.

[B19] The semiconductor device (1, 131, 133, 141, 151, 161, 171, 181, 201) according to B18, further comprising: a semiconductor layer (7) of a first conductivity type; and a floating region (40) of a second conductivity type which is formed in an electrically floating state at the surface layer portion of the main surface (3) along the trench separation structure (10) in the outer region (21), wherein the Schottky electrode (38) retains the floating region (40) in the electrically floating state in the outer region (21) and forms the Schottky junction with the main surface (3) in the active region (22).

[B20] The semiconductor device (1, 131, 133, 141, 151, 161, 171, 181, 201) according to B18 or B19, wherein the main surface (3) inside the active region (22) is depressed in a thickness direction with respect to the main surface (3) inside the outer region (21).

[C1] A semiconductor device (301) comprising: a semiconductor layer (307) of a first conductivity type (n-type) which has a main surface (303); a plurality of trench structures (320) which include a first trench structure (321) and a second trench structure (322) that are formed in the main surface (303) at an interval in a first direction (X) and that each extends in a band shape in a second direction (Y) that intersects the first direction (X); a first trench separation structure (341) which is formed in the main surface (303) at an interval from the first trench structure (321) in the first direction (X) such as to face the second trench structure (322) across the first trench structure (321) and which extends in a band shape in the second direction (Y); a second trench separation structure (342) which has an outer connecting portion (361, 371) that connects an end portion (343, 344) of the first trench separation structure (341) and an end portion (323, 324) of the second trench structure (322) at an interval from an end portion (323, 324) of the first trench structure (321) and that extends in a band shape in the first direction (X); and a Schottky electrode (420) which is connected to a portion that is exposed from the plurality of trench structures (320) in the main surface (303).

According to this structure, it is possible to suppress an electric current concentration at the end portion (323, 324) of the trench structure (320) and the end portion (343, 344) of the first trench separation structure (341) by the second trench separation structure (342). It is, thus, possible to provide the semiconductor device (301) capable of improving the electrical characteristics.

[C2] The semiconductor device (301) according to C1, wherein the outer connecting portion (361, 371) extends in a circular arc shape between the end portion (343, 344) of the first trench separation structure (341) and the end portion (323, 324) of the second trench structure (322).

[C3] The semiconductor device (301) according to C1 or C2, further comprising: an outer mesa portion (391) which has a first portion (393) that is demarcated among the plurality of trench structures (320) and the first trench separation structure (341) in the semiconductor layer (307) and a second portion (394) that is demarcated between the end portion (323, 324) of the first trench structure (321) and the outer connecting portion (361, 371) in the semiconductor layer (307); wherein the Schottky electrode (420) forms the Schottky junction with the outer mesa portion (391).

[C4] The semiconductor device (301) according to C3, wherein the Schottky electrode (420) forms the Schottky junction with the first portion (393) and the second portion (394) of the outer mesa portion (391).

[C5] The semiconductor device (301) according to any one of C1 to C4, wherein the plurality of trench structures (320) are formed at a first interval (I11) in the first direction (X), the first trench separation structure (341) is formed at a second interval (112) falling within a range of not less than 0.9 times and not more than 1.1 times larger than the first interval (I11) in the first direction (X) from the first trench structure (321), and the outer connecting portion (361, 371) connect the end portion (343, 344) of the first trench separation structure (341) and the end portion (323, 324) of the second trench structure (322) at a third interval (113) falling within a range of not less than 0.9 times and not more than 1.1 times larger than the first interval (I11) in the second direction (Y) from the end portion (323, 324) of the first trench structure (321).

[C6] The semiconductor device (301) according to any one of C1 to C4, wherein the plurality of trench structures (320) include the plurality of first trench structures (321) and the plurality of second trench structures (322) which are arrayed alternately at intervals in the first direction (X), and the second trench separation structure (342) has a connecting portion (362, 372) internal connecting portion (362, 372) which connect the end portions (323, 324) of the two adjacent second trench structures (322) at an interval from the end portion (323, 324) of the first trench structure (321).

[C7] The semiconductor device (301) according to C6, wherein the connecting portion (362, 372) the internal connecting portions (362, 372) extend in a circular arc shape between the end portions (323, 324) of the two adjacent second trench structures (322).

[C8] The semiconductor device (301) according to any one of C1 to C7, wherein the plurality of trench structures (320) each has a first width (W11), the first trench separation structure (341) has a second width (W12) in excess of the first width (W11), and the second trench separation structure (342) has a third width (W13) in excess of the first width (W11).

[C9] The semiconductor device (301) according to any one of C1 to C8, wherein the plurality of trench structures (320) are constituted of an odd number of the structures.

[C10] The semiconductor device (301) according to any one of C1 to C9, further comprising: a semiconductor region (400) of a second conductivity type (p-type) which is formed at a surface layer portion of the main surface (303) along the first trench separation structure (341) and the second trench separation structure (342).

[C11] The semiconductor device (301) according to C10, wherein the semiconductor region (400) is fixed in an electrically floating state.

[C12] The semiconductor device (301) according to C10 or C11, wherein the semiconductor region (400) includes a first region (403) along the first trench separation structure (341), a second region (404) along the second trench separation structure (342) and a third region (405) which connects the first region (403) and the second region (404) in a circular arc shape.

[C13] The semiconductor device (301) according to any one of C10 to C12, further comprising: an insulating film (410) which covers the semiconductor region (400); wherein the Schottky electrode (420) faces the semiconductor region (400) across the insulating film (410).

[C14] A semiconductor device (301) comprising: a semiconductor layer (307) of a first conductivity type (n-type) which has a main surface (303); a plurality of trench structures (320) which include a plurality of first trench structures (321) and a plurality of second trench structures (322) that are formed alternately in the main surface (303) at an interval in a first direction (X) and that each extends in a band shape in a second direction (Y) that intersects the first direction (X); a trench separation structure (342) which has a connecting portion (362, 372) that connects end portions (323, 324) of the two adjacent second trench structures (322) at an interval from an end portion (323, 324) of the first trench structure (321); and a Schottky electrode (420) which is connected to a portion that is exposed from the plurality of trench structures (320) in the main surface (303).

[C15] The semiconductor device (301) according to C14, wherein the connecting portion (362, 372) extends in a circular arc shape between the end portions (323, 324) of the two adjacent second trench structures (322).

[C16] The semiconductor device (301) according to C14 or C15, further comprising: a mesa portion (392) which has a first portion (395) that is demarcated among the plurality of trench structures (320) in the semiconductor layer (307) and a second portion (396) that is demarcated between the end portion (323, 324) of the trench structure (320) and the connecting portion (362, 372) in the semiconductor layer (307), wherein the Schottky electrode (420) forms a Schottky junction with the first portion (395) and the second portion (396) of the mesa portion (392).

[C17] The semiconductor device (301) according to C16, wherein the mesa portion (392) is formed in an annular shape which surrounds the first trench structure (321).

[C18] The semiconductor device (301) according to any one of C14 to C17, wherein the plurality of trench structures (320) are formed at a first interval (I11) in the first direction (X), and the connecting portion (362, 372) connect the end portions (323, 324) of the two adjacent second trench structures (322) at a second interval (112) falling within a range of not less than 0.9 times and not more than 1.1 times larger than the first interval (I11) in the second direction (Y) from the end portion (323, 324) of the first trench structure (321).

[C19] The semiconductor device (301) according to any one of C14 to C18, wherein the trench separation structure (342) has a plurality of the connecting portions (362, 372).

[C20] The semiconductor device (301) according to any one of C14 to C19, further comprising: a semiconductor region (400) of a second conductivity type (p-type) which is formed at the surface layer portion of the main surface (303) along the trench separation structure (342).

[D1] A semiconductor device (301) comprising: a semiconductor layer (307) which has a main surface (303); a trench structure (320, 321, 322) which includes a trench (328) that is formed in the main surface (303), an insulating film (329) that covers a wall surface of the trench (328) and an electrode (330) that is embedded in the trench (328) across the insulating film (329); a protrusion portion (331) which is constituted of an upper end portion of the insulating film (329) and protrudes as a wall from the main surface (303) such as to separate the electrode (330) and the main surface (303); and a Schottky electrode (420) which covers the main surface (303) and the trench structure (320, 321, 322) and which forms a Schottky junction with the main surface (303).

According to this semiconductor device (301), it is possible to separate a portion which covers the insulating film (329) in the Schottky electrode (420) from the Schottky junction portion by the protrusion portion (331). It is thereby possible to suppress a tunneling leakage current to the semiconductor layer (307) resulting from the portion which covers the insulating film (329) in the Schottky electrode (420). It is, thus, possible to provide the semiconductor device (301) capable of improving reliability.

[D2] The semiconductor device (301) according to D1, wherein the protrusion portion (331) protrudes upper than the electrode (330).

[D3] The semiconductor device (301) according to D1 or D2, wherein the electrode (330) is positioned on the bottom wall (327) side of the trench (328) with respect to the main surface (303).

[D4] The semiconductor device (301) according to any one of D1 to D3, wherein the protrusion portion (331) linearly extends along the wall surface of the trench (328) as viewed in plan.

[D5] The semiconductor device (301) according to any one of D1 to D4, wherein the protrusion portion (331) is formed in an entire area of the trench structure (320, 321, 322).

[D6] The semiconductor device (301) according to any one of D1 to D5, wherein the protrusion portion (331) demarcates a recess (332) with the electrode (330) in an inner portion of the trench structure (320, 321, 322), and the Schottky electrode (420) enters into the recess (332) from above the protrusion portion (331) and is connected to the electrode (330) inside the recess (332).

[D7] The semiconductor device (301) according to any one of D1 to D6, wherein the main surface (303) includes an outer main surface (312) that is positioned at a peripheral edge portion and an active main surface (313) that is positioned at an inner portion and depressed in a thickness direction with respect to the outer main surface (312), the trench structure (320, 321, 322) is formed in the active main surface (313), the protrusion portion (331) protrudes in the wall shape from the active main surface (313), and the Schottky electrode (420) forms the Schottky junction with the active main surface (313).

[D8] The semiconductor device (301) according to D7, wherein the protrusion portion (331) is formed in a depth range between the outer main surface (312) and the active main surface (313).

[D9] The semiconductor device (301) according to D7 or D8, wherein the Schottky electrode (420) is electrically separated from the outer main surface (312).

[D10] The semiconductor device (301) according to any one of D1 to D9, further comprising: a plurality of the trench structures (320, 321, 322); and a mesa portion (390) which is demarcated in the semiconductor layer (307) such as to be electrically separated from the plurality of electrodes (330) by the plurality of protrusion portions (331).

[D11] The semiconductor device (301) according to D10, wherein the Schottky electrode (420) covers the plurality of protrusion portions (331) and the mesa portion (390) and forms the Schottky junction with the mesa portion (390).

[D12] The semiconductor device (301) according to any one of D1 to D11, further comprising: a trench separation structure (340, 341, 342) which includes a separation trench (348, 378) that is formed in the main surface (303), a separation insulating film (349, 379) that covers a wall surface of the separation trench (348, 378) and a separation electrode (350, 380) that is embedded in the separation trench (348, 378) across the separation insulating film (349, 379), the trench separation structure (340, 341, 342) demarcating an outer region (310) and an active region (311) in the main surface (303), wherein the trench structure (320, 321, 322) is formed in the main surface (303) in the active region (311).

[D13] The semiconductor device (301) according to D12, further comprising: a separation protrusion portion (351, 381) which is constituted of an upper end portion of the separation insulating film (349, 379) and protrudes as a wall from the main surface (303) such as to separate the separation electrode (350, 380) and the main surface (303).

[D14] The semiconductor device (301) according to D13, wherein the separation protrusion portion (351, 381) is connected to the protrusion portion (331).

[D15] The semiconductor device (301) according to any one of D12 to D14, wherein the trench separation structure (340, 341, 342) is formed in an annular shape which surrounds the trench structure (320, 321, 322) as viewed in plan.

[D16] The semiconductor device (301) according to any one of D12 to D15, wherein the Schottky electrode (420) is electrically connected to the separation electrode (350, 380).

[D17] The semiconductor device (301) according to any one of D12 to D16, further comprising: the semiconductor layer (307) of a first conductivity type and a floating region (400) of a second conductivity type which is formed in an electrically floating state at a surface layer portion of the main surface (303) along the trench separation structure (340, 341, 342) in the outer region (310), wherein the Schottky electrode (420) forms the Schottky junction with the main surface (303) in the active region (311) such as to retain the floating region (400) in the electrically floating state in the outer region (310).

[D18] A semiconductor device (301) comprising: a semiconductor layer (307) which has a main surface (303), a trench separation structure (340, 341, 342) which includes a separation trench (348, 378) that is formed in the main surface (303), a separation insulating film (349, 379) that covers a wall surface of the separation trench (348, 378) and a separation electrode (350, 380) that is embedded in the separation trench (348, 378) across the separation insulating film (349, 379), the trench separation structure (340, 341, 342) demarcating an outer region (310) and an active region (311) in the main surface (303); a separation protrusion portion (351, 381) which is constituted of an upper end portion of the separation insulating film (349, 379) and protrudes as a wall from the main surface (303) such as to separate the separation electrode (350, 380) and the main surface (303) on the active region (311) side; and a Schottky electrode (420) which forms a Schottky junction with the main surface (303) on the active region (311) side.

According to this semiconductor device (301), it is possible to separate a portion which covers the separation insulating film (349, 379) in the Schottky electrode (420) from the Schottky junction portion by the separation protrusion portion (351, 381). It is thereby possible to suppress a tunneling leakage current to the semiconductor layer (307) due to the portion which covers the separation insulating film (349, 379) in the Schottky electrode (420). It is, thus, possible to provide the semiconductor device (301) capable of improving reliability.

[D19] The semiconductor device (301) according to D18, further comprising: the semiconductor layer (307) of a first conductivity type and a floating region (400) of a second conductivity type which is formed in an electrically floating state at the surface layer portion of the main surface (303) along the trench separation structure (340, 341, 342) in the outer region (310), wherein the Schottky electrode (420) retains the floating region (400) in the electrically floating state in the outer region (310) and forms the Schottky junction with the main surface (303) in the active region (311).

[D20] The semiconductor device (301) according to D18 or D19, wherein the main surface (303) inside the active region (311) is depressed in a thickness direction with respect to the main surface (303) inside the outer region (310).

[E1] A semiconductor device (301) comprising: a semiconductor layer (307) of a first conductivity type (n-type) which has a main surface (303); a trench separation structure (340, 341, 342) which includes a separation trench (348, 378) that is formed in the main surface (303), a separation insulating film (349, 379) that covers a wall surface of the separation trench (348, 378) and a separation electrode (350, 380) that is embedded in the separation trench (348, 378) across the separation insulating film (349, 379), the trench separation structure (340, 341, 342) demarcating an outer region (310) and an active region (311) in the main surface (303); a floating region (400) of a second conductivity type (p-type) which is formed in an electrically floating state at a surface layer portion of the main surface (303) along the trench separation structure (340, 341, 342) in the outer region (310); and a Schottky electrode (420) which is electrically connected to the separation electrode (350, 380) such as to retain the floating region (400) in the electrically floating state in the outer region (310) and which forms a Schottky junction with the main surface (303) in the active region (311).

According to this structure, it is possible to relax an electric field intensity at a peripheral edge portion of the active region (311) by a depletion layer which expands from the floating region (400). Further, since the floating region (400) is formed in the electrically floating state, it does not form a pn-junction (that is, pn-junction diode) with the semiconductor layer (307). Therefore, it is possible to suppress a breakdown voltage (VB) of the SBD from being limited by a breakdown voltage (VB) of the pn-junction diode. It is thereby possible to suppress a reverse current (IR), with the peripheral edge portion of the active region (311) given as a starting point, and also to suppress a decrease in breakdown voltage (VB). It is, thus, possible to provide the semiconductor device (301) capable of improving the electrical characteristics.

[E2] The semiconductor device (301) according to E1, wherein the floating region (400) is adjacent to the trench separation structure (340, 341, 342) in the outer region (310).

[E3] The semiconductor device (301) according to E1 or E2, wherein the floating region (400) is formed in a depth range between the main surface (303) and a bottom wall (347, 357) of the trench separation structure (340, 341, 342) in the outer region (310).

[E4] The semiconductor device (301) according to any one of E1 to E3, wherein the floating region (400) is formed deeper than the trench separation structure (340, 341, 342).

[E5] The semiconductor device (301) according to any one of E1 to E4, wherein the floating region (400) has a covering portion (408) which covers a bottom wall (347, 357) of the trench separation structure (340, 341, 342).

[E6] The semiconductor device (301) according to E5, wherein the covering portion (408) covers a portion on the outer region (310) side such as to expose a portion on the active region (311) side in the bottom wall (347, 357) of the trench separation structure (340, 341, 342).

[E7] The semiconductor device (301) according to any one of E1 to E6, wherein the trench separation structure (340, 341, 342) is formed in an annular shape as viewed in plan, and the floating region (400) is formed along an outer peripheral wall of the trench separation structure (340, 341, 342) in the outer region (310).

[E8] The semiconductor device (301) according to E7, wherein the floating region (400) surrounds the trench separation structure (340, 341, 342) as viewed in plan.

[E9] The semiconductor device (301) according to any one of E1 to E8, wherein the Schottky electrode (420) is connected to a portion of the separation electrode (350, 380) on the active region (311) side such as to expose a portion of the separation electrode (350, 380) on the outer region (310) side.

[E10] The semiconductor device (301) according to any one of E1 to E9, wherein the main surface (303) inside the active region (311) is depressed in a thickness direction with respect to the main surface (303) inside the outer region (310).

[E11] The semiconductor device (301) according to E10, wherein the trench separation structure (340, 341, 342) includes a first portion (350a, 380a) which is positioned on the outer region (310) side and a second portion (50b, 80b) which is positioned on the active region (311) side and depressed in a thickness direction of the semiconductor layer (307) with respect to the first portion (350a, 380a).

[E12] The semiconductor device (301) according to any one of E1 to E11, further comprising: a main surface insulating film (410) which is formed on the outer region (310) such as to cover an entire area of the floating region (400).

[E13] The semiconductor device (301) according to E12, wherein the main surface insulating film (410) covers a portion of the separation electrode (350, 380) on the outer region (310) side such as to expose a portion of the separation electrode (350, 380) on the active region (311) side.

[E14] The semiconductor device (301) according to E12 or E13, wherein the main surface insulating film (410) has a wall portion (412) which demarcates a contact opening (411) exposing the active region (311) on the separation electrode (350, 380), and the Schottky electrode (420) is electrically connected to the main surface (303) and the separation electrode (350, 380) inside the contact opening (411).

[E15] The semiconductor device (301) according to any one of E12 to E14, wherein the Schottky electrode (420) has a lead-out portion (424) which is led out on the main surface insulating film (410) from the active region (311) and faces a part of the separation electrode (350, 380) and the floating region (400) across the main surface insulating film (410).

[E16] The semiconductor device (301) according to E15, wherein the lead-out portion (424) faces an entire area of the floating region (400) across the main surface insulating film (410).

[E17] The semiconductor device (301) according to any one of E1 to E16, further comprising: a trench structure (320, 321, 322) which includes a trench (328) that is formed in the main surface (303), an insulating film (329) that covers a wall surface of the trench (328) and an electrode (330) that is embedded in the trench (328) across the insulating film (329) and is formed at an interval on the main surface (303) in the active region (311); wherein the Schottky electrode (420) is electrically connected to the electrode (330) in the active region (311) and forms the Schottky junction with the main surface (303).

[E18] The semiconductor device (301) according to E17, further comprising: a protrusion portion (331) which is constituted of an upper end portion of the insulating film (329) and protrudes as a wall from the main surface (303) such as to separate the electrode (330) and the main surface (303).

[E19] The semiconductor device (301) according to E17 or E18, wherein the trench separation structure (340, 341, 342) is formed wider than the trench structure (320, 321, 322).

[E20] The semiconductor device (301) according to any one of E17 to E19, wherein the trench structure (320, 321, 322) is connected to the trench separation structure (340, 341, 342).

While embodiments of the present invention have been described in detail, these are merely specific examples used to clarify the technical content of the present invention, and the present invention should not be interpreted as being limited to these specific examples and the scope of the present invention shall be limited only by the attached claims.

### REFERENCE SIGNS LIST

1 Semiconductor device
3 First main surface
7 Drift layer (semiconductor layer)
10 Trench separation structure
11 Inner peripheral wall
12 Outer peripheral wall
13 Bottom wall
14 Separation trench
15 Separation insulating film
16 Separation electrode
21 Outer region
22 Active region
25 First portion
26 Second portion
27 Contact opening
30 Trench structure
36 Trench
37 Insulating film
37a Protrusion portion
38 Electrode
40 Floating region
43 Covering portion
50 Main surface insulating film
51 Through hole
60 Schottky electrode
62 Lead-out portion
131 Semiconductor device
133 Semiconductor device
141 Semiconductor device
151 Semiconductor device
161 Semiconductor device
171 Semiconductor device
181 Semiconductor device
201 Semiconductor device
301 Semiconductor device
303 First main surface
307 Drift layer (semiconductor layer)
320 Trench structure
321 First trench structure
322 Second trench structure
323 First end portion
324 Second end portion
341 First trench separation structure
342 Second trench separation structure
343 First end portion
344 Second end portion
361 First outer connecting portion (connecting portion)
362 First internal connecting portion (connecting portion)
371 Second outer connecting portion (connecting portion)
372 Second internal connecting portion (connecting portion)
391 Outer mesa portion
392 Inner mesa portion
393 First mesa main body (first portion)
394 First mesa end portion (second portion)
395 First mesa main body (first portion)
396 Second mesa end portion (second portion)
400 Semiconductor region
403 First region
404 Second region
405 Third region
410 Main surface insulating film
420 Schottky electrode
I1 First interval
I2 Second interval
I3 Third interval
I11 First interval
I12 Second interval
I13 Third interval
W1 First width
W2 Second width
W3 Third width
W11 First width
W12 Second width
W13 Third width
X First direction
Y Second direction

1. A semiconductor device comprising:
a semiconductor layer of a first conductivity type which has a main surface:
a trench separation structure which includes a separation trench that is formed in the main surface, a separation insulating film that covers a wall surface of the separation trench and a separation electrode that is embedded in the separation trench across the separation insulating film, trench separation structure demarcating an outer region and an active region in the main surface;
a floating region of a second conductivity type which is formed in an electrically floating state at a surface layer portion of the main surface along the trench separation structure in the outer region; and
a Schottky electrode which is electrically connected to the separation electrode such as to retain the floating region in the electrically floating state in the outer region and which forms a Schottky junction with the main surface in the active region.

2. The semiconductor device according to claim 1, wherein
the floating region is adjacent to the trench separation structure in the outer region.

3. The semiconductor device according to claim 1, wherein
the floating region is formed in a depth range between the main surface and a bottom wall of the trench separation structure in the outer region.

4. The semiconductor device according to claim 1, wherein
the floating region is formed deeper than the trench separation structure.

5. The semiconductor device according to claim 1, wherein
the floating region has a covering portion which covers the bottom wall of the trench separation structure.

6. The semiconductor device according to claim 5, wherein
the covering portion covers a portion on the outer region side such as to expose a portion on the active region side in the bottom wall of the trench separation structure.

7. The semiconductor device according to claim 1, wherein
the trench separation structure is formed in an annular shape having an inner peripheral wall and an outer peripheral wall as viewed in plan and demarcates the outer region and the active region in the main surface by the inner peripheral wall, and
the floating region is formed along the outer peripheral wall of the trench separation structure in the outer region.

8. The semiconductor device according to claim 7, wherein
the floating region surrounds the trench separation structure as viewed in plan.

9. The semiconductor device according to claim 1, wherein
the Schottky electrode is connected to a portion of the separation electrode on the active region side in the separation electrode such as to expose a portion of the separation electrode on the outer region side.

10. The semiconductor device according to claim 1, wherein
the main surface inside the active region is depressed in a thickness direction with respect to the main surface inside the outer region.

11. The semiconductor device according to claim 10, wherein
the trench separation structure includes a first portion which is positioned on the outer region side and a second portion which is positioned on the active region side and depressed in a thickness direction of the semiconductor layer with respect to the first portion, and
the trench separation structure demarcates a contact opening which is depressed from the main surface inside the outer region in the thickness direction of the semiconductor layer, with the main surface inside the active region.

12. The semiconductor device according to claim 1, further comprising:
a main surface insulating film which is formed on the outer region such as to cover an entire area of the floating region.

13. The semiconductor device according to claim 12, wherein
the main surface insulating film covers a portion of the separation electrode on the outer region side such as to expose a portion of the separation electrode on the active region side.

14. The semiconductor device according to claim 12, wherein
the main surface insulating film has a wall portion which demarcates a through hole for exposing the active region on the separation electrode, and
the Schottky electrode is electrically connected to the main surface and the separation electrode inside the through hole.

15. The semiconductor device according to claim 12, wherein
the Schottky electrode has a lead-out portion which is led out on the main surface insulating film from the active region and faces a part of the separation electrode and the floating region across the main surface insulating film.

16. The semiconductor device according to claim 15, wherein
the lead-out portion faces an entire area of the floating region across the main surface insulating film.

17. The semiconductor device according to claim 1, further comprising:
a trench structure which includes a trench that is formed in the main surface, an insulating film that covers a wall surface of the trench and an electrode that is embedded in the trench across the insulating film, the trench structure forming at an interval on the main surface in the active region;
wherein the Schottky electrode is electrically connected to the electrode in the active region and forms the Schottky junction with the main surface.

18. The semiconductor device according to claim 17, further comprising:
a protrusion portion which is constituted of an upper end portion of the insulating film and protrudes as a wall from the main surface such as to separate the electrode and the main surface.

19. The semiconductor device according to claim 17, wherein
the trench separation structure is formed wider than the trench structure.

20. The semiconductor device according to claim 17, wherein
the trench structure is connected to the trench separation structure.
